(19) United States
(12) Patent Application Publication
(10) Pub. No.: US 2023/0189634 A1
(43) Pub. Date: Jun. 15, 2023

(54) LIGHT EMITTING ELEMENT AND POLYCYCLIC COMPOUND FOR THE SAME

(71) Applicant: Samsung Display Co., Ltd., Yongin-si (KR)

(72) Inventors: HYEONGMIN KIM, Suwon-si (KR); HEECHOON AHN, Seoul (KR); HYUNAH UM, Seoul (KR); Juhui YUN, Suwon-si (KR); YESEUL LEE, Hwaseong-si (KR)

(21) Appl. No.: 17/950,958

(22) Filed: Sep. 22, 2022

(30) Foreign Application Priority Data
Dec. 10, 2021 (KR) 10-2021-0176439

(51) Int. Cl. H01L 51/00; H01L 51/50

(52) U.S. Cl. CPC H01L 51/0094; H01L 51/0072; H01L 51/5024; H01L 2251/5376

(57) ABSTRACT

A light emitting element includes a first electrode, a second electrode disposed on the first electrode, and at least one functional layer which is disposed between the first electrode and the second electrode, and includes a polycyclic compound represented by Formula 1 below, thereby exhibiting high efficiency and low driving voltage characteristics.

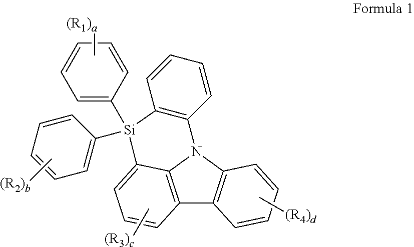

### CROSS-REFERENCE TO RELATED APPLICATION

This application claims priority to and the benefit of Korean Patent Application No. 10-2021-0176439, filed on Dec. 10, 2021, the entire content of which is hereby incorporated by reference.

### BACKGROUND

### 1. Field

The present disclosure herein relates to a light emitting element and a polycyclic compound utilized therein, and for example, to a light emitting element including a polycyclic compound utilized as a luminescent material.

### 2. Description of the Related Art

Recently, the development of an organic electroluminescence display device as an image display device is being actively conducted. The organic electroluminescence display device includes a so-called self-luminescent light emitting element in which holes and electrons injected from a first electrode and a second electrode recombine in an emission layer, and thus a luminescent material in the emission layer emits light to implement display (e.g., to display an image).

In the application of a light emitting element to a display device, there is a desire (e.g., a demand) for a light emitting element having a low driving voltage, a high luminous efficiency, and a long service life (e.g., long lifespan), and development on materials for a light emitting element capable of stably attaining such characteristics is being continuously pursued (e.g., required).

### SUMMARY

An aspect according to embodiments of the present disclosure is directed toward a light emitting element with improved driving voltage characteristic and luminous efficiency.

An aspect according to embodiments of the present disclosure is directed toward a polycyclic compound capable of improving driving voltage characteristic and luminous efficiency of a light emitting element.

According to an embodiment of the present disclosure, a light emitting element includes a first electrode, a second electrode on the first electrode, and at least one functional layer between the first electrode and the second electrode, wherein the at least one functional layer includes a polycyclic compound represented by Formula 1:

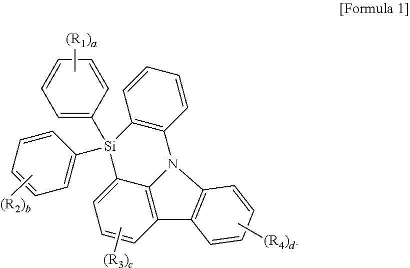

In Formula 1 above, R₁ and R₂ may each independently be a hydrogen atom, a deuterium atom, a cyano group, a substituted or unsubstituted silyl group, a substituted or unsubstituted alkyl group having 1 to 20 carbon atoms, a substituted or unsubstituted cycloalkyl group having 3 to 20 ring-forming carbon atoms, a substituted or unsubstituted heterocycloalkyl group having 3 to 20 ring-forming carbon atoms, a substituted or unsubstituted cycloalkenyl group having 3 to 20 ring-forming carbon atoms, a substituted or unsubstituted heterocycloalkenyl having 3 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms; R₃ and R₄ may each independently be a hydrogen atom, a deuterium atom, or a group represented by Formula 2 or Formula 3; a and b may each independently be an integer of 0 to 5, c may be an integer of 0 to 3, and d may be an integer of 0 to 4.

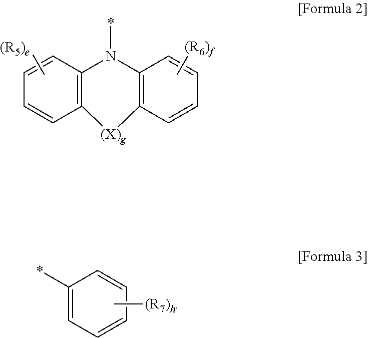

In Formula 2 above, g may be 0 or 1, when g is 0, the two phenyl groups of Formula 2 are only connected through the N atom, and when g is 1, X is a direct linkage.

In Formula 2 and Formula 3 above, R₅ to R₇ may each independently be a hydrogen atom, a deuterium atom, a cyano group, a substituted or unsubstituted silyl group, a substituted or unsubstituted alkyl group having 1 to 20 carbon atoms, a substituted or unsubstituted cycloalkyl group having 3 to 20 ring-forming carbon atoms, a substituted or unsubstituted heterocycloalkyl group having 3 to 20 ring-forming carbon atoms, a substituted or unsubstituted cycloalkenyl group having 3 to 20 ring-forming carbon atoms, a substituted or unsubstituted heterocycloalkenyl group having 3 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, e and f may each independently be an integer of 0 to 4, h may be an integer of 0 to 5, and [symbol] represents a linking position.

In an embodiment, the at least one functional layer may include an emission layer, a hole transport region between the first electrode and the emission layer, and an electron transport region between the emission layer and the second electrode, and the emission layer may include the polycyclic compound.

In an embodiment, the emission layer may be to emit delayed fluorescence or phosphorescence.

In an embodiment, the emission layer may include a host and a dopant, and the host may include the polycyclic compound.

In an embodiment, the emission layer may be to emit light having a center wavelength of about 430 nm to about 480 nm.

In an embodiment, in the polycyclic compound represented by Formula 1 above, R₁ and R₂ may each independently be a hydrogen atom, a deuterium atom, or a substituted or unsubstituted phenyl group.

In an embodiment, in the polycyclic compound represented by Formula 1 above, at least one selected from R₃ or R₄ may be represented by Formula 2 or Formula 3 above.

In an embodiment, Formula 2 above may be represented by Formula 2-1 or Formula 2-2:

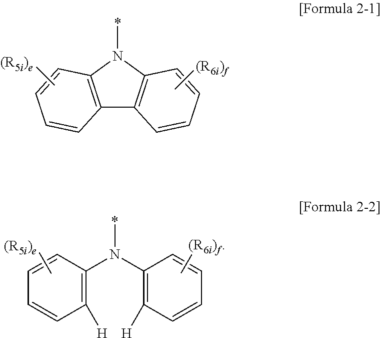

In Formula 2-1 and Formula 2-2 above, R₅ᵢ and R₆ may each independently be a hydrogen atom, a deuterium atom, a substituted or unsubstituted silyl group, a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms, and e and f may each independently be an integer of 1 to 4.

In an embodiment, the polycyclic compound represented by Formula 1 above may be represented by Formula 1-1 or Formula 1-2:

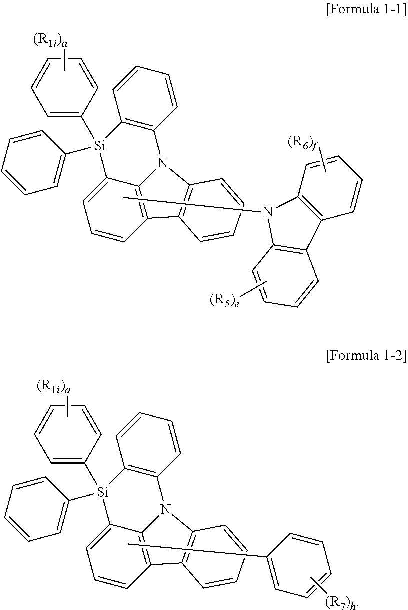

In Formula 1-1 and Formula 1-2 above, Ru may be a hydrogen atom, a deuterium atom, a substituted or unsubstituted alkyl group having 1 to 10 carbon atoms, or a substituted or unsubstituted aryl group having 6 to 20 ring-forming carbon atoms, and R₅ to R₇, a, e, f, and h may be the same as respectively defined in Formula 1 to Formula 3 above.

In an embodiment, the polycyclic compound represented by Formula 1-1 above may be represented by Formula 1-1-1 or Formula 1-1-2:

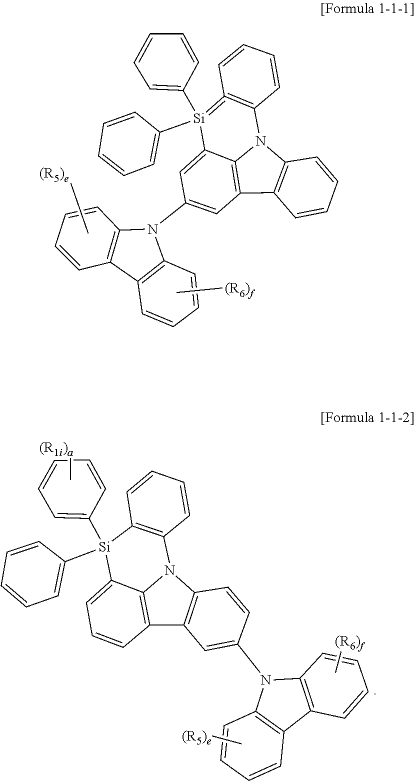

In Formula 1-1-1 and Formula 1-1-2 above, R₁ᵢ, R₅, R₆, a, e, and f may be the same as respectively defined in Formula 1-1 and Formula 2 above.

In an embodiment, the polycyclic compound represented by Formula 1-2 above may be represented by Formula 1-2-1 or 1-2-2:

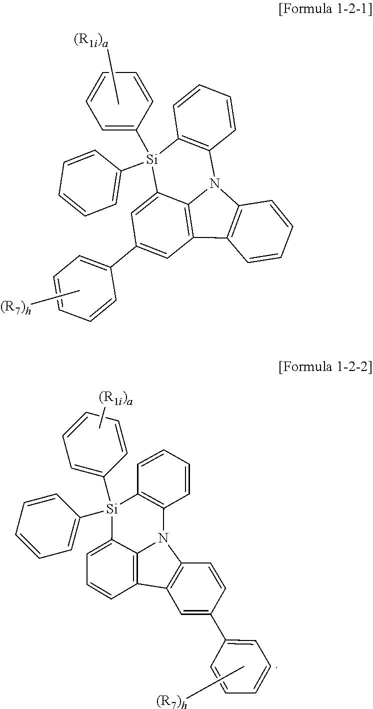

In Formula 1-2-1 and Formula 1-2-2 above, R₁ᵢ, R₇, a, and h may be the same as respectively defined in Formula 1-2 and Formula 3 above.

In an embodiment, R₅ to R₇ above may each independently be a hydrogen atom, a deuterium atom, or a group represented by any one selected from among R-1 to R-5:

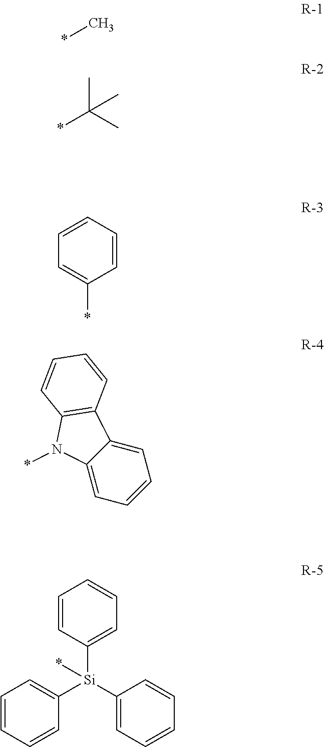

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a plan view illustrating a display device according to an embodiment of the present disclosure;

FIG. 2 is a cross-sectional view illustrating a part taken along the line I-I′ of FIG. 1;

FIG. 3 is a cross-sectional view schematically illustrating a light emitting element according to an embodiment of the present disclosure;

FIG. 4 is a cross-sectional view schematically illustrating a light emitting element according to an embodiment of the present disclosure;

FIG. 5 is a cross-sectional view schematically illustrating a light emitting element according to an embodiment of the present disclosure;

FIG. 6 is a cross-sectional view schematically illustrating a light emitting element according to an embodiment of the present disclosure;

FIG. 7 is a cross-sectional view illustrating a display device according to an embodiment of the present disclosure;

FIG. 8 is a cross-sectional view illustrating a display device according to an embodiment of the present disclosure;

FIG. 9 is a cross-sectional view illustrating a display device according to an embodiment of the present disclosure; and

FIG. 10 is a cross-sectional view illustrating a display device according to an embodiment of the present disclosure.

### DETAILED DESCRIPTION

The present disclosure may be modified in many alternate forms, and thus specific embodiments will be shown in the drawings and described in this text in more detail. It should be understood, however, that it is not intended to limit the present disclosure to the particular forms disclosed, but rather, is intended to cover all modifications, equivalents, and alternatives falling within the spirit and scope of the present disclosure.

In the present specification, when a component (or a region, a layer, a portion, etc.) is referred to as being “on,” “connected to,” or “coupled to” another component, it refers to that the component may be directly disposed on/connected to/coupled to the other component, or that a third component may be disposed therebetween.

Like reference numerals refer to like components throughout. Also, in the drawings, the thicknesses, ratios, and dimensions of the components may be exaggerated for effective description of technical contents. The term “and/or” includes all combinations of one or more of which associated configurations may define.

It will be understood that, although the terms “first,” “second,” etc. may be used herein to describe one or more suitable components, these components should not be limited by these terms. These terms are only used to distinguish one component from another. For example, a first component could be termed a second component, and, similarly, a second component could be termed a first component, without departing from the scope of the present disclosure. As used herein, the singular forms, “a,” “an,” and “the” are intended to include the plural forms as well, unless the context clearly indicates otherwise.

In addition, terms such as “below,” “under,” “on,” and “above” may be used to describe the relationship between components illustrated in the drawings. The terms are used as a relative concept and are described with reference to the direction indicated in the drawings.

It should be understood that the terms “comprise,” or “have” are intended to specify the presence of stated features, integers, steps, operations, components, parts, or combinations thereof in the disclosure, but do not preclude the presence or addition of one or more other features, integers, steps, operations, components, parts, or combinations thereof.

Unless otherwise defined, all terms (including technical and scientific terms) used herein have the same meaning as commonly understood by one of ordinary skill in the art to which the present disclosure belongs. In addition, it will be understood that terms, such as those defined in commonly used dictionaries, should be interpreted as having a meaning that is consistent with their meaning in the context of the relevant art and will not be interpreted in an idealized or overly formal sense unless expressly so defined herein.

In the present application, when a part such as a layer, a film, a region, or a plate is referred to as being “on” or “above” another part, it can be directly on the other part, or an intervening part may also be present. On the contrary, when a part such as a layer, a film, a region, or a plate is referred to as being “under” or “below” another part, it can be directly under the other part, or an intervening part may also be present. In addition, it will be understood that when a part is referred to as being “on” another part, it can be disposed on the other part, or disposed under the other part as well.

In the specification, the term “substituted or unsubstituted” may refer to a functional group that is substituted or unsubstituted with at least one substituent selected from the group consisting of a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In addition, each of the substituents described above may be substituted or unsubstituted. For example, a biphenyl group may be interpreted as an aryl group or a phenyl group substituted with a phenyl group.

In the specification, the phrase “bonded to an adjacent group to form a ring” may indicate that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In addition, the rings formed by adjacent groups being bonded to each other may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be a linear, branched or cyclic alkyl group. The number of carbon atoms in the alkyl group may be 1 to 60, 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but the embodiment of the present disclosure is not limited thereto.

The term “hydrocarbon ring group” as used herein refers to any functional group or substituent derived from an aliphatic hydrocarbon ring or a ring in which an aliphatic hydrocarbon ring group and an aromatic hydrocarbon ring are fused. The number of ring-forming carbon atoms in the hydrocarbon ring group may be 5 to 60, 5 to 30, or 5 to 30.

In the specification, the term “aryl group” refers to any functional group or substituent derived from an aromatic hydrocarbon ring. The aryl group may be a monocyclic aryl group or a polycyclic aryl group. The number of ring-forming carbon atoms in the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but the embodiment of the present disclosure is not limited thereto.

In the specification, the term “heterocyclic group” refers to any functional group or substituent derived from a ring containing at least one of B, 0, N, P, Se, Si, or S as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

When the heterocyclic group includes two or more heteroatoms, the two or more heteroatoms may be the same as or different from each other. The heterocyclic group may be a monocyclic heterocyclic group or a polycyclic heterocyclic group and may include a heteroaryl group. The number of ring-forming carbon atoms in the heterocyclic group may be 2 to 60, 2 to 30, 2 to 20, or 2 to 10.

In the specification, the aliphatic heterocyclic group may contain at least one of B, 0, N, P, Se, Si, or S as a heteroatom. The number of ring-forming carbon atoms of the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group etc., but the embodiment of the present disclosure is not limited thereto.

In the specification, the heteroaryl group may contain at least one of B, 0, N, P, Se, Si, or S as a heteroatom. When the heteroaryl group contains two or more heteroatoms, the two or more heteroatoms may be the same as or different from each other. The heteroaryl group may be a monocyclic heteroaryl group or a polycyclic heteroaryl group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but the embodiment of the present disclosure is not limited thereto.

In the specification, the above description of the aryl group may be applied to an arylene group except that the arylene group is a divalent group. The above description of the heteroaryl group may be applied to a heteroarylene group except that the heteroarylene group is a divalent group.

In the specification, the fluorenyl group may be substituted, and two substituents may be bonded to each other to form a spiro structure. Examples of cases where the fluorenyl group is substituted are as follows. However, the embodiment of the present disclosure is not limited thereto.

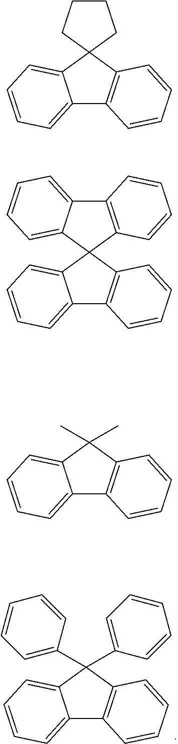

In the specification, a silyl group includes an alkyl silyl group and an aryl silyl group. Examples of the silyl group may include a trimethylsilyl group, a triethylsilyl group, a t-butyldimethylsilyl group, an ethyldimethylsilyl group, a propyldimethylsilyl group, a triphenylsilyl group, a diphenylsilyl group, a phenylsilyl group, etc., but the embodiment of the present disclosure is not limited thereto.

In the specification, a thio group may include an alkylthio group and an arylthio group. The thio group may refer to that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, and/or a naphthylthio group, but the embodiment of the present disclosure is not limited thereto.

In the specification, an oxy group may refer to that an oxygen atom is bonded to the alkyl group or the aryl group as defined above. The oxy group may include an alkoxy group and an aryl oxy group. The alkoxy group may be a linear chain, a branched chain or a ring chain. The number of carbon atoms in the alkoxy group is not specifically limited, but may be, for example, 1 to 60, 1 to 20 or 1 to 10. The number of ring-forming carbon atoms in the aryloxy group is not specifically limited, but may be, for example, 6 to 60, 6 to 30 or 6 to 20. Examples of the oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy, etc., but the embodiment of the present disclosure is not limited thereto.

The term “boron group” as used herein may refer to that a boron atom is bonded to the alkyl group or the aryl group as defined above. The boron group includes an alkyl boron group and an aryl boron group. Examples of the boron group may include a dimethylboron group, a diethylboron group, a t-butylmethylboron group, a diphenylboron group, a phenylboron group, etc., but the embodiment of the present disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, a triphenylamine group, etc., but the embodiment of the present disclosure is not limited thereto.

In the specification, the alkyl group in the alkylthio group, the alkylsulfoxy group, the alkylaryl group, the alkylamino group, the alkyl boron group, the alkyl silyl group, and the alkyl amine group is the same as the examples of the alkyl group described above.

In the specification, the aryl group in the aryloxy group, the arylthio group, the arylsulfoxy group, the arylamino group, the arylboron group, the arylsilyl group, the arylamine group is the same as the examples of the aryl group described above.

In the specification, a direct linkage may refer to a single bond. In some embodiments, “ [symbol] ” herein refers to a position to be connected.

Hereinafter, a light emitting element according to an embodiment of the present disclosure will be described with reference to the drawings.

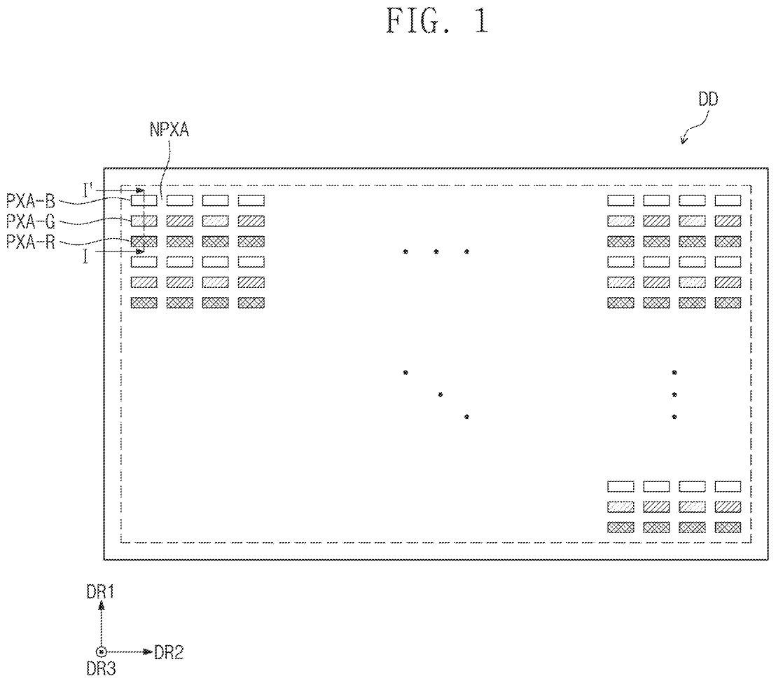

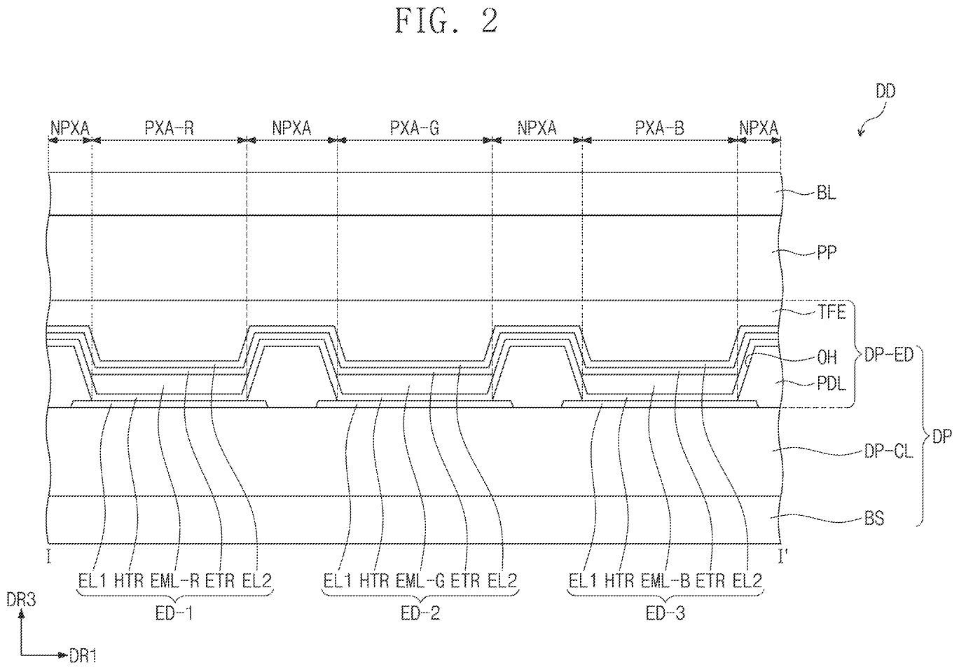

FIG. 1 is a plan view illustrating an embodiment of a display device DD. FIG. 2 is a cross-sectional view of the display device DD of the embodiment. FIG. 2 is a cross-sectional view illustrating a part taken along the line I-I′ of FIG. 1.

The display device DD may include a display panel DP and an optical layer PP disposed on the display panel DP. The display panel DP may include light emitting elements ED-1, ED-2, and ED-3. The display device DD may include a plurality of light emitting elements ED-1, ED-2, and ED-3. The optical layer PP may be disposed on the display panel DP and control reflected light in the display panel DP due to external light. The optical layer PP may include, for example, a polarization layer or a color filter layer. In some embodiments, unlike the configuration illustrated in the drawing, the optical layer PP may not be provided in the display device DD of an embodiment.

A base substrate BL may be disposed on the optical layer PP. The base substrate BL may be a member which provides a base surface on which the optical layer PP is disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, unlike the configuration illustrated, the base substrate BL may not be provided.

The display device DD according to an embodiment may further include a filling layer. The filling layer may be disposed between a display element layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display element layer DP-ED. The display element layer DP-ED may include a pixel defining film PDL, the light emitting elements ED-1, ED-2, and ED-3 disposed between portions of the pixel defining film PDL, and an encapsulation layer TFE disposed on the light emitting elements ED-1, ED-2, and ED-3.

The base layer BS may be a member which provides a base surface on which the display element layer DP-ED is disposed. The base layer BS may be a glass substrate, a metal substrate, a plastic substrate, etc. However, the embodiment is not limited thereto, and the base layer BS may be an inorganic layer, an organic layer, or a composite material layer.

In an embodiment, the circuit layer DP-CL is disposed on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-1, ED-2, and ED-3 of the display element layer DP-ED.

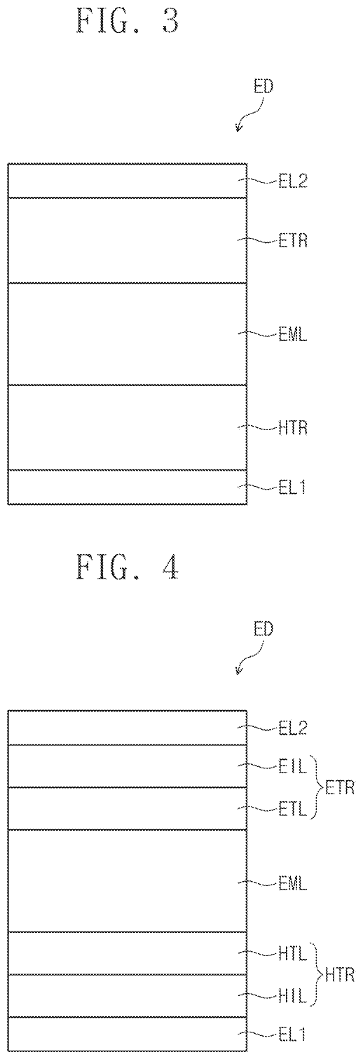

Each of the light emitting elements ED-1, ED-2, and ED-3 may have a structure of a light emitting element ED of an embodiment according to FIGS. 3 to 6, which will be described in more detail later. Each of the light emitting elements ED-1, ED-2 and ED-3 may include a first electrode EL1, a hole transport region HTR, emission layer(s) EML-R, EML-G and/or EML-B (e.g., a corresponding selected from among the emission layer EML-R, the emission layer EML-G, and the emission layer EML-B), an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are provided as a common layer in the entire light emitting elements ED-1, ED-2, and ED-3. However, the embodiment of the present disclosure is not limited thereto, and unlike the configuration illustrated in FIG. 2, the hole transport region HTR and the electron transport region ETR in an embodiment may be provided by being patterned inside the openings OH defined in the pixel defining film PDL. For example, the hole transport region HTR, the emission layers EML-R, EML-G, and EML-B, and the electron transport region ETR of the light emitting elements ED-1, ED-2, and ED-3 in an embodiment may be provided by being patterned through an inkjet printing method.

The encapsulation layer TFE may cover the light emitting elements ED-1, ED-2 and ED-3. The encapsulation layer TFE may seal the display element layer DP-ED. The encapsulation layer TFE may be a thin film encapsulation layer. The encapsulation layer TFE may be formed as one layer or by laminating a plurality of layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film may protect the display element layer DP-ED from moisture/oxygen, and the encapsulation-organic film may protect the display element layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The encapsulation layer TFE may be disposed on the second electrode EL2 and may be disposed to fill the opening OH.

Referring to FIGS. 1 and 2, the display device DD may include a non-light emitting region NPXA and light emitting regions PXA-R, PXA-G and PXA-B. The light emitting regions PXA-R, PXA-G and PXA-B may be regions in which light generated by the respective light emitting elements ED-1, ED-2 and ED-3 is emitted. The light emitting regions PXA-R, PXA-G, and PXA-B may be spaced apart from one another on a plane (e.g., in a plan view).

Each of the light emitting regions PXA-R, PXA-G, and PXA-B may be a region divided by the pixel defining film PDL. The non-light emitting regions NPXA may be regions between the adjacent light emitting regions PXA-R, PXA-G, and PXA-B, which correspond to portions of the pixel defining film PDL. In some embodiments, in the specification, the light emitting regions PXA-R, PXA-G, and PXA-B may each correspond to a respective pixel. The pixel defining film PDL may divide or define the light emitting elements ED-1, ED-2, and ED-3. The emission layers EML-R, EML-G and EML-B of the light emitting elements ED-1, ED-2 and ED-3 may be disposed in openings OH defined in the pixel defining film PDL and separated from one another.

The light emitting regions PXA-R, PXA-G and PXA-B may be divided into a plurality of groups according to the color of light generated from the light emitting elements ED-1, ED-2 and ED-3. In the display device DD of an embodiment shown in FIGS. 1 and 2, three light emitting regions PXA-R, PXA-G, and PXA-B which emit red light, green light, and blue light, respectively, are illustrated. For example, the display device DD of an embodiment may include the red light emitting region PXA-R, the green light emitting region PXA-G, and the blue light emitting region PXA-B that are separated from one another.

In the display device DD according to an embodiment, the plurality of light emitting elements ED-1, ED-2 and ED-3 may be to emit light (e.g., light beams) having wavelengths different from one another. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, the embodiment of the present disclosure is not limited thereto, and the first to third light emitting elements ED-1, ED-2, and ED-3 may be to emit light (e.g., light beams) in substantially the same wavelength range or at least one light emitting element may be to emit a light (e.g., light beam) in a wavelength range different from the others. For example, the first to third light emitting elements ED-1, ED-2, and ED-3 may all emit blue light.

The light emitting regions PXA-R, PXA-G, and PXA-B in the display device DD according to an embodiment may be arranged in a stripe form. Referring to FIG. 1, the plurality of red light emitting regions PXA-R may be arranged with one another along a second directional axis DR2, the plurality of green light emitting regions PXA-G may be arranged with one another along the second directional axis DR2, and the plurality of blue light emitting regions PXA-B may be arranged with one another along the second directional axis DR2. In some embodiments, the red light emitting region PXA-R, the green light emitting region PXA-G, and the blue light emitting region PXA-B may also be alternately arranged in this order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from one another according to the wavelength range of the emitted light. In this case, the areas of the light emitting regions PXA-R, PXA-G, and PXA-B may refer to areas when viewed on a plane defined by the first directional axis DR1 and the second directional axis DR2 (e.g., in a plan view).

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display device DD. For example, the arrangement form of the light emitting regions PXA-R, PXA-G, and PXA-B may be a PENTILE® arrangement form (e.g., an RGBG matrix, RGBG structure, or RGBG matrix structure) or a Diamond Pixel™ arrangement form. PENTILE® and Diamond Pixel™ are both trademarks of Samsung Display Co., Ltd.

In some embodiments, the areas of the light emitting regions PXA-R, PXA-G, and PXA-B may be different from one another. For example, in an embodiment, the area of the green light emitting region PXA-G may be smaller than that of the blue light emitting region PXA-B, but the embodiment of the present disclosure is not limited thereto.

Hereinafter, FIGS. 3 to 6 are cross-sectional views schematically illustrating light emitting elements according to embodiments. Each of the light emitting elements ED according to embodiments may include a first electrode EL1, a second electrode EL2 facing the first electrode EL1, and at least one functional layer disposed between the first electrode EU and the second electrode EL2. The light emitting element ED of an embodiment may include a polycyclic compound of an embodiment, which will be described in more detail below, in at least one functional layer.

Each of the light emitting elements ED may include, as the at least one functional layer, a hole transport region HTR, an emission layer EML, and an electron transport region ETR that are sequentially stacked in the stated order. For example, each of the light emitting elements ED of embodiments may include the first electrode EL1, the hole transport region HTR, the emission layer EML, the electron transport region ETR, and the second electrode EL2 that are sequentially stacked in the stated order.

The light emitting element ED of an embodiment may include the polycyclic compound of an embodiment, which will be described in more detail below, in the emission layer EML. However, the embodiment of the present disclosure is not limited thereto, and the light emitting element ED: may include the polycyclic compound according to an embodiment, which will be described in more detail below, in the hole transport region HTR from among the plurality of functional layers disposed between the first electrode EL1 and the second electrode EL2; or may include the polycyclic compound according to an embodiment, which will be described in more detail below, in a capping layer CPL disposed on the second electrode EL2, as well as in the emission layer EML and the electron transport region ETR.

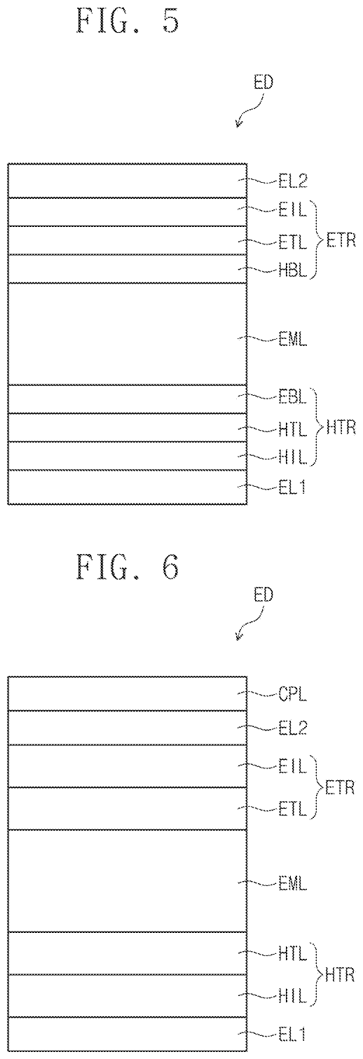

Compared with FIG. 3, FIG. 4 illustrates a cross-sectional view of a light emitting element ED of an embodiment, in which a hole transport region HTR includes a hole injection layer HIL and a hole transport layer HTL, and an electron transport region ETR includes an electron injection layer EIL and an electron transport layer ETL. In some embodiments, compared with FIG. 3, FIG. 5 illustrates a cross-sectional view of a light emitting element ED of an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting element ED of an embodiment including a capping layer CPL disposed on a second electrode EL2.

In the light emitting element ED according to an embodiment, the first electrode EL1 has suitable conductivity (e.g., is a conductor). The first electrode EL1 may be formed of a metal material, a metal alloy, or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode EU may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected therefrom (e.g., from among these), a mixture of two or more therefrom (e.g., selected from among these), or an oxide thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/AI (a stacked structure of LiF and Al), Mo, Ti, W, or a compound or mixture thereof (e.g., a mixture of Ag and Mg). In some embodiments, the first electrode EU may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but the embodiment of the present disclosure is not limited thereto. In some embodiments, the first electrode EL1 may include the above-described metal material(s), combination(s) of at least two metal material(s) of the above-described metal materials, oxide(s) of the above-described metal material(s), and/or the like. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer, and/or an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL, that are stacked in the respective stated order from the first electrode EU, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1:

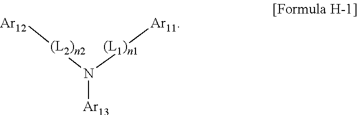

In Formula H-1 above, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. n1 and n2 may each independently be an integer of 0 to 10. In some embodiments, when n1 or n2 is an integer of 2 or more, a plurality of Li's and/or a plurality of L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁₁ and Ar₁₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₁₃ may be a substituted or unsubstituted aryl group having 6 to 30 ring-forming carbon atoms.

The compound represented by Formula H-1 above may be a monoamine compound (e.g., a compound including a single amine group). In some embodiments, the compound represented by Formula H-1 above may be a diamine compound in which at least one selected from among Ar₁₁ to Ar₁₃ includes an amine group as a substituent. In some embodiments, the compound represented by Formula H-1 above may be a carbazole-based compound including a substituted or unsubstituted carbazole group in at least one of Ar₁₁ or Ar₁₂, or a fluorene-based compound including a substituted or unsubstituted fluorene group in at least one of Aril or Ar₁₂.

The compound represented by Formula H-1 may be represented by any one selected from among the compounds of Compound Group H. However, the compounds listed in Compound Group H are examples, and the compounds represented by Formula H-1 are not limited to those represented by Compound Group H:

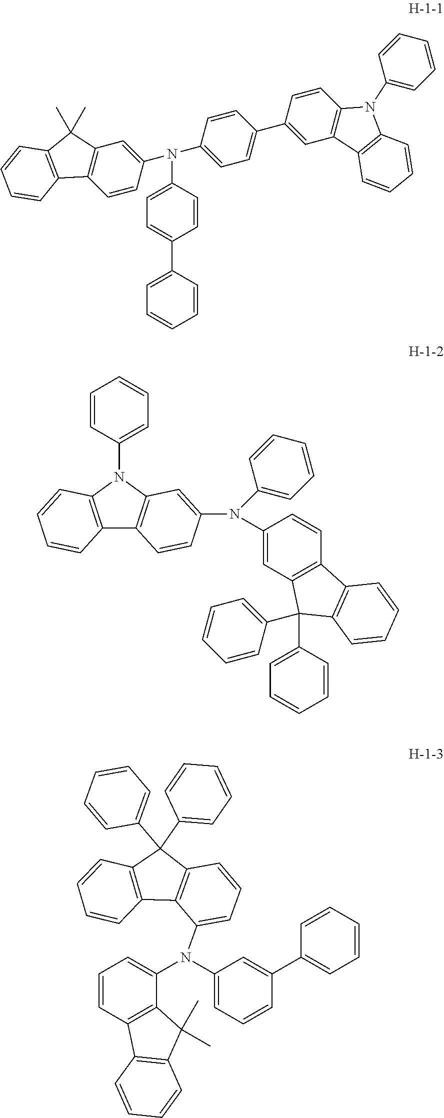 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

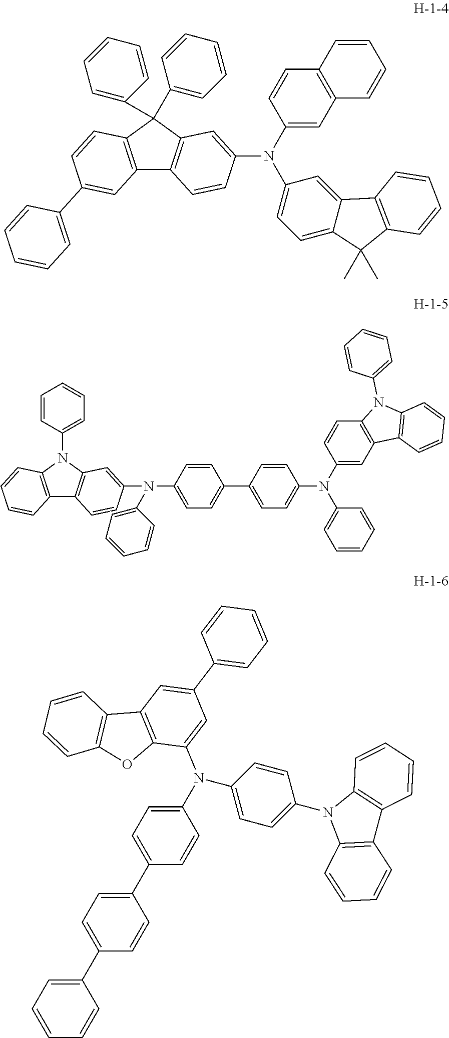 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

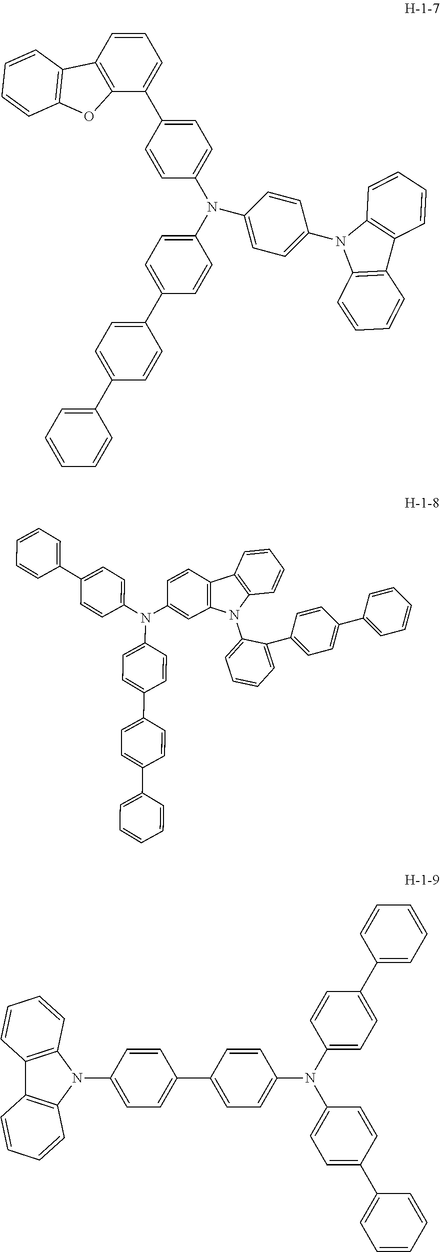 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

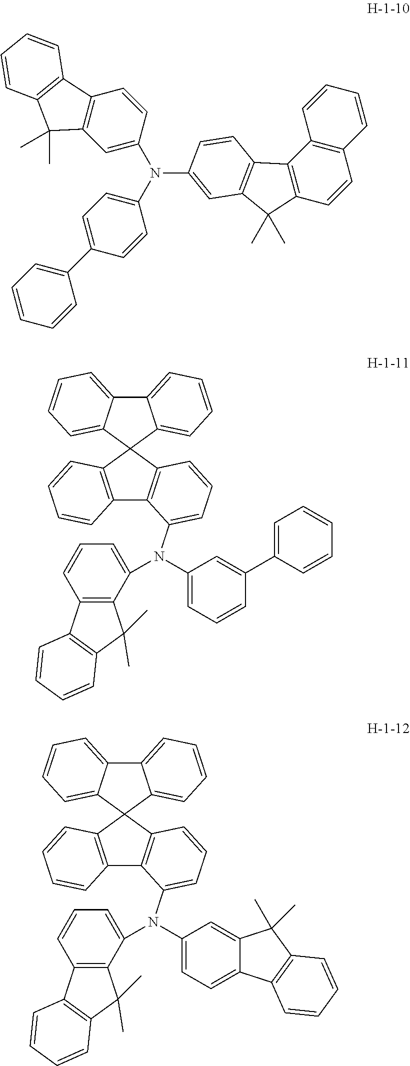

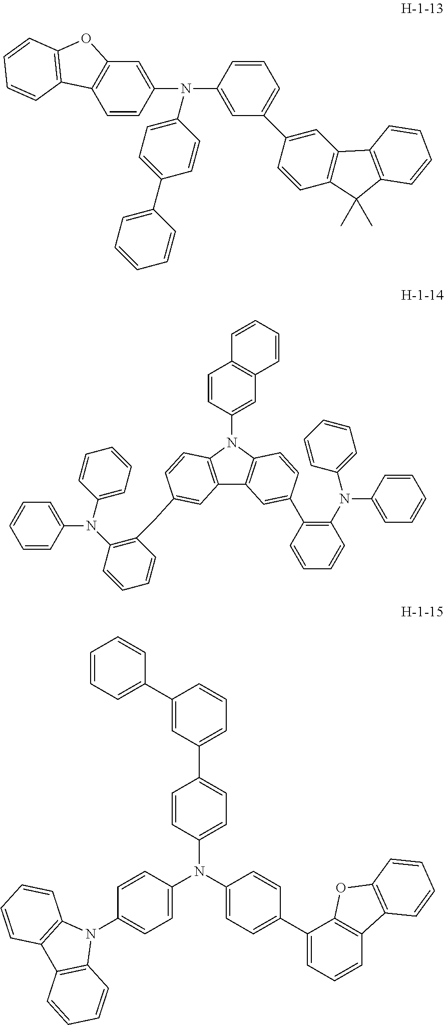 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2Cc2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

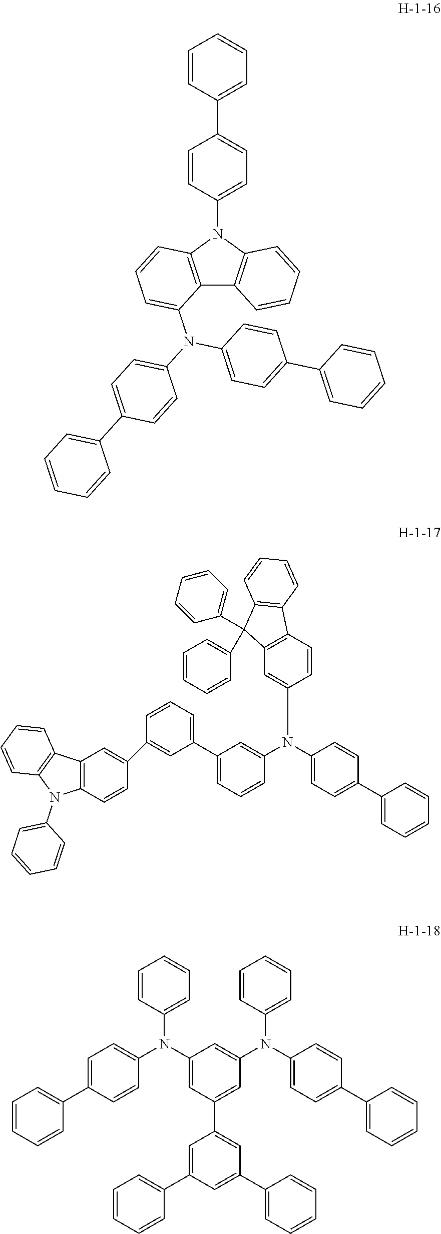 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(Cc3ccc4c(c3)C(c3ccccc3)(c3ccccc3)c3ccccc3-4)c3cccc(-c4cccc(-c5ccc6c(c5)c5ccccc5n6-c5ccccc5)c4)c3)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

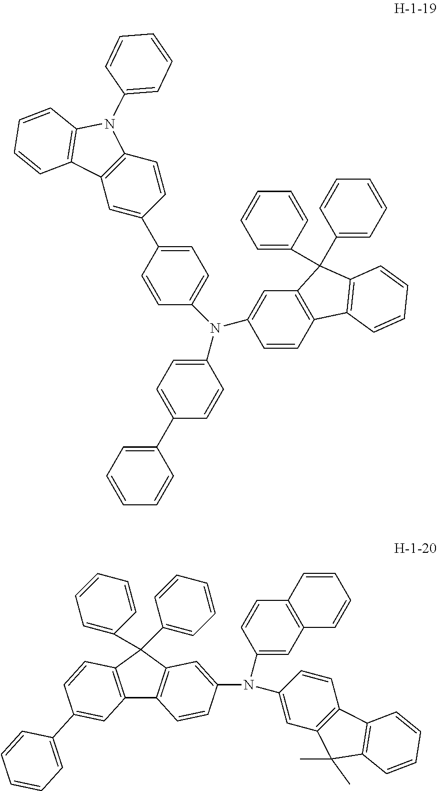 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; CC1(C)c2ccccc2-c2ccc(N(c3ccc4c(c3)C(c3ccccc3)(c3ccccc3)c3ccc(-c5ccccc5)cc3-4)c3ccc4ccccc4c3)cc21]

The hole transport region HTR may further include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB(or NPD)), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole and/or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) and/or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 30 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the above-described ranges, satisfactory, suitable, and/or desired hole transport properties may be achieved without a substantial increase in driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a halogenated metal (e.g., metal halide) compound, a quinone derivative, a metal oxide, or a cyano group-containing compound, but the embodiment of the present disclosure is not limited thereto. For example, the p-dopant may include a metal halide compound such as Cul and/or RbI, a quinone derivative such as tetracyanoquinodimethane (TCNQ) and/or 2,3,5,6-tetrafluoro-7,7, 8,8-tetracyanoquinodimethane (F4-TCNQ), a metal oxide such as tungsten oxide and/or molybdenum oxide, a cyano group-containing compound such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cya nomethyl]-2,3,5,6-tetrafluorobenzonitrile (NDP9), etc., but the embodiment of the present disclosure is not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be contained in the hole transport region HTR may be utilized as a material to be contained in the buffer layer. The electron blocking layer EBL is a layer that serves to prevent or reduce the electron injection from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

In the light emitting element ED according to an embodiment, the emission layer EML may include a polycyclic compound of an embodiment. The polycyclic compound of an embodiment may be a fused polycyclic compound including a structure in which a silyl group is fused with a carbazole skeleton. For example, the polycyclic compound of an embodiment may be a fused polycyclic compound in which a carbazole and a triphenylsilyl group are fused with each other.

The polycyclic compound in an embodiment may be represented by Formula 1. The polycyclic compound represented by Formula 1 may have a molecular weight of about 500 or more:

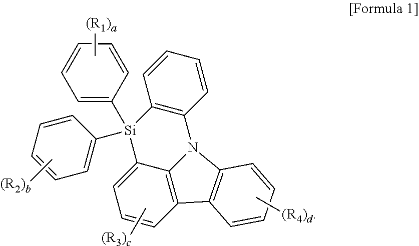

In Formula 1, R₁ and R₂ may each independently be a hydrogen atom, a deuterium atom, a cyano group, a substituted or unsubstituted silyl group, a substituted or unsubstituted alkyl group having 1 to 20 carbon atoms, a substituted or unsubstituted cycloalkyl group having 3 to 20 ring-forming carbon atoms, a substituted or unsubstituted heterocycloalkyl group having 3 to 20 ring-forming carbon atoms, a substituted or unsubstituted cycloalkenyl group having 3 to 20 ring-forming carbon atoms, a substituted or unsubstituted heterocycloalkenyl group having 3 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms. For example, R₁ and R₂ may each independently be a substituted or unsubstituted alkyl group having 1 to 10 carbon atoms, or a substituted or unsubstituted aryl group having 6 to 20 ring-forming carbon atoms. For example, R₁ and R₂ may each independently be a hydrogen atom, a deuterium atom, or a substituted or unsubstituted phenyl group. However, the embodiment of the present disclosure is not limited thereto.

In Formula 1, a and b may each independently be an integer of 0 to 5. For example, the case where a is 0 may be the same as the case where a is 1 and R₁ is a hydrogen atom. The case where b is 0 may be the same as the case where b is 1 and R₂ is a hydrogen atom.

When each of a and b is an integer of 2 or more, a plurality of R₁'s and R₂'s may each be the same or different. For example, when a is 2, two R₁'s may be the same as or different from each other. In addition, when b is 2, two R₂'s may be the same as or different from each other.

In Formula 1, R₃ and R₄ may each independently be a hydrogen atom, a deuterium atom, or a substituent represented by Formula 2 or Formula 3. In the polycyclic compound represented by Formula 1 of an embodiment, at least one of R₃ or R₄ may be a substituent represented by Formula 2 or Formula 3. For example, the polycyclic compound of an embodiment may include one substituent represented by Formula 2 or one substituent represented by Formula 3. However, the embodiment of the present disclosure is not limited thereto, and the polycyclic compound of an embodiment may include two or more substituents represented by Formula 2 and/or Formula 3.

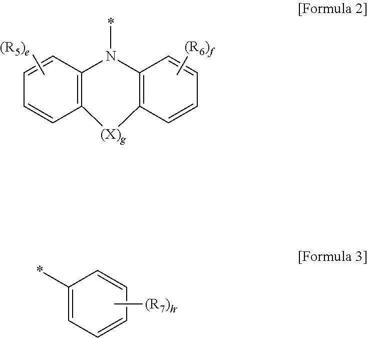

In Formula 2 and Formula 3, [symbol] represents a linking position, and may be a part bonded to an aromatic ring in Formula 1.

In Formula 2 and Formula 3, R₅ to R₇ may each independently be a hydrogen atom, a deuterium atom, a cyano group, a substituted or unsubstituted silyl group, a substituted or unsubstituted alkyl group having 1 to 20 carbon atoms, a substituted or unsubstituted cycloalkyl group having 3 to 20 ring-forming carbon atoms, a substituted or unsubstituted heterocycloalkyl group having 3 to 20 ring-forming carbon atoms, a substituted or unsubstituted cycloalkenyl group having 3 to 20 ring-forming carbon atoms, a substituted or unsubstituted heterocycloalkenyl group having 3 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring.

In an embodiment, R₅ to R₇ may each independently be a hydrogen atom, a deuterium atom, or a substituent represented by any one selected from among R-1 to R-5. However, the embodiment of the present disclosure is not limited thereto. In R-1 to R-5, “ [symbol] ” may be a part bonded to a benzene ring in Formula 2 or Formula 3:

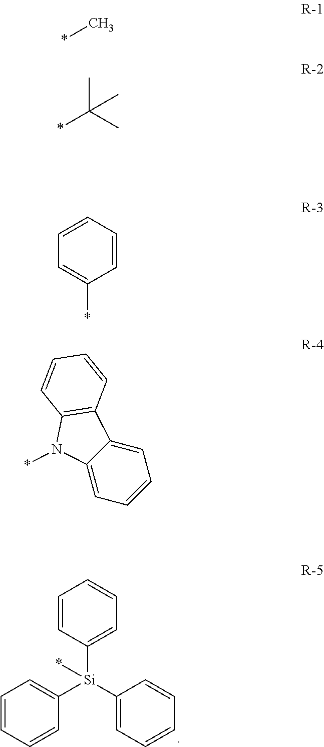

In Formula 2, e and f may each independently be an integer of 0 to 4. For example, the case where e is 0 may refer to that the substituent represented by Formula 2 is not substituted with R₅, and may be the same as the case where e is 1 and R₅ is a hydrogen atom. In addition, such an example description may be equally applied to the case where f is Of.

When each of a and f is an integer of 2 or more, a plurality of R₅'s and R₆'s may each be the same or different. For example, when a is 2, two R₅'s may be the same as or different from each other. In addition, when f is 2, two R₆'s may be the same as or different from each other.

In Formula 2, g is 0 or 1, and when g is 1, X may be a direct linkage. For example, when g is 0, the two benzene rings linked to the nitrogen atom in Formula 2 may not be linked via X. That is, when g is 0, the substituent represented by Formula 2 may include a diphenylamine moiety and not a carbazole moiety. In addition, the case where g is 1 may refer to that the two benzene rings linked to the nitrogen atom in Formula 2 is linked via a direct linkage to form a fused ring. That is, when g is 1, the substituent represented by Formula 2 may include a carbazole moiety.

For example, when g in Formula 2 is 0, the substituent represented by Formula 2 may be represented by Formula 2-2. When g in Formula 2 is 1, the substituent represented by Formula 2 may be represented by Formula 2-1:

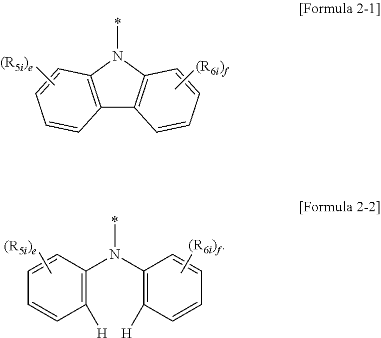

In Formula 2-1 and Formula 2-2, the same description of R₅ and R₆ as described in Formula 2 above may be applied to R₅ᵢ to R₆ᵢ. For example, R₅ᵢ and R₆ᵢ may each independently be a hydrogen atom, a deuterium atom, a substituted or unsubstituted silyl group, a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms. For example, R₅ᵢ to R₆ᵢ may each independently be a hydrogen atom, a deuterium atom, or a substituent represented by any one selected from among R-1 to R-5. However, the embodiment of the present disclosure is not limited thereto.

In Formula 2-1 and Formula 2-2, the same as described in Formula 2 may be applied to e and f.

In Formula 3, h is an integer of 0 to 5. For example, the case where h is 0 may refer to that the substituent represented by Formula 3 is not substituted with R₇, and may be the same as the case where h is 1 and R₇ is a hydrogen atom. When h is an integer of 2 or more, a plurality of R₇'s may be the same as or different from each other. For example, when h is 2, two R₇'s may be the same as or different from each other.

In an embodiment, the polycyclic compound represented by Formula 1 may be represented by Formula 1-1 or Formula 1-2. The polycyclic compound represented by Formula 1-1 of an embodiment corresponds to the case where R₁ is specified in the polycyclic compound represented by Formula 1, and any one selected from among R₃ and R₄ is a substituent represented by Formula 2. The polycyclic compound represented by Formula 1-2 of an embodiment corresponds to the case where R₁ is specified in the polycyclic compound represented by Formula 1, and any one selected from among R₃ and R₄ is a substituent represented by Formula 3.

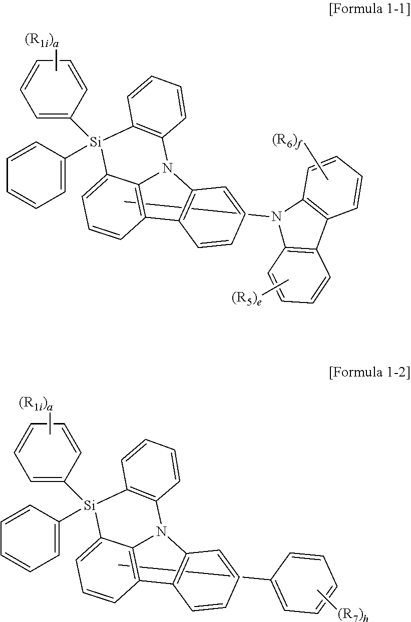

In Formula 1-1 and Formula 1-2, the same description of R₁ as described in Formula 1 above may be applied to R₁ᵢ. For example, Ru may be a hydrogen atom, a deuterium atom, a substituted or unsubstituted alkyl group having 1 to 10 carbon atoms, or a substituted or unsubstituted aryl group having 6 to 20 ring-forming carbon atoms.

In Formula 1-1 and Formula 1-2, the same as described in Formula 1 to Formula 3 above may be applied to R₅ to R₇, a, e, f, and h.

In an embodiment, the polycyclic compound represented by Formula 1-1 may be represented by Formula 1-1-1 or Formula 1-1-2. Formula 1-1-1 and Formula 1-1-2 represent that the bonding position of the carbazole moiety in Formula 1-1 is specified. In addition, Formula 1-1-1 and Formula 1-1-2 may respectively represent the case where R₃ in Formula 1 is a substituent represented by Formula 2 and R₄ in Formula 1 is a substituent represented by Formula 2.

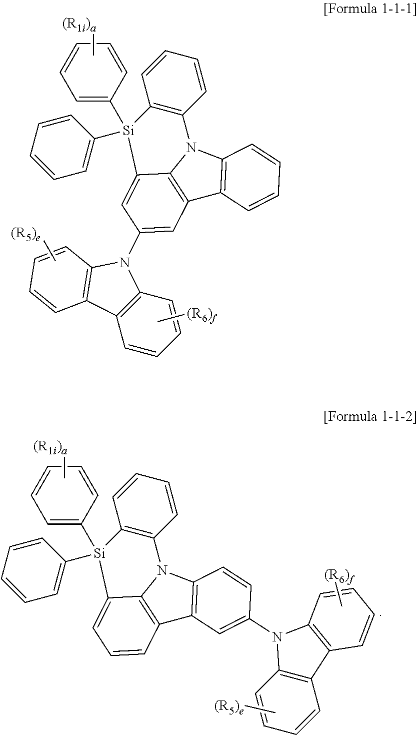

In Formula 1-1-1 and Formula 1-1-2, the same as described in Formula 1-1 and Formula 2 above may be applied to R₁ᵢ, R₅, R₆, a, e, and f.

In an embodiment, the polycyclic compound represented by Formula 1-2 may be represented by Formula 1-2-1 or Formula 1-2-2. Formula 1-2-1 and Formula 1-2-2 represent that the bonding position of the substituted or unsubstituted phenyl group in Formula 1-2 is specified. In addition, Formula 1-2-1 and Formula 1-2-2 may respectively represent the case where R₃ in Formula 1 is a substituent represented by Formula 3 and R₄ in Formula 1 is a substituent represented by Formula 3.

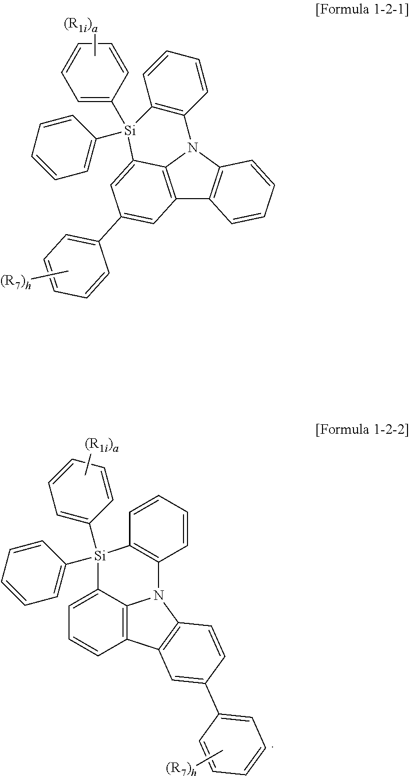

In Formula 1-2-1 and Formula 1-2-2, the same as described in Formula 1-2 and Formula 3 above may be applied to R₁ᵢ, R₇, a and h.

The polycyclic compound represented by Formula 1 of an embodiment may be represented by any one selected from among the compounds represented by Compound Group 1. The light emitting element ED of an embodiment may include at least one polycyclic compound selected from among the compounds represented by Compound Group 1 in the emission layer EML.

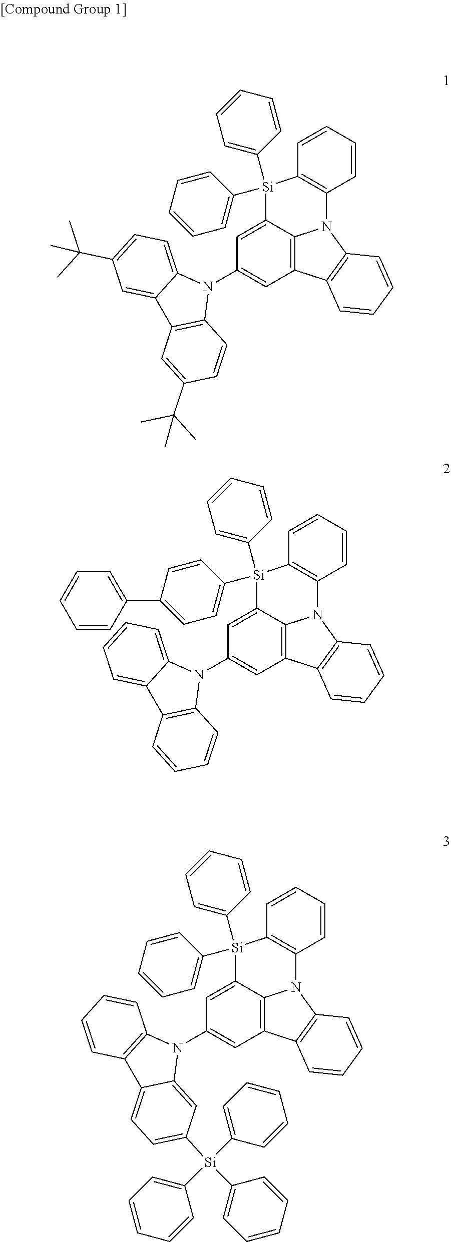 [SMILES: CC(C)(C)c1ccc2c(c1)c1cc(C(C)(C)C)ccc1n2-c1cc2c3c(c1)c1ccccc1n3-c1ccccc1[Si]2(c1ccccc1)c1ccccc1 ; c1ccc(-c2ccc([Si]3(c4ccccc4)c4ccccc4-n4c5ccccc5c5cc(-n6c7ccccc7c7ccccc76)cc3c54)cc2)cc1 ; c1ccc([Si](c2ccccc2)(c2ccccc2)c2ccc3c4ccccc4n(-c4cc5c6c(c4)c4ccccc4n6-c4ccccc4[Si]5(c4ccccc4)c4ccccc4)c3c2)cc1]

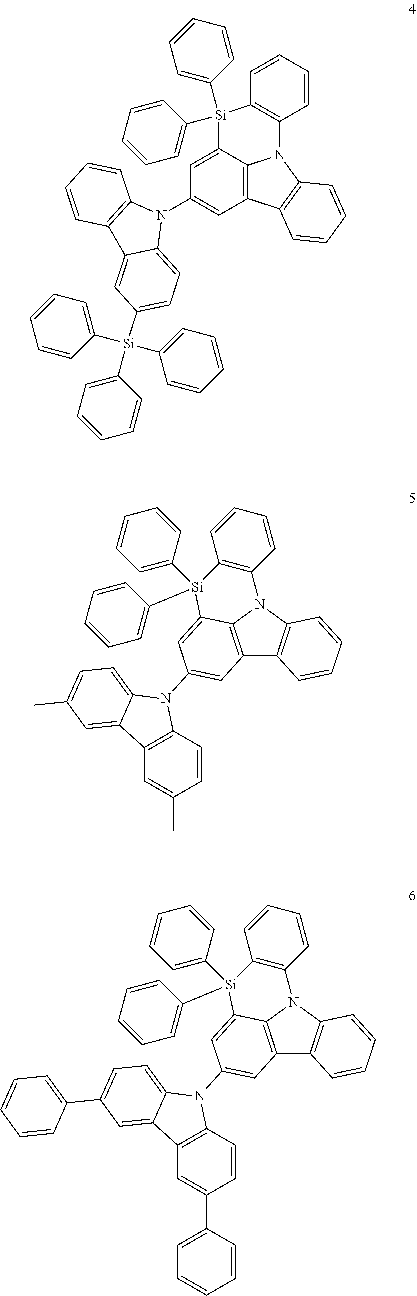 [SMILES: c1ccc([Si](c2ccccc2)(c2ccccc2)c2ccc3c(c2)c2ccccc2n3-c2cc3c4c(c2)c2ccccc2n4-c2ccccc2[Si]3(c2ccccc2)c2ccccc2)cc1 ; Cc1ccc2c(c1)c1cc(C)ccc1n2-c1cc2c3c(c1)c1ccccc1n3-c1ccccc1[Si]2(c1ccccc1)c1ccccc1 ; c1ccc(-c2ccc3c(c2)c2cc(-c4ccccc4)ccc2n3-c2cc3c4c(c2)c2ccccc2n4-c2ccccc2[Si]3(c2ccccc2)c2ccccc2)cc1]

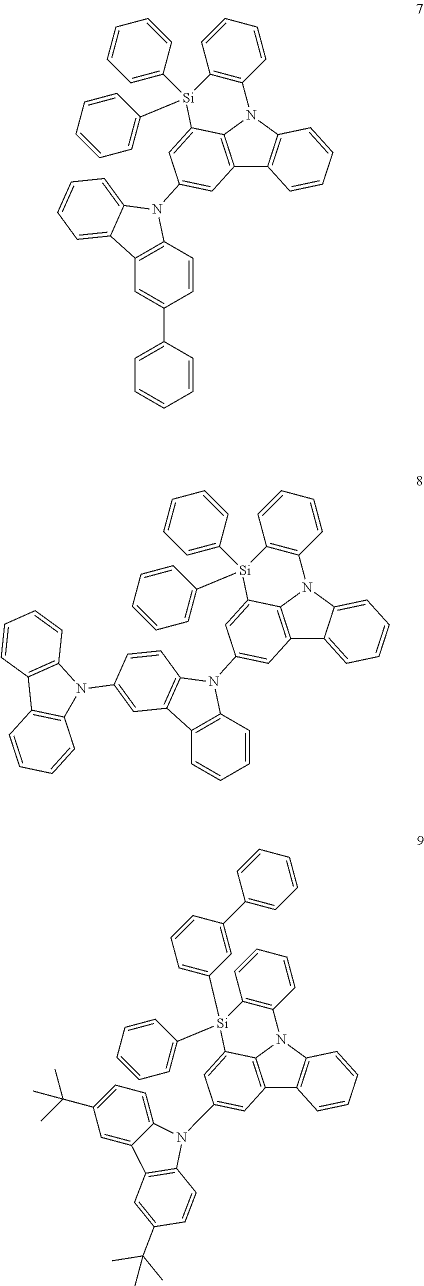 [SMILES: c1ccc(-c2ccc3c(c2)c2ccccc2n3-c2cc3c4c(c2)c2ccccc2n4-c2ccccc2[Si]3(c2ccccc2)c2ccccc2)cc1 ; c1ccc([Si]2(c3ccccc3)c3ccccc3-n3c4ccccc4c4cc(-n5c6ccccc6c6cc(-n7c8ccccc8c8ccccc87)ccc65)cc2c43)cc1 ; CC(C)(C)c1ccc2c(c1)c1cc(C(C)(C)C)ccc1n2-c1cc2c3c(c1)c1ccccc1n3-c1ccccc1[Si]2(c1ccccc1)c1cccc(-c2ccccc2)c1]

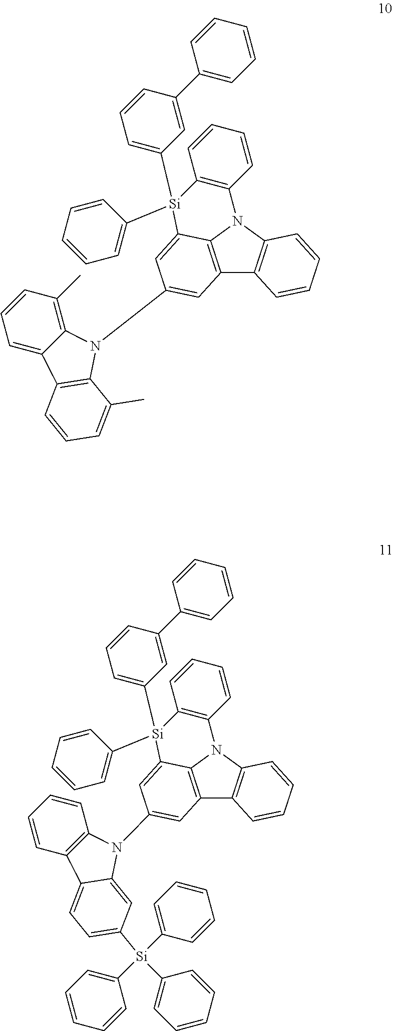 [SMILES: Cc1cccc2c3cccc(C)c3n(-c3cc4c5c(c3)c3ccccc3n5-c3ccccc3[Si]4(c3ccccc3)c3cccc(-c4ccccc4)c3)c12 ; c1ccc(-c2cccc([Si]3(c4ccccc4)c4ccccc4-n4c5ccccc5c5cc(-n6c7ccccc7c7ccc([Si](c8ccccc8)(c8ccccc8)c8ccccc8)cc76)cc3c54)c2)cc1]

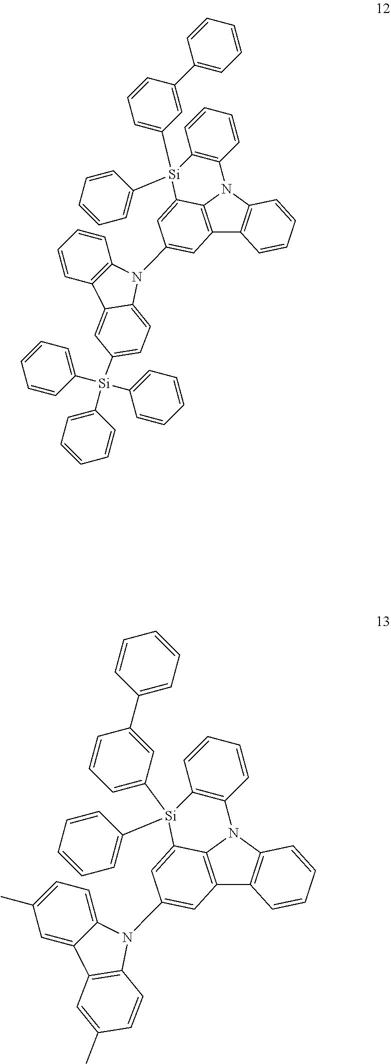 [SMILES: c1ccc(-c2cccc([Si]3(c4ccccc4)c4ccccc4-n4c5ccccc5c5cc(-n6c7ccccc7c7cc([Si](c8ccccc8)(c8ccccc8)c8ccccc8)ccc76)cc3c54)c2)cc1 ; Cc1ccc2c(c1)c1cc(C)ccc1n2-c1cc2c3c(c1)c1ccccc1n3-c1ccccc1[Si]2(c1ccccc1)c1cccc(-c2ccccc2)c1]

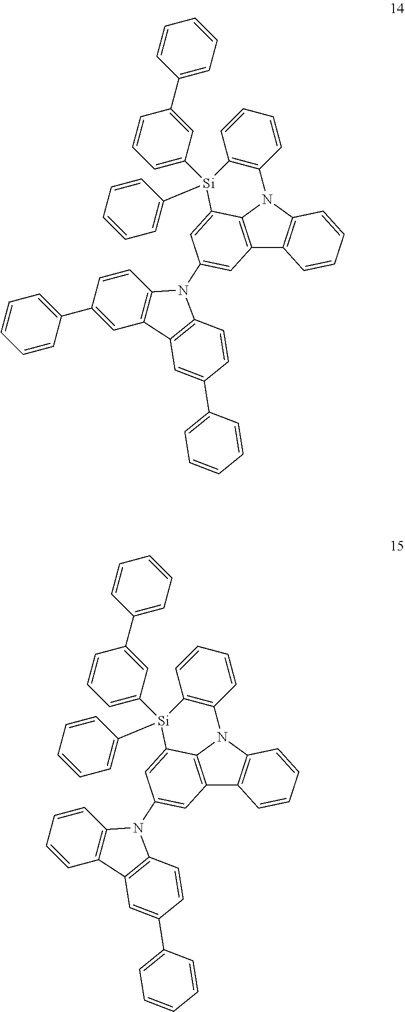 [SMILES: c1ccc(-c2cccc([Si]3(c4ccccc4)c4ccccc4-n4c5ccccc5c5cc(-n6c7ccc(-c8ccccc8)cc7c7cc(-c8ccccc8)ccc76)cc3c54)c2)cc1 ; c1ccc(-c2cccc([Si]3(c4ccccc4)c4ccccc4-n4c5ccccc5c5cc(-n6c7ccccc7c7cc(-c8ccccc8)ccc76)cc3c54)c2)cc1]

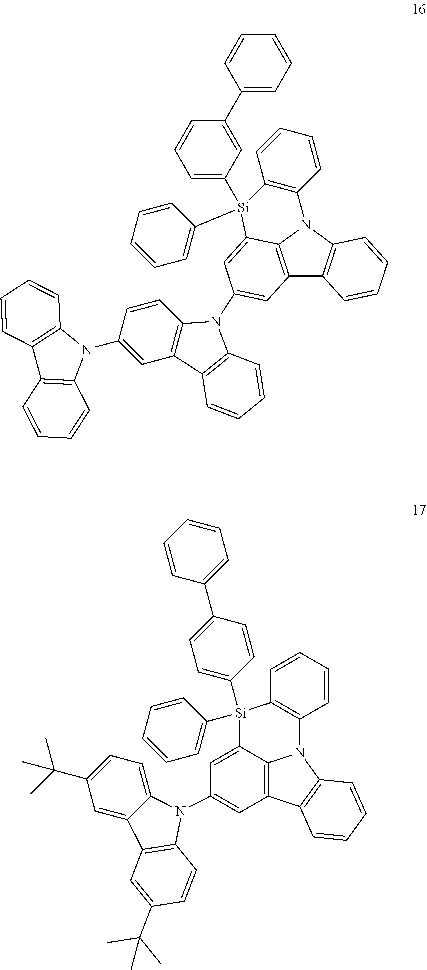 [SMILES: c1ccc(-c2cccc([Si]3(c4ccccc4)c4ccccc4-n4c5ccccc5c5cc(-n6c7ccccc7c7cc(-n8c9ccccc9c9ccccc98)ccc76)cc3c54)c2)cc1 ; CC(C)(C)c1ccc2c(c1)c1cc(C(C)(C)C)ccc1n2-c1cc2c3c(c1)c1ccccc1n3-c1ccccc1[Si]2(c1ccccc1)c1ccc(-c2ccccc2)cc1]

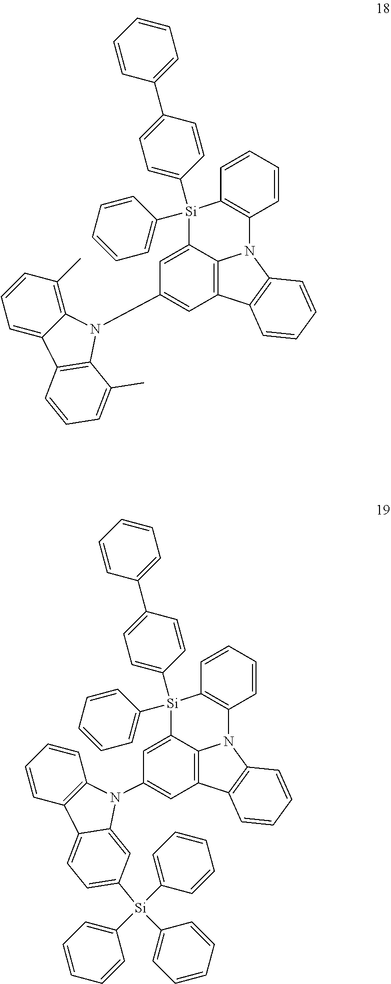 [SMILES: Cc1cccc2c3cccc(C)c3n(-c3cc4c5c(c3)c3ccccc3n5-c3ccccc3[Si]4(c3ccccc3)c3ccc(-c4ccccc4)cc3)c12 ; c1ccc(-c2ccc([Si]3(c4ccccc4)c4ccccc4-n4c5ccccc5c5cc(-n6c7ccccc7c7ccc([Si](c8ccccc8)(c8ccccc8)c8ccccc8)cc76)cc3c54)cc2)cc1]

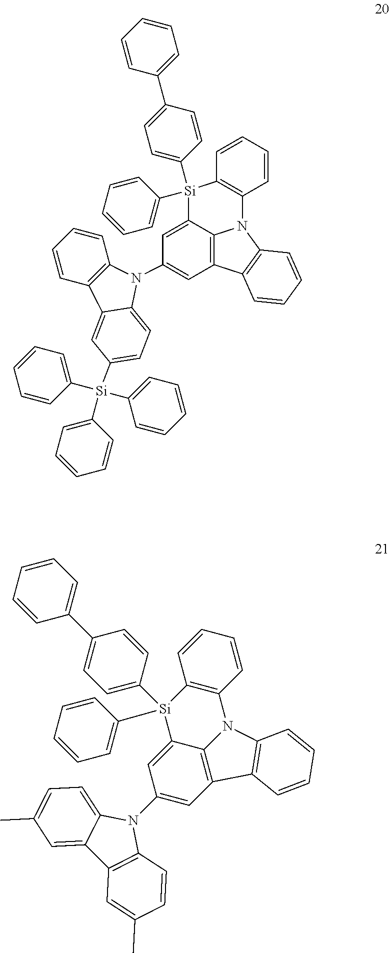 [SMILES: c1ccc(-c2ccc([Si]3(c4ccccc4)c4ccccc4-n4c5ccccc5c5cc(-n6c7ccccc7c7cc([Si](c8ccccc8)(c8ccccc8)c8ccccc8)ccc76)cc3c54)cc2)cc1 ; Cc1ccc2c(c1)c1cc(C)ccc1n2-c1cc2c3c(c1)c1ccccc1n3-c1ccccc1[Si]2(c1ccccc1)c1ccc(-c2ccccc2)cc1]

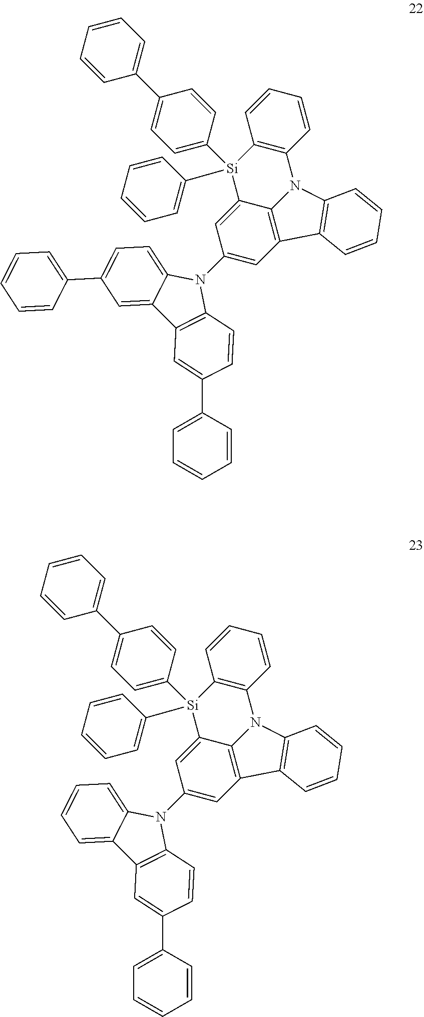 [SMILES: c1ccc(-c2ccc([Si]3(c4ccccc4)c4ccccc4-n4c5ccccc5c5cc(-n6c7ccc(-c8ccccc8)cc7c7cc(-c8ccccc8)ccc76)cc3c54)cc2)cc1 ; c1ccc(-c2ccc([Si]3(c4ccccc4)c4ccccc4-n4c5ccccc5c5cc(-n6c7ccccc7c7cc(-c8ccccc8)ccc76)cc3c54)cc2)cc1]

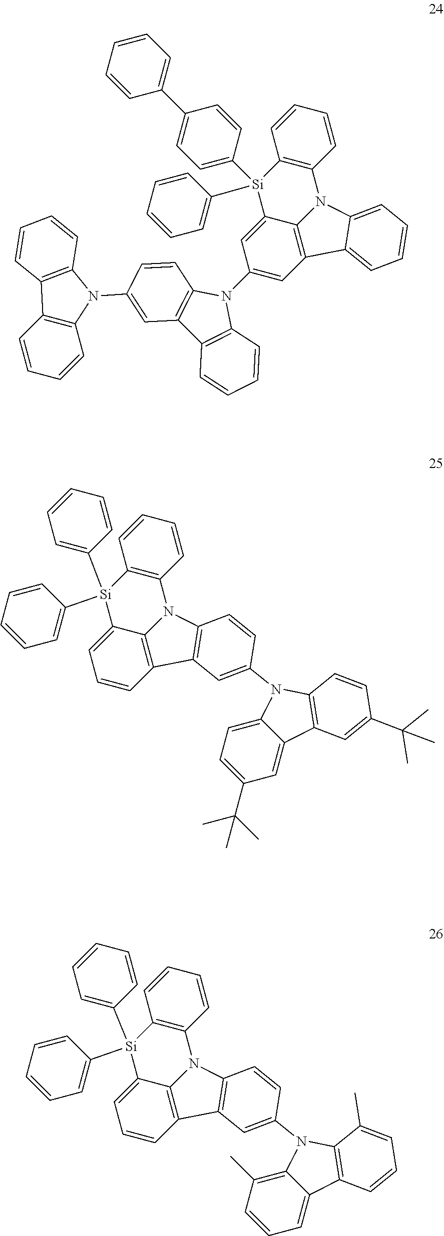 [SMILES: c1ccc(-c2ccc([Si]3(c4ccccc4)c4ccccc4-n4c5ccccc5c5cc(-n6c7ccccc7c7cc(-n8c9ccccc9c9ccccc98)ccc76)cc3c54)cc2)cc1 ; CC(C)(C)c1ccc2c(c1)c1cc(C(C)(C)C)ccc1n2-c1ccc2c(c1)c1cccc3c1n2-c1ccccc1[Si]3(c1ccccc1)c1ccccc1 ; Cc1cccc2c3cccc(C)c3n(-c3ccc4c(c3)c3cccc5c3n4-c3ccccc3[Si]5(c3ccccc3)c3ccccc3)c12]

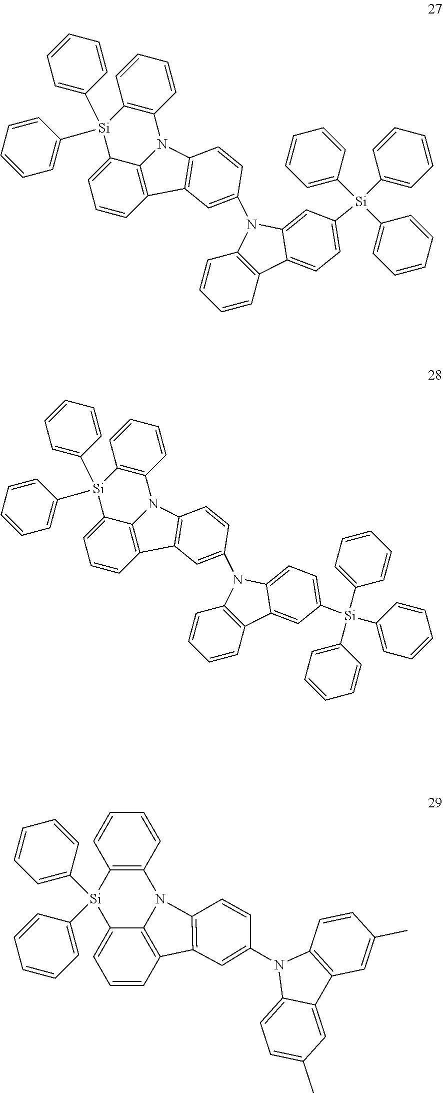 [SMILES: c1ccc([Si](c2ccccc2)(c2ccccc2)c2ccc3c4ccccc4n(-c4ccc5c(c4)c4cccc6c4n5-c4ccccc4[Si]6(c4ccccc4)c4ccccc4)c3c2)cc1 ; c1ccc([Si](c2ccccc2)(c2ccccc2)c2ccc3c(c2)c2ccccc2n3-c2ccc3c(c2)c2cccc4c2n3-c2ccccc2[Si]4(c2ccccc2)c2ccccc2)cc1 ; Cc1ccc2c(c1)c1cc(C)ccc1n2-c1ccc2c(c1)c1cccc3c1n2-c1ccccc1[Si]3(c1ccccc1)c1ccccc1]

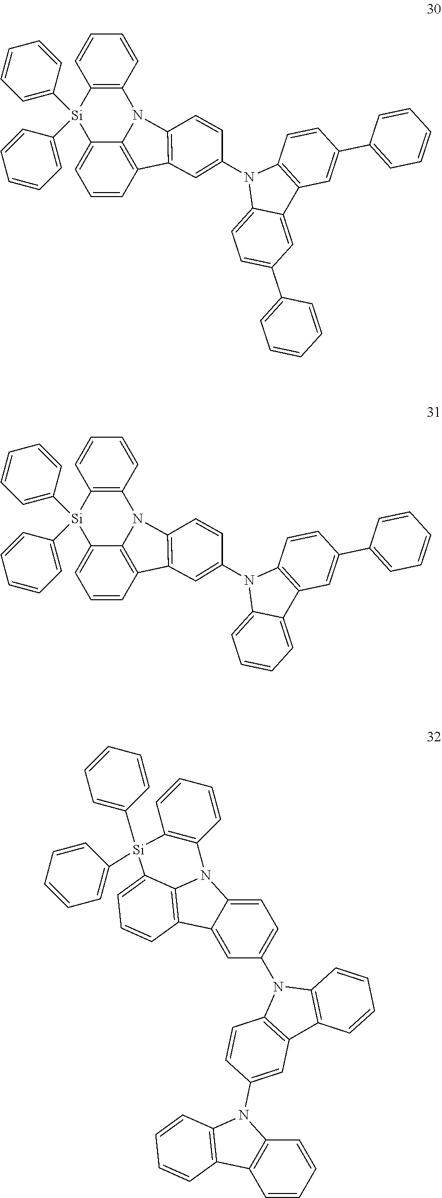 [SMILES: c1ccc(-c2ccc3c(c2)c2cc(-c4ccccc4)ccc2n3-c2ccc3c(c2)c2cccc4c2n3-c2ccccc2[Si]4(c2ccccc2)c2ccccc2)cc1 ; c1ccc(-c2ccc3c(c2)c2ccccc2n3-c2ccc3c(c2)c2cccc4c2n3-c2ccccc2[Si]4(c2ccccc2)c2ccccc2)cc1 ; c1ccc([Si]2(c3ccccc3)c3ccccc3-n3c4ccc(-n5c6ccccc6c6cc(-n7c8ccccc8c8ccccc87)ccc65)cc4c4cccc2c43)cc1]

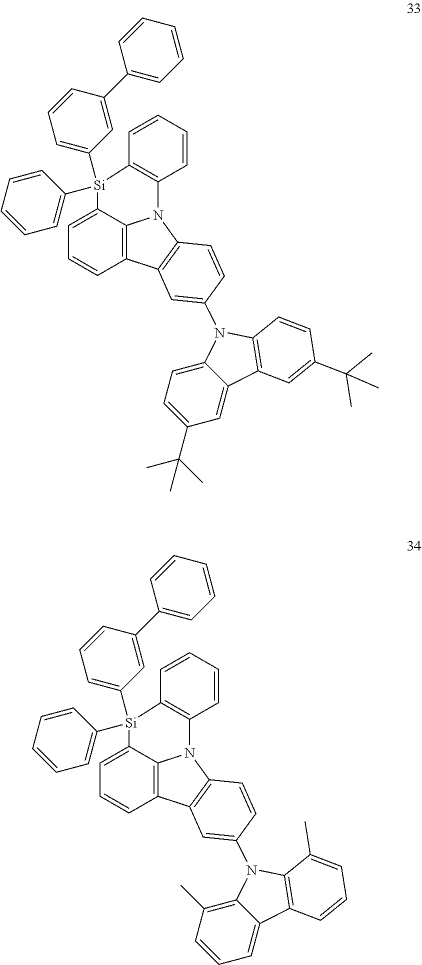 [SMILES: CC(C)(C)c1ccc2c(c1)c1cc(C(C)(C)C)ccc1n2-c1ccc2c(c1)c1cccc3c1n2-c1ccccc1[Si]3(c1ccccc1)c1cccc(-c2ccccc2)c1 ; Cc1cccc2c3cccc(C)c3n(-c3ccc4c(c3)c3cccc5c3n4-c3ccccc3[Si]5(c3ccccc3)c3cccc(-c4ccccc4)c3)c12]

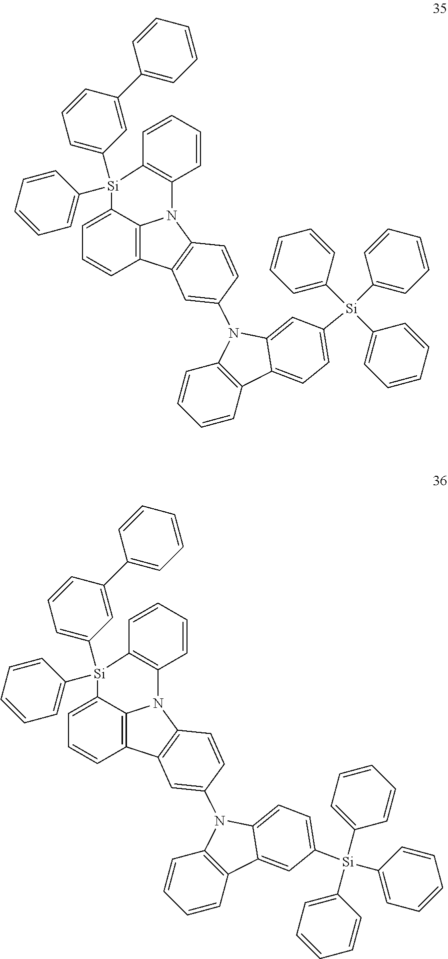 [SMILES: c1ccc(-c2cccc([Si]3(c4ccccc4)c4ccccc4-n4c5ccc(-n6c7ccccc7c7ccc([Si](c8ccccc8)(c8ccccc8)c8ccccc8)cc76)cc5c5cccc3c54)c2)cc1 ; c1ccc(-c2cccc([Si]3(c4ccccc4)c4ccccc4-n4c5ccc(-n6c7ccccc7c7cc([Si](c8ccccc8)(c8ccccc8)c8ccccc8)ccc76)cc5c5cccc3c54)c2)cc1]

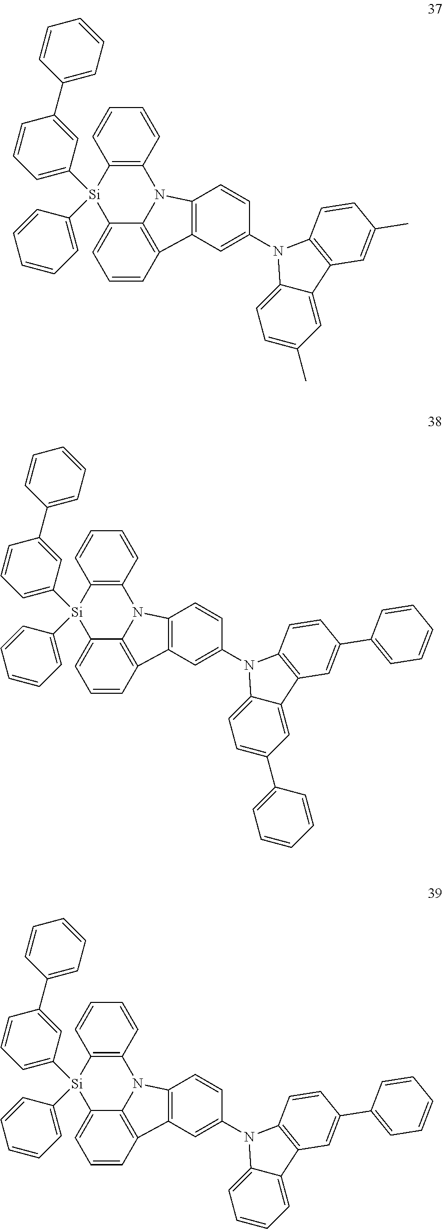 [SMILES: Cc1ccc2c(c1)c1cc(C)ccc1n2-c1ccc2c(c1)c1cccc3c1n2-c1ccccc1[Si]3(c1ccccc1)c1cccc(-c2ccccc2)c1 ; c1ccc(-c2cccc([Si]3(c4ccccc4)c4ccccc4-n4c5ccc(-n6c7ccc(-c8ccccc8)cc7c7cc(-c8ccccc8)ccc76)cc5c5cccc3c54)c2)cc1 ; c1ccc(-c2cccc([Si]3(c4ccccc4)c4ccccc4-n4c5ccc(-n6c7ccccc7c7cc(-c8ccccc8)ccc76)cc5c5cccc3c54)c2)cc1]

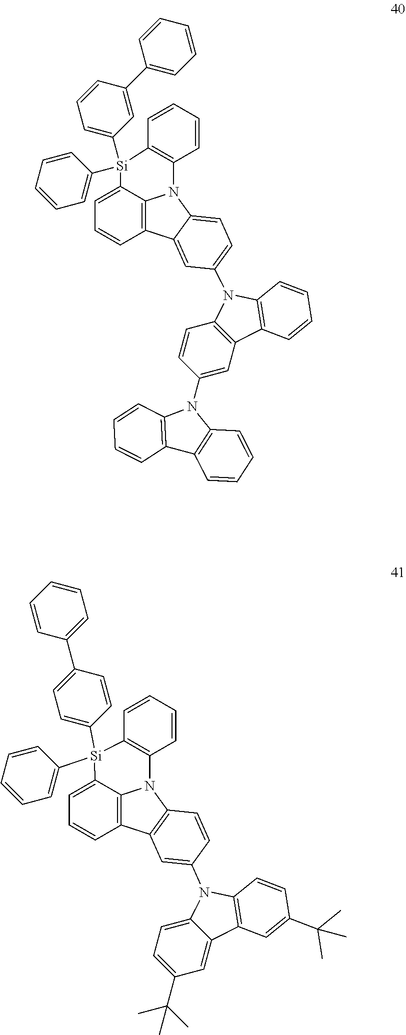 [SMILES: c1ccc(-c2cccc([Si]3(c4ccccc4)c4ccccc4-n4c5ccc(-n6c7ccccc7c7cc(-n8c9ccccc9c9ccccc98)ccc76)cc5c5cccc3c54)c2)cc1 ; CC(C)(C)c1ccc2c(c1)c1cc(C(C)(C)C)ccc1n2-c1ccc2c(c1)c1cccc3c1n2-c1ccccc1[Si]3(c1ccccc1)c1ccc(-c2ccccc2)cc1]

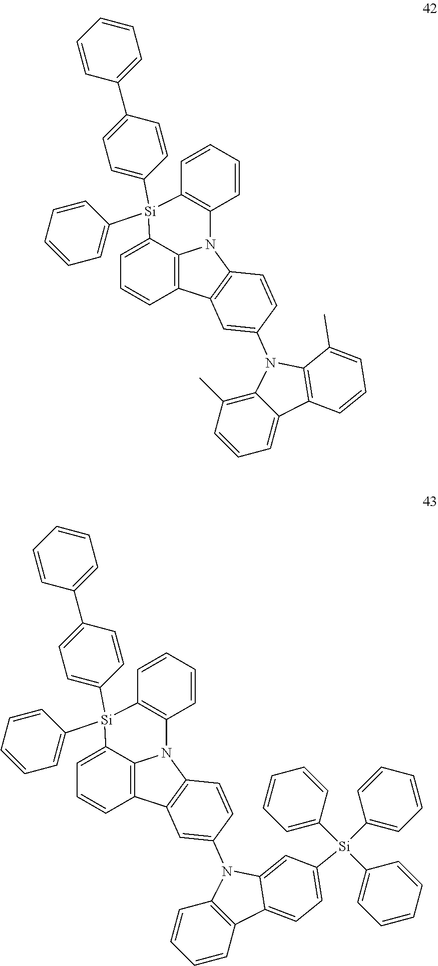 [SMILES: Cc1cccc2c3cccc(C)c3n(-c3ccc4c(c3)c3cccc5c3n4-c3ccccc3[Si]5(c3ccccc3)c3ccc(-c4ccccc4)cc3)c12 ; c1ccc(-c2ccc([Si]3(c4ccccc4)c4ccccc4-n4c5ccc(-n6c7ccccc7c7ccc([Si](c8ccccc8)(c8ccccc8)c8ccccc8)cc76)cc5c5cccc3c54)cc2)cc1]

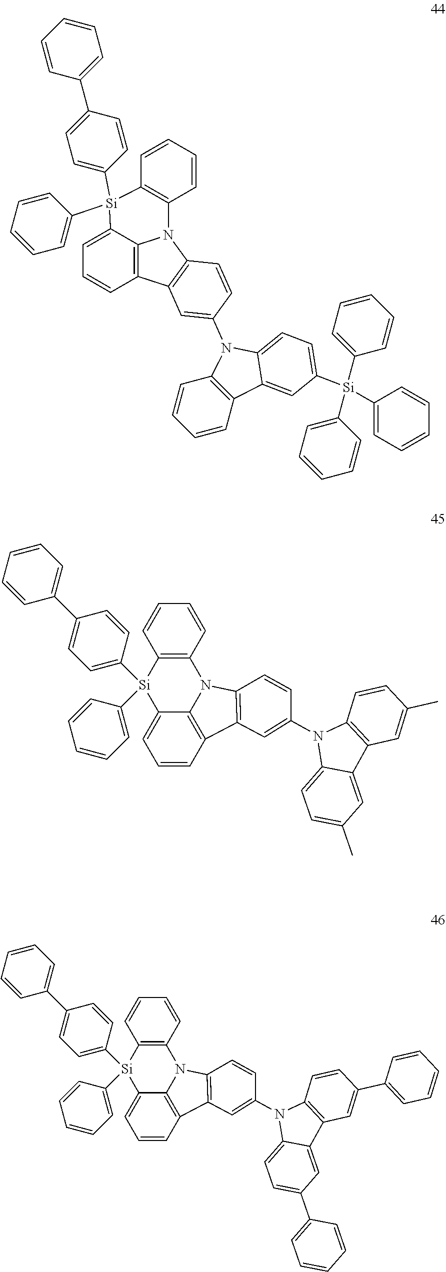 [SMILES: c1ccc(-c2ccc([Si]3(c4ccccc4)c4ccccc4-n4c5ccc(-n6c7ccccc7c7cc([Si](c8ccccc8)(c8ccccc8)c8ccccc8)ccc76)cc5c5cccc3c54)cc2)cc1 ; Cc1ccc2c(c1)c1cc(C)ccc1n2-c1ccc2c(c1)c1cccc3c1n2-c1ccccc1[Si]3(c1ccccc1)c1ccc(-c2ccccc2)cc1 ; c1ccc(-c2ccc([Si]3(c4ccccc4)c4ccccc4-n4c5ccc(-n6c7ccc(-c8ccccc8)cc7c7cc(-c8ccccc8)ccc76)cc5c5cccc3c54)cc2)cc1]

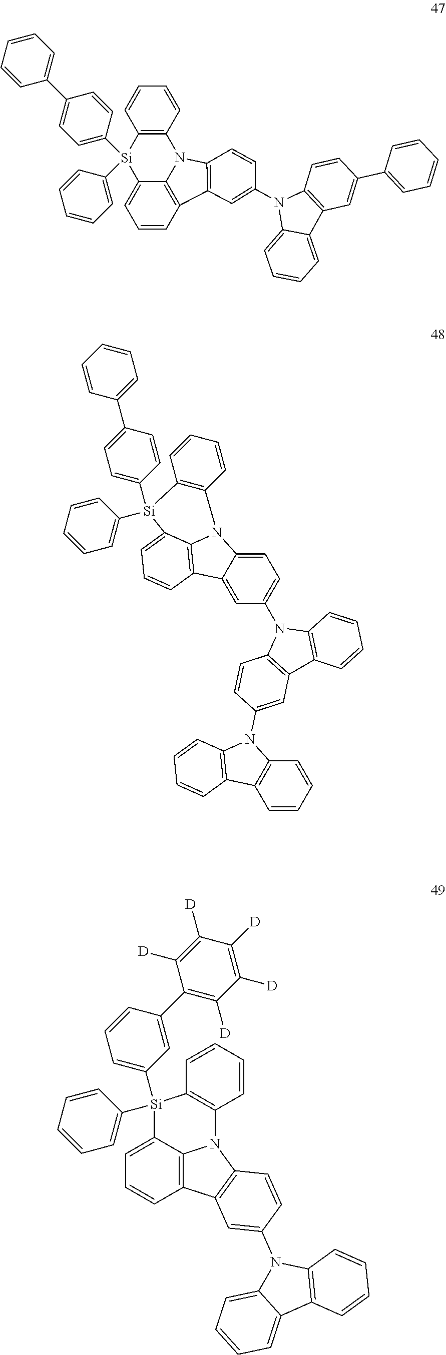 [SMILES: c1ccc(-c2ccc([Si]3(c4ccccc4)c4ccccc4-n4c5ccc(-n6c7ccccc7c7cc(-c8ccccc8)ccc76)cc5c5cccc3c54)cc2)cc1 ; c1ccc(-c2ccc([Si]3(c4ccccc4)c4ccccc4-n4c5ccc(-n6c7ccccc7c7cc(-n8c9ccccc9c9ccccc98)ccc76)cc5c5cccc3c54)cc2)cc1 ; [2H]c1c([2H])c([2H])c(-c2cccc([Si]3(c4ccccc4)c4ccccc4-n4c5ccc(-n6c7ccccc7c7ccccc76)cc5c5cccc3c54)c2)c([2H])c1[2H]]

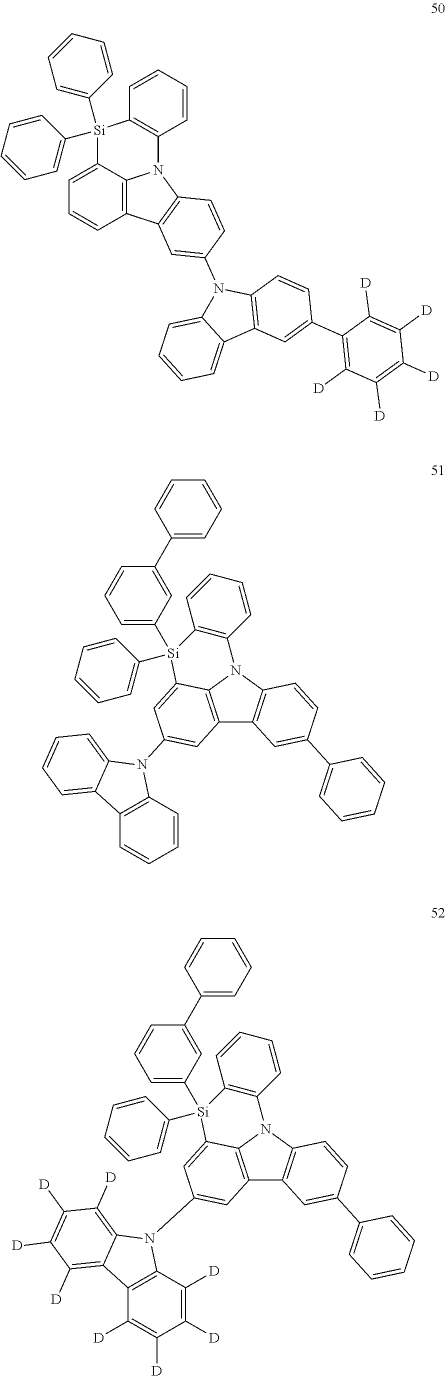 [SMILES: [2H]c1c([2H])c([2H])c(-c2ccc3c(c2)c2ccccc2n3-c2ccc3c(c2)c2cccc4c2n3-c2ccccc2[Si]4(c2ccccc2)c2ccccc2)c([2H])c1[2H] ; c1ccc(-c2cccc([Si]3(c4ccccc4)c4ccccc4-n4c5ccc(-c6ccccc6)cc5c5cc(-n6c7ccccc7c7ccccc76)cc3c54)c2)cc1 ; [2H]c1c([2H])c([2H])c2c(c1[2H])c1c([2H])c([2H])c([2H])c([2H])c1n2-c1cc2c3c(c1)c1cc(-c4ccccc4)ccc1n3-c1ccccc1[Si]2(c1ccccc1)c1cccc(-c2ccccc2)c1]

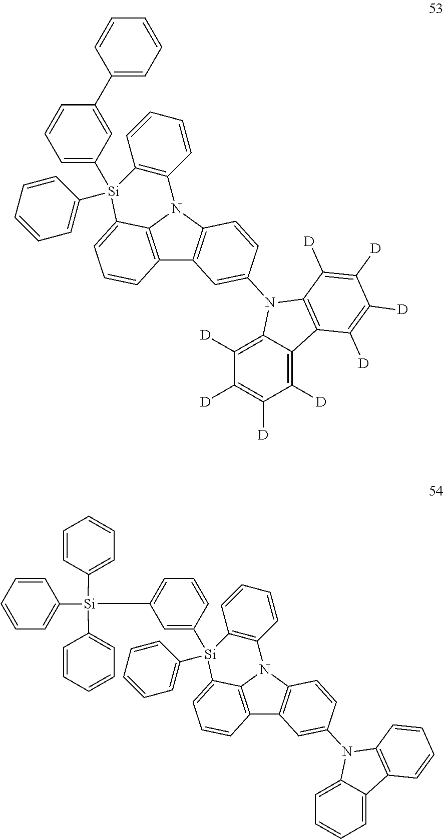 [SMILES: [2H]c1c([2H])c([2H])c2c(c1[2H])c1c([2H])c([2H])c([2H])c([2H])c1n2-c1ccc2c(c1)c1cccc3c1n2-c1ccccc1[Si]3(c1ccccc1)c1cccc(-c2ccccc2)c1 ; c1ccc([Si](c2ccccc2)(c2ccccc2)c2cccc([Si]3(c4ccccc4)c4ccccc4-n4c5ccc(-n6c7ccccc7c7ccccc76)cc5c5cccc3c54)c2)cc1]

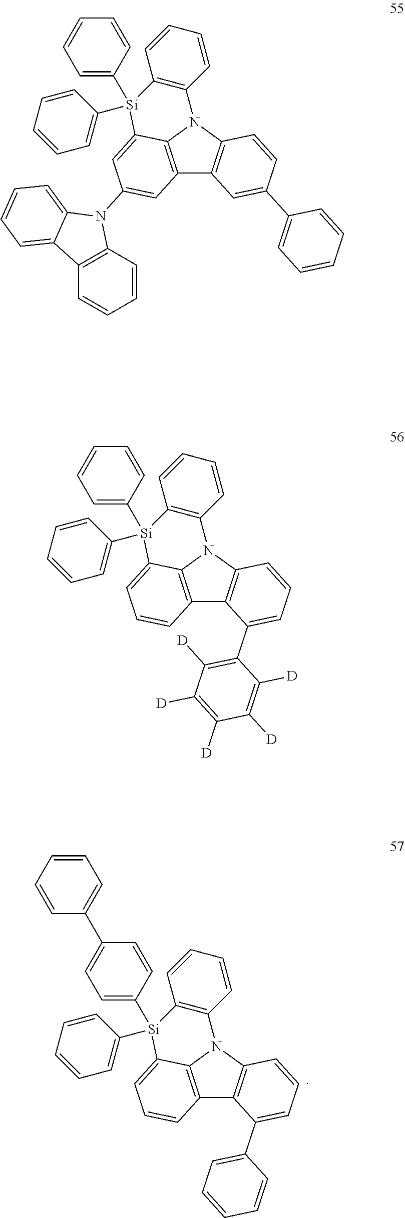 [SMILES: c1ccc(-c2ccc3c(c2)c2cc(-n4c5ccccc5c5ccccc54)cc4c2n3-c2ccccc2[Si]4(c2ccccc2)c2ccccc2)cc1 ; [2H]c1c([2H])c([2H])c(-c2cccc3c2c2cccc4c2n3-c2ccccc2[Si]4(c2ccccc2)c2ccccc2)c([2H])c1[2H] ; c1ccc(-c2ccc([Si]3(c4ccccc4)c4ccccc4-n4c5cccc(-c6ccccc6)c5c5cccc3c54)cc2)cc1]

The polycyclic compound of an embodiment includes a skeleton in which a triphenylsilane group, which may cause steric hindrance effects on a carbazole group, is fused with the carbazole group, may reduce the generation of exciplex due to the intermolecular interaction, and thus may exhibit excellent or suitable color purity when utilized as an emission layer material, and may have a relatively high lowest triplet excitation energy level (T1 level).

The polycyclic compound represented by Formula 1 of an embodiment may be a luminescent material having a luminescence center wavelength in a wavelength region of about 430 nm to about 480 nm. The emission layer EML of the light emitting element ED may include the polycyclic compound represented by Formula 1 of an embodiment, thereby emitting blue light. For example, the emission layer EML of the light emitting element ED of an embodiment may be to emit blue light in a region of about 480 nm or less. However, the embodiment of the present disclosure is not limited thereto, and the emission layer EML may be to emit green light or red light.

In some embodiments, the emission layer EML includes a host and a dopant, and may include the above-described polycyclic compound as a host. The polycyclic compound represented by Formula 1 of an embodiment may be a host material of the emission layer.

For example, the emission layer EML in the light emitting element ED of an embodiment may include a host for emitting phosphorescence and a dopant for emitting phosphorescence, and may include the above-described polycyclic compound of an embodiment as a host for emitting phosphorescence. In some embodiments, the emission layer EML in the light emitting element ED of an embodiment may include a host for emitting fluorescence and a dopant for emitting fluorescence, and may include the above-described polycyclic compound of an embodiment as a host for emitting fluorescence.

The emission layer EML in the light emitting element ED of an embodiment may include a host for emitting delayed fluorescence and a dopant for emitting delayed fluorescence, and may include the above-described polycyclic compound of an embodiment as a host for emitting delayed fluorescence. The emission layer EML in the light emitting element ED of an embodiment may include a host for emitting blue thermally activated delayed fluorescence (TADF) and a dopant for emitting blue TADF, and may include the above-described polycyclic compound of an embodiment as a host for emitting blue TADF. The emission layer EML may include at least one selected from among the polycyclic compounds represented by Compound Group 1 as described above as a host material of the emission layer.

In some embodiments, in the light emitting element ED of an embodiment, the emission layer EML may further include a suitable material. The emission layer EML may include one or more anthracene derivatives, pyrene derivatives, fluoranthene derivatives, chrysene derivatives, dehydrobenzanthracene derivatives, and/or triphenylene derivatives. In an embodiment, the emission layer EML may include one or more anthracene derivatives and/or pyrene derivatives.

In each light emitting element ED of embodiments illustrated in FIGS. 3 to 6, the emission layer EML may include a host and a dopant, and the emission layer EML may include a compound represented by Formula E-1. The compound represented by Formula E-1 may be utilized as a fluorescence host material or a delayed fluorescence host material.

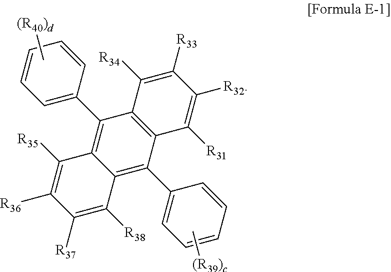

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In some embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer of 0 to 5.

The compound represented by Formula E-1 may be any one selected from among the compounds represented by Compound Group E-1:

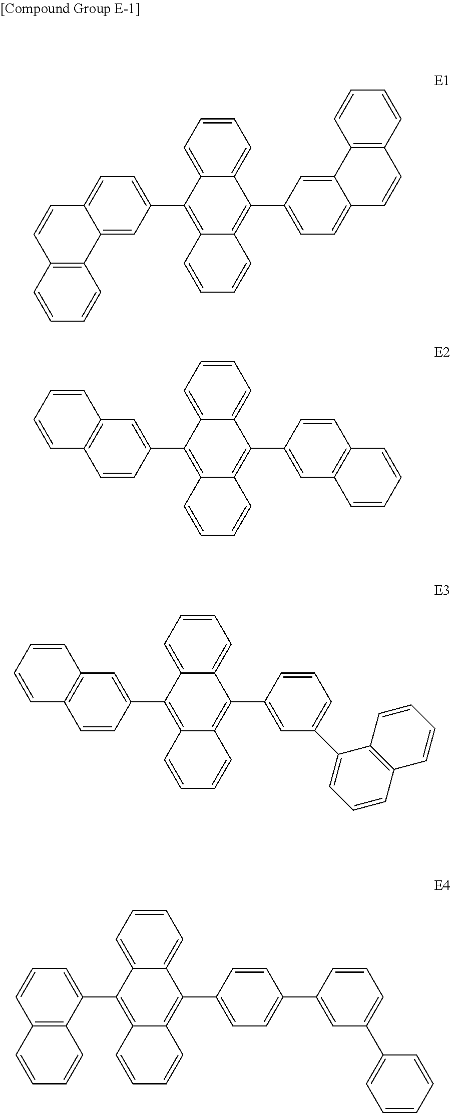

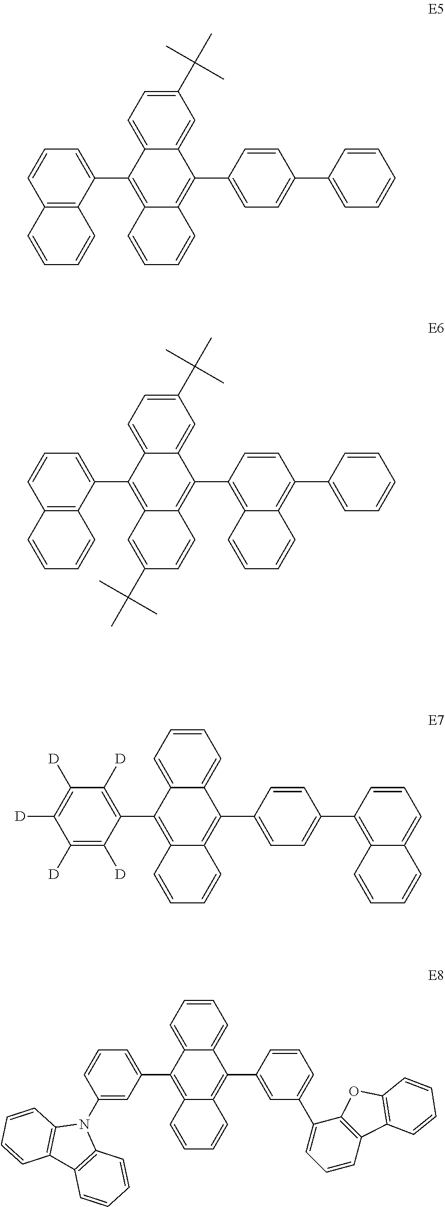

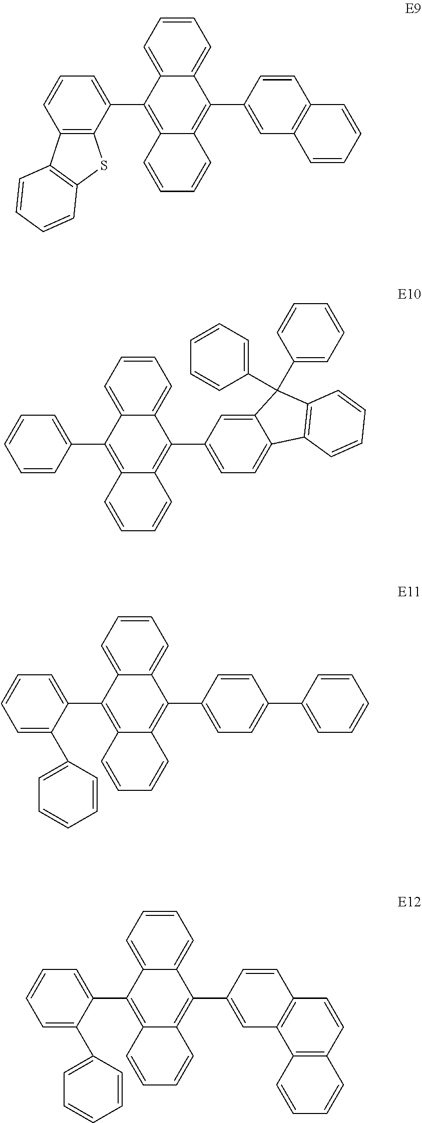

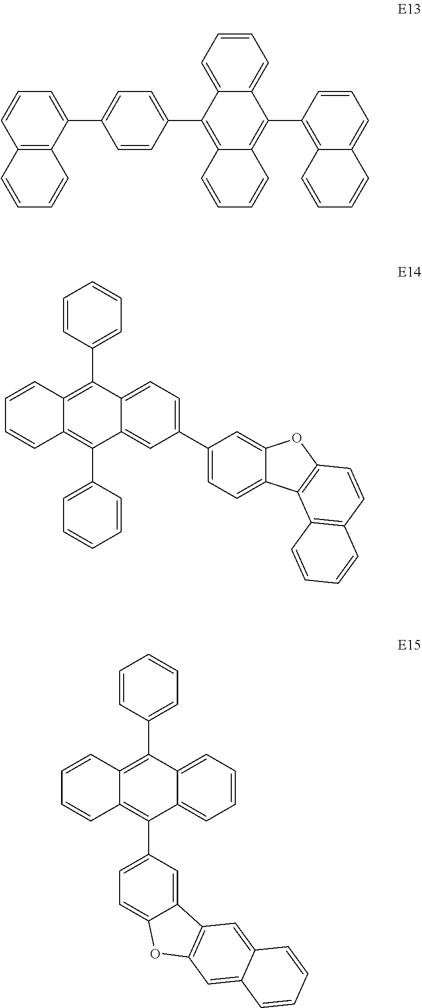

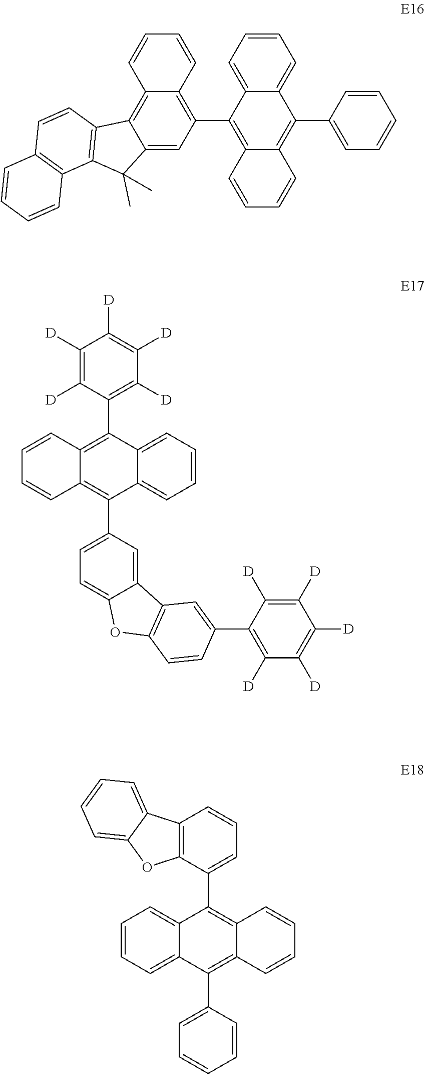

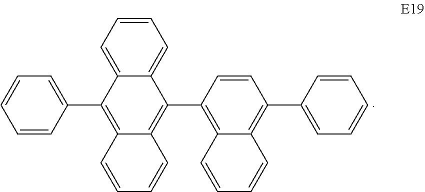 [SMILES: c1ccc(-c2ccc(-c3c4ccccc4c(-c4ccccc4)c4ccccc34)c3ccccc23)cc1]

In an embodiment, the emission layer EML may further include a compound represented by Formula E-2a or Formula E-2b. The compound represented by Formula E-2a or Formula E-2b may be utilized as a phosphorescence host material or a delayed fluorescence host material.

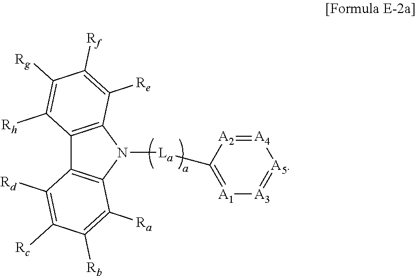

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or more, a plurality of La's may each independently be a substituted or unsubstituted arylene group having 6 to 30 ring-forming carbon atoms, or a substituted or unsubstituted heteroarylene group having 2 to 30 ring-forming carbon atoms.

In addition, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted oxide group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In an embodiment, Rₐ to Rᵢ may be bonded to an adjacent group to form a hydrocarbon ring or a heterocycle containing N, O, S, etc. as a ring-forming atom.

In some embodiments, in Formula E-2a, two or three selected from among A₁ to A₅ may be N, and the rest (e.g., a remainder from among A₁ to A₅) may be CRᵢ.

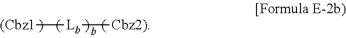

In Formula E-2b, Cbz1 and Cbz2 may each independently be an unsubstituted carbazole group, or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, b may be an integer of 0 to 10, and when b is an integer of 2 or more, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from among the compounds of Compound Group E-2. However, the compounds listed in Compound Group E-2 are examples, and the compound represented by Formula E-2a or Formula E-2b is not limited to those represented in Compound Group E-2.

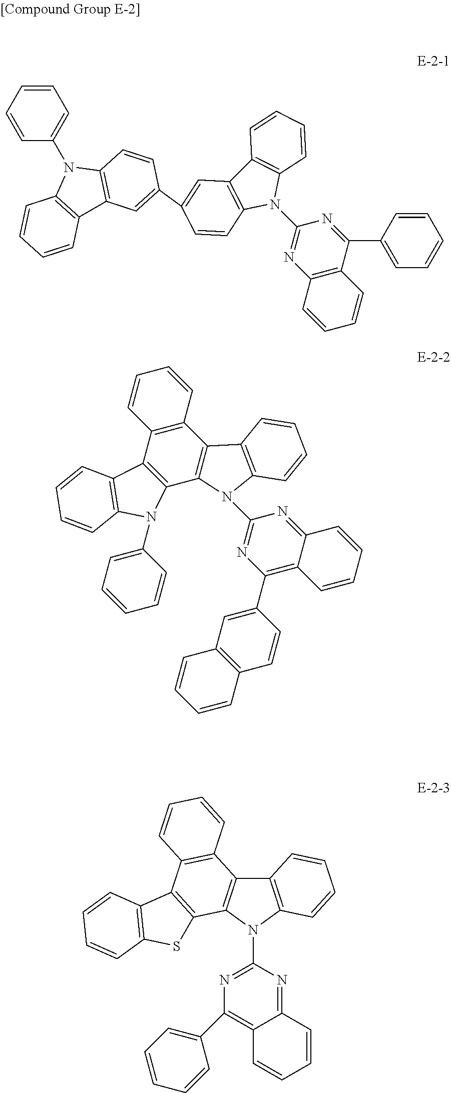 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

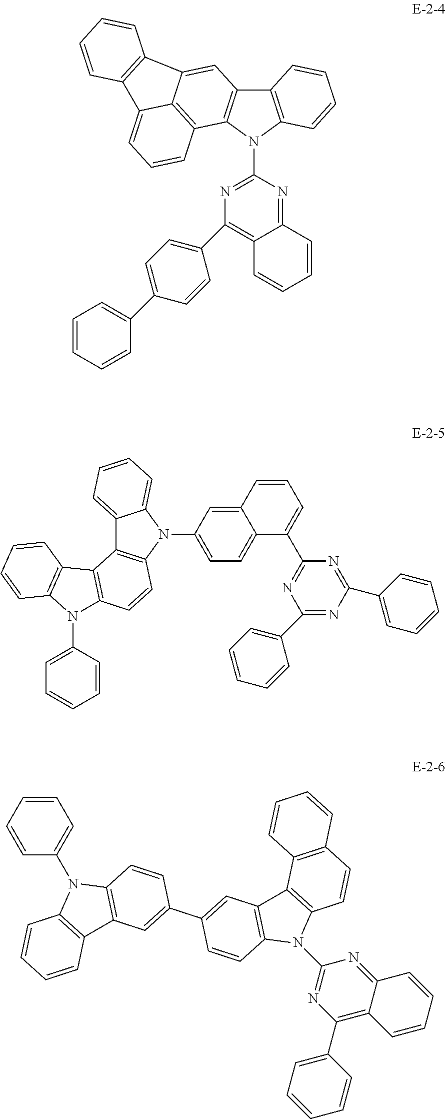 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

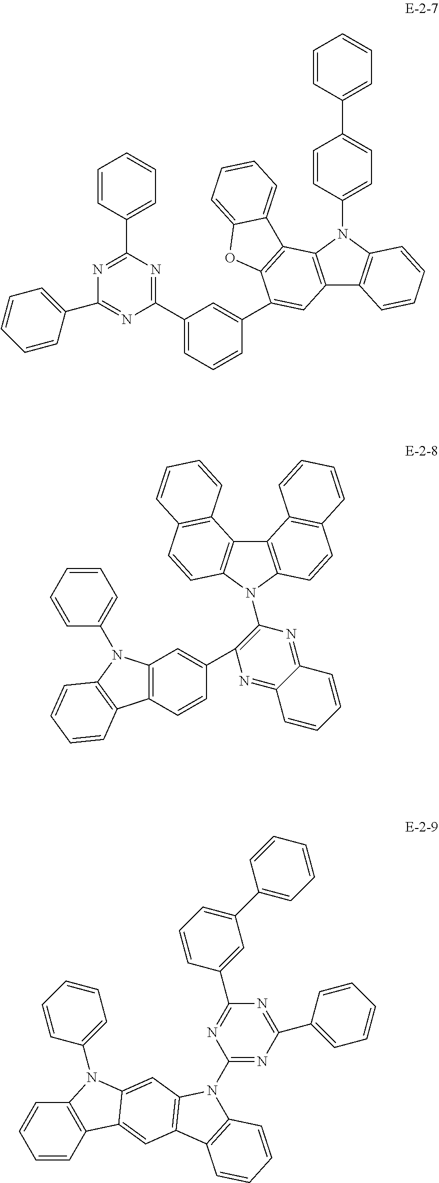 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

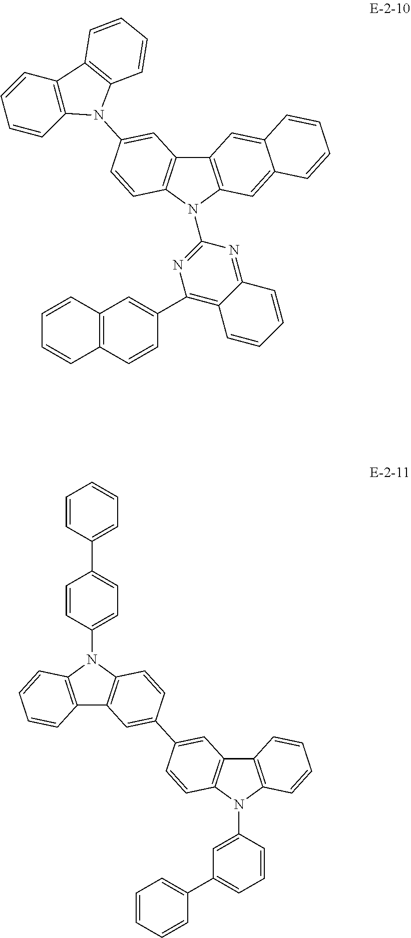 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

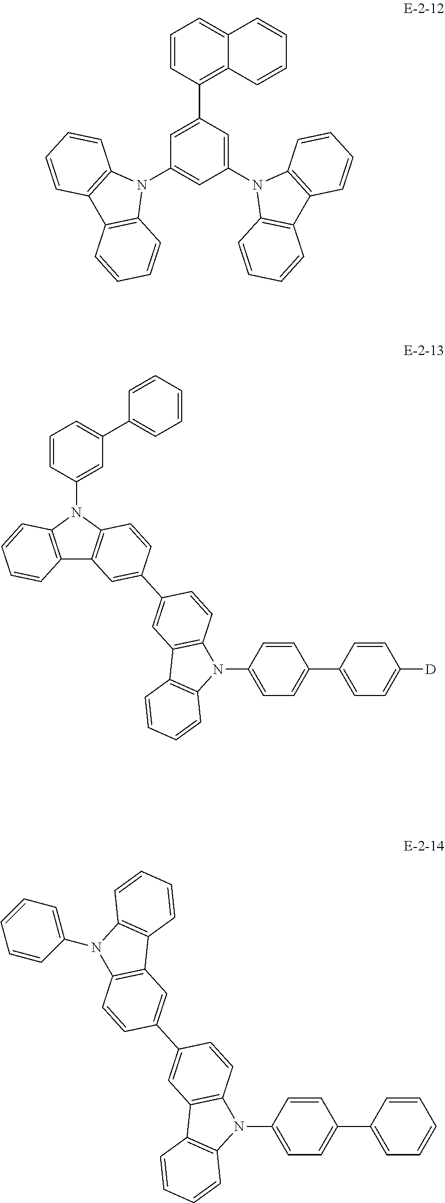 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1]

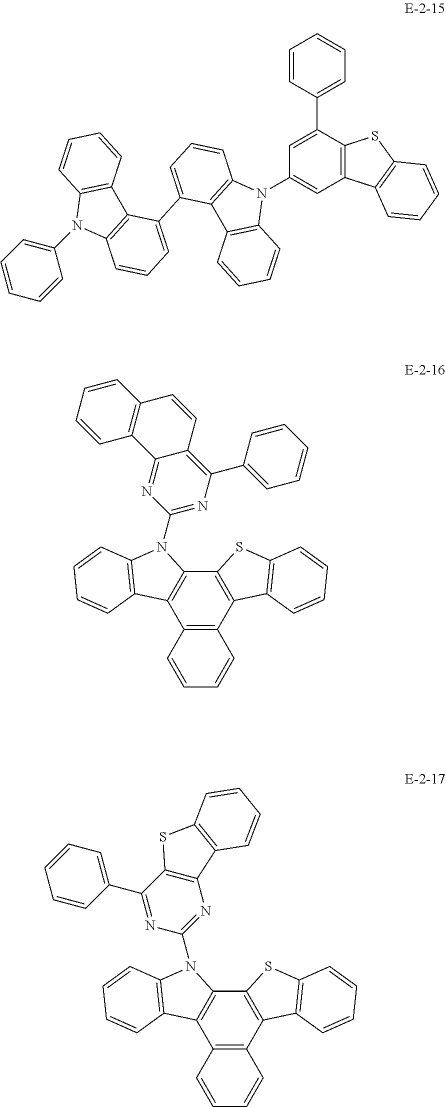 [SMILES: c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1]

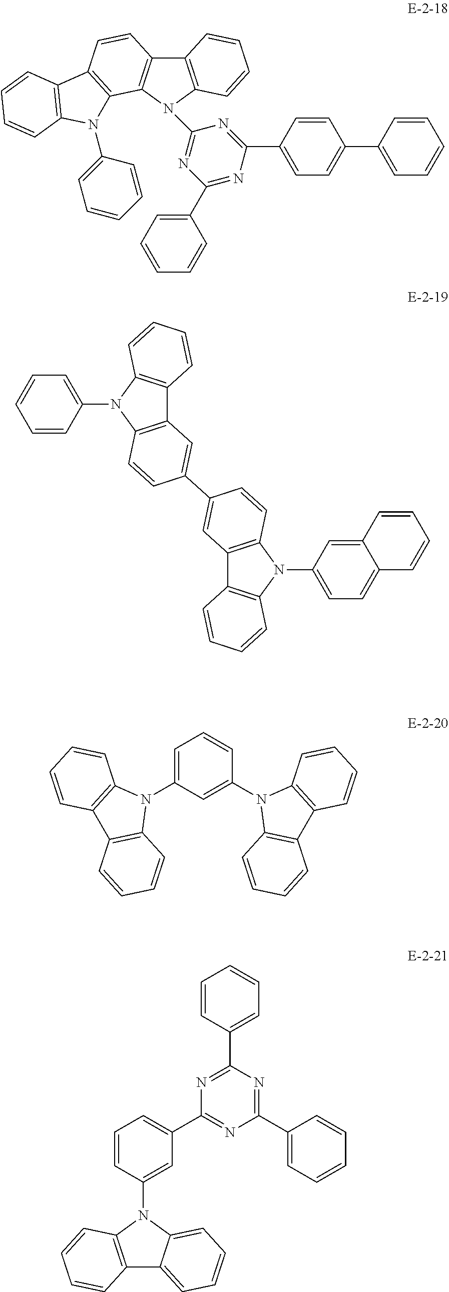 [SMILES: c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

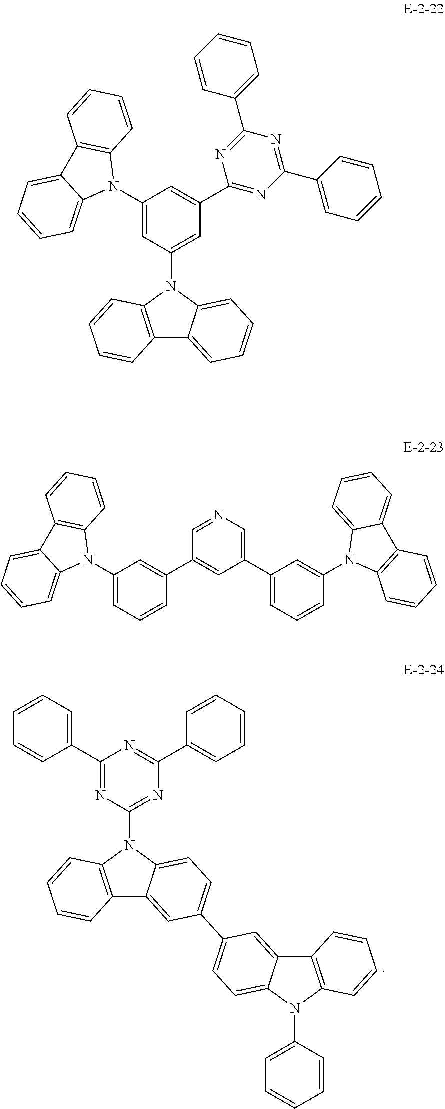 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material suitable in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyI)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, the embodiment of the present disclosure is not limited thereto, for example, tris(8-hydroxyquinolino)aluminum (Alq3), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as a host material.

The emission layer EML may further include a compound represented by Formula M-a or Formula M-b. The compound represented by Formula M-a or Formula M-b may be utilized as a phosphorescent dopant material. In some embodiments, the compound represented by Formula M-a or Formula M-b in an embodiment may be utilized as an auxiliary dopant material.

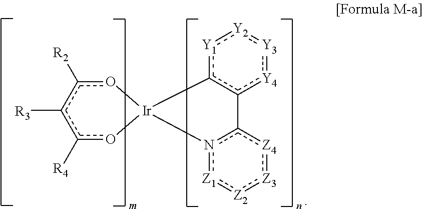

In Formula M-a above, Y₁ to Y₄ and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m may be 0 or 1, and n may be 2 or 3. In Formula M-a, when m is 0, n is 3, and when m is 1, n is 2.

The compound represented by Formula M-a may be represented by any one selected from among Compound M-a1 to Compound M-a25. However, Compounds M-a1 to M-a25 are examples, and the compound represented by Formula M-a is not limited to those represented by Compounds M-a1 to M-a25.

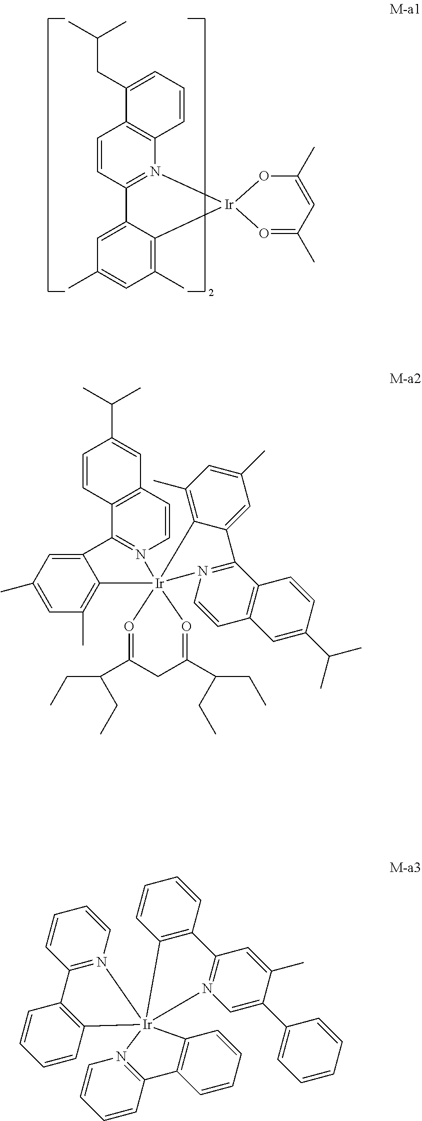

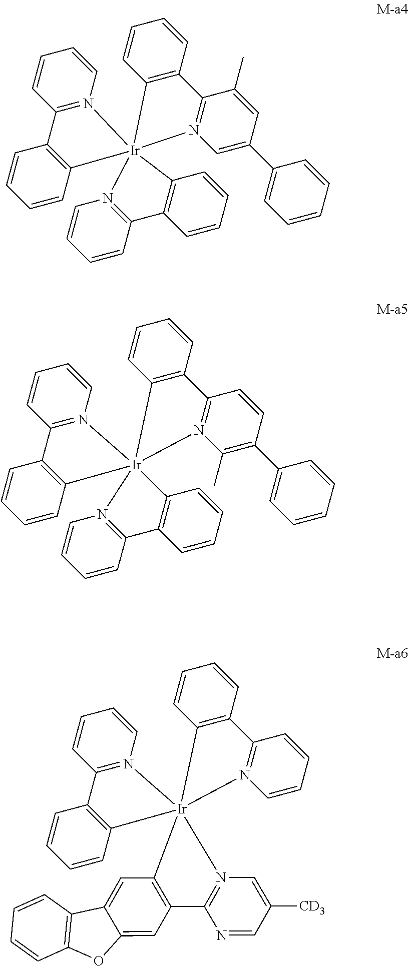

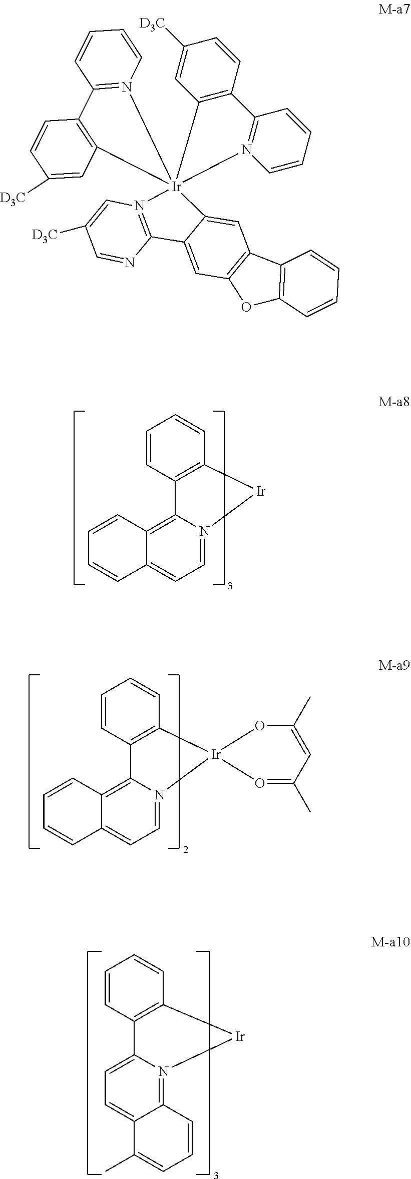

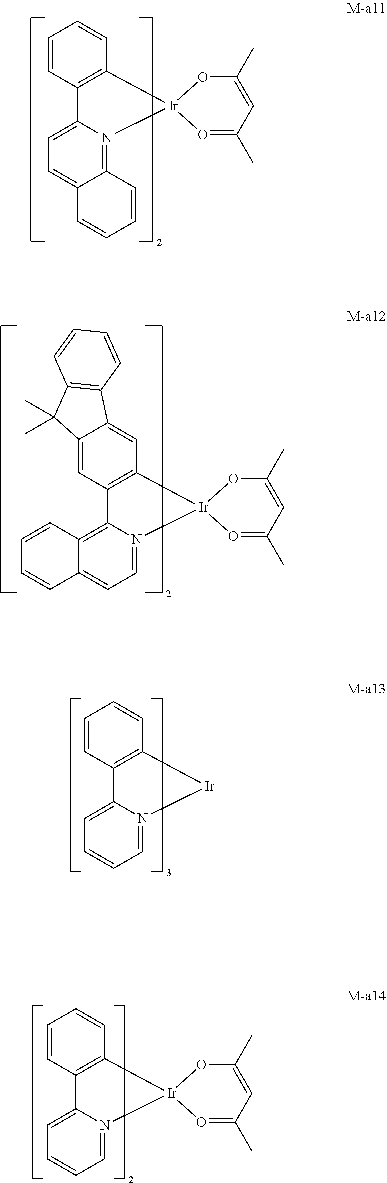

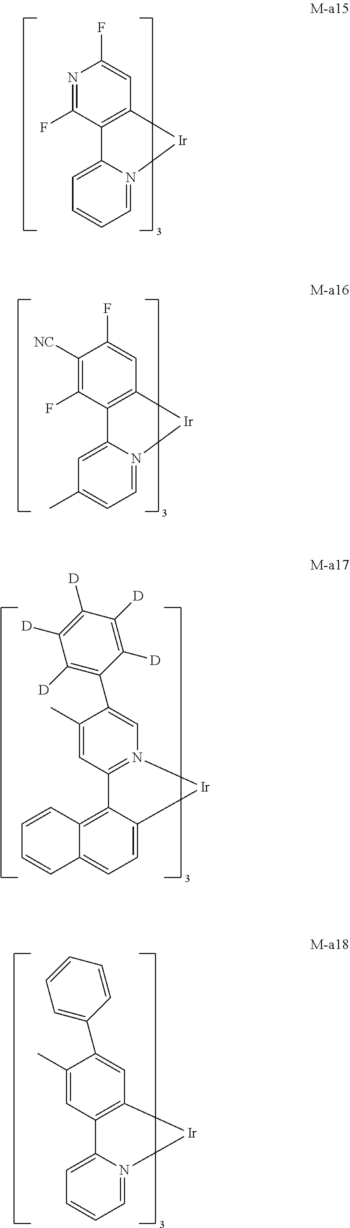

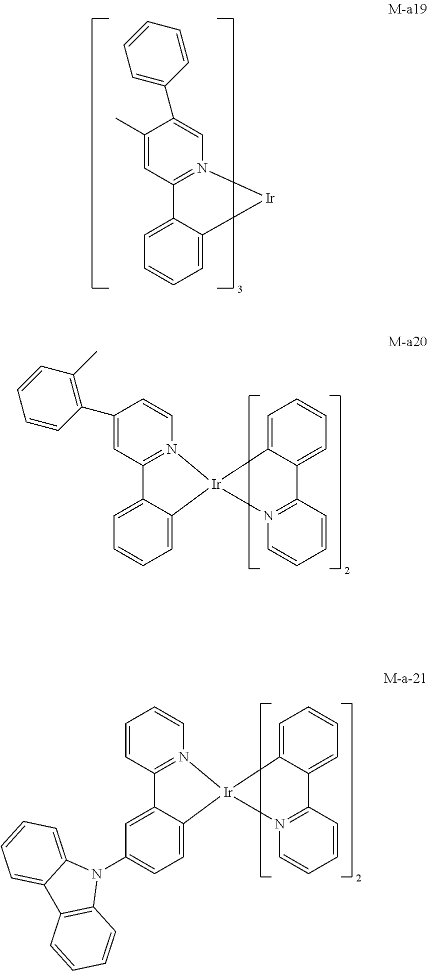

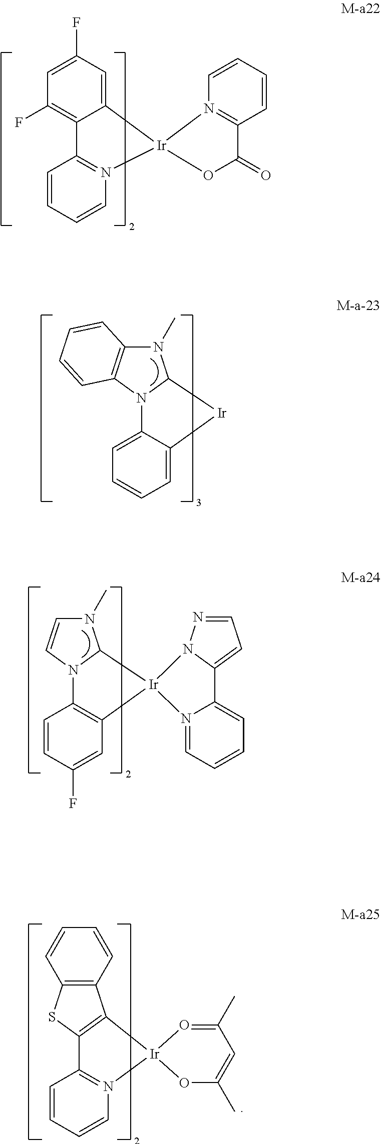

Compound M-a1 and Compound M-a2 may be utilized as a red dopant material, and Compound M-a3 to Compound M-a7 may be utilized as a green dopant material.

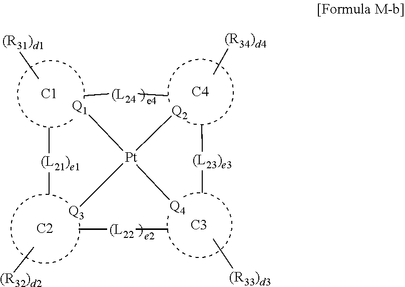

In Formula M-b, Q₁ to Q₄ may each independently be C or N, and C1 to C4 may each independently be a substituted or unsubstituted hydrocarbon ring having 5 to 30 ring-forming carbon atoms, or a substituted or unsubstituted heterocycle having 2 to 30 ring-forming carbon atoms. L₂₁ to L₂₄ may each independently be a direct linkage,

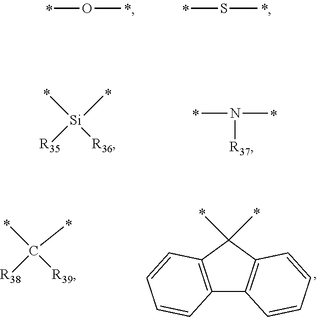

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, and e1 to e4 may each independently be 0 or 1. R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and d1 to d4 may each independently be an integer of 0 to 4.

The compound represented by Formula M-b may be utilized as a blue phosphorescent dopant or a green phosphorescent dopant.

The compound represented by Formula M-b may be represented by any one selected from among the compounds below. However, the compounds below are examples, and the compound represented by Formula M-b is not limited to those represented by the compounds below.

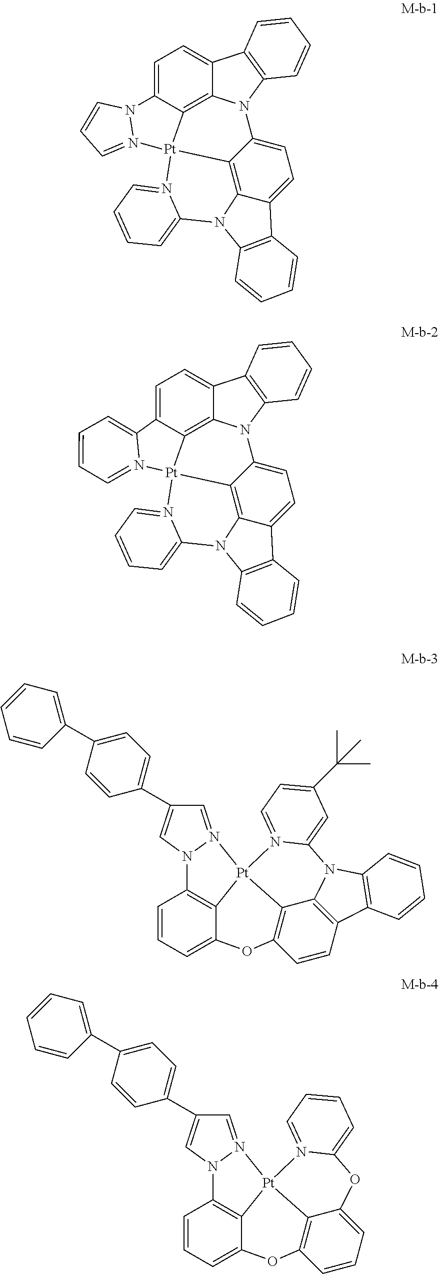

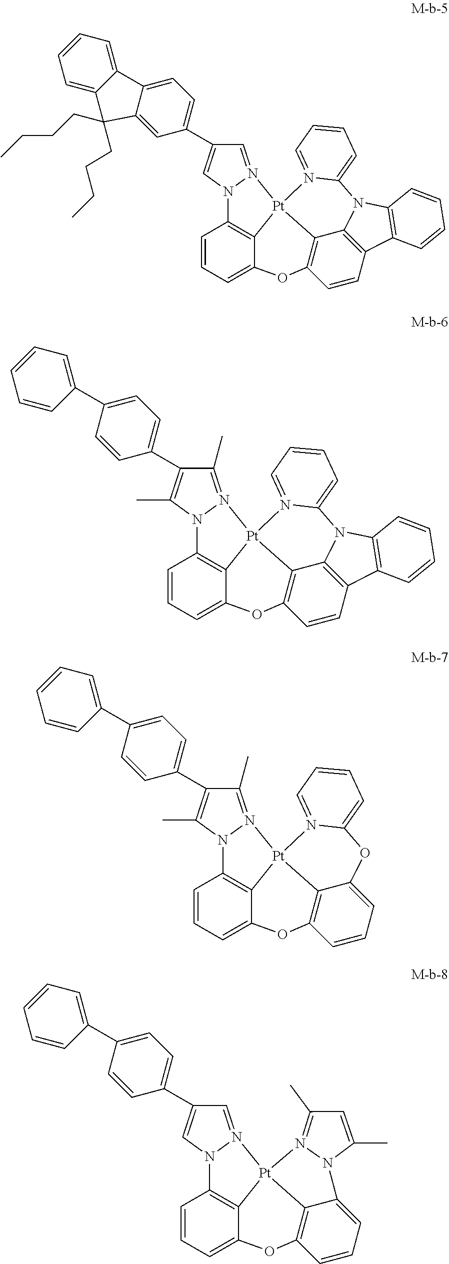

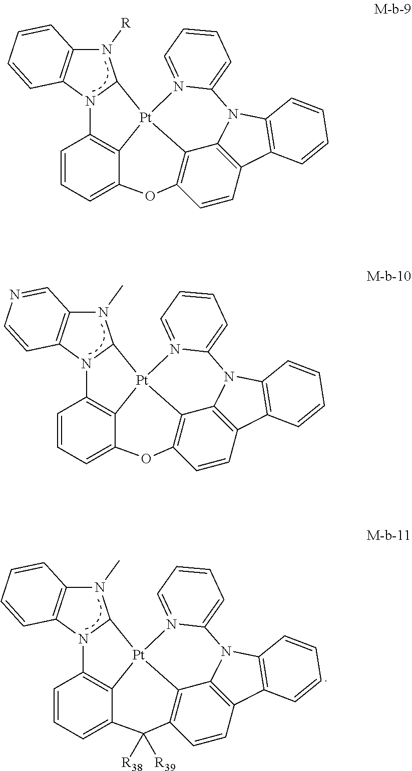

In the compounds, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layer EML may further include a compound represented by any one selected from among Formula F-a to Formula F-c. The compound represented by Formula F-a or Formula F-c may be utilized as a fluorescence dopant material.

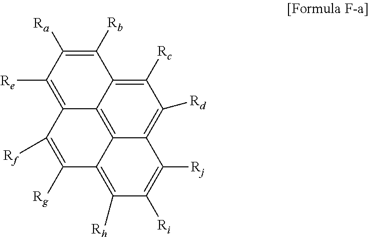

In Formula F-a above, two groups selected from among Rₐ to Rⱼ may each independently be substituted with *—NAr₁Ar₂ The others (e.g., the rest of Rₐ to Rⱼ), which are not substituted with *—NAr₁Ar₂ among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *—NAr₁Ar₂ An and Are may each independently be a substituted or unsubstituted aryl group having 6 to 30 ring-forming carbon atoms, or a substituted or unsubstituted heteroaryl group having 2 to 30 ring-forming carbon atoms. For example, at least one of An or Are may be a heteroaryl group containing 0 or S as a ring-forming atom.

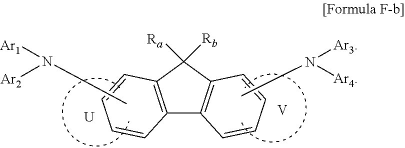

In Formula F-b above, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In an embodiment, An to Ara may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, in Formula F-b, when the number of U or V is 1, one ring indicated by U or V forms a condensed ring at the designated part, and when the number of U or V is 0, it indicates that no ring indicated by U or V is present. For example, when the number of U is 0 and the number of V is 1, or when the number of U is 1 and the number of V is 0, the fused ring having a fluorene core in Formula F-b may be a cyclic compound having four rings. In addition, when each number of U and V is 0, the fused ring in Formula F-b may be a cyclic compound having three rings. In addition, when each number of U and V is 1, the fused ring having a fluorene core in Formula F-b may be a cyclic compound having five rings.

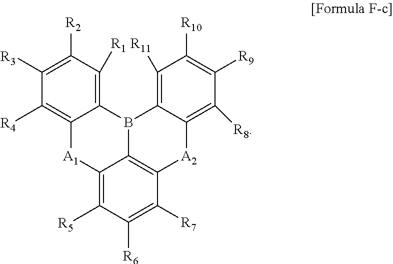

In Formula F-c, A₁ and A₂ may each independently be 0, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In Formula F-c, A₁ and A₂ may each independently be bonded to substituents of an adjacent ring to form a condensed ring. For example, when A₁ and A₂ may each independently be NRₘ, A₁ may be bonded to R₄ or R₅ to form a ring. In some embodiments, A₂ may be bonded to R₇ or R₈ to form a ring.

In an embodiment, the emission layer EML may include, as a suitable dopant material, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and/or N-(4-((E)-2-(6-((E)-4-(diphenylamino)styryl)naphthalen-2-yl)vinyl)phenyl)-N-phenylbenz enamine (N-BDAVBi)), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), etc.

The emission layer EML may include a suitable phosphorescent dopant material. For example, a metal complex containing iridium (Ir), platinum (Pt), osmium (Os), gold (Au), titanium (Ti), zirconium (Zr), hafnium (Hf), europium (Eu), terbium (Tb), and/or thulium (Tm) may be utilized as a phosphorescent dopant. For example, iridium(III) bis(4,6-difluorophenylpyridinato-N,C2′)picolinate (Flrpic), bis(2,4-difluorophenylpyridinato)-tetrakis(1-pyrazolyl)borate (Firs), and/or platinum octaethyl porphyrin (PtOEP) may be utilized as a phosphorescent dopant. However, the embodiment of the present disclosure is not limited thereto.

The emission layer EML may include a quantum dot material. The core of the quantum dot may be selected from a Group II-VI compound, a Group III-VI compound, a Group compound, a Group III-V compound, a Group III-II-V compound, a Group IV-VI compound, a Group IV element, a Group IV compound, or a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS,

CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ and/or In₂Se₃, a ternary compound such as InGaS₃ and/or InGaSe₃, or any combination thereof.

The Group compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, and a quaternary compound such as AgInGaS₂ and/or CuInGaS₂.

The Group III-V compound may be selected from the group consisting of a binary compound selected from the group consisting of GaN, GaP, GaAs, GaSb, AIN, AIP, AlAs, AlSb, InN, InP, InAs, InSb, and a mixture thereof, a ternary compound selected from the group consisting of GaNP, GaNAs, GaNSb, GaPAs, GaPSb, AINP, AINAs, AINSb, AIPAs, AIPSb, InGaP, InAIP, InNP, InNAs, InNSb, InPAs, InPSb, and a mixture thereof, and a quaternary compound selected from the group consisting of GaAINP, GaAINAs, GaAINSb, GaAIPAs, GaAIPSb, GaInNP, GaInNAs, GaInNSb,

GaInPAs, GaInPSb, InAINP, InAINAs, InAINSb, InAIPAs, InAIPSb, and a mixture thereof. In some embodiments, the Group III-V compound may further include a Group II metal. For example, InZnP, etc. may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In this case, the binary compound, the ternary compound, and/or the quaternary compound may be present in a particle with a substantially uniform concentration distribution, or may be present in the same particle with a partially different concentration distribution. In some embodiments, the quantum dot may have a core/shell structure in which one quantum dot is around (e.g., surrounds) another quantum dot. The core/shell structure may have a concentration gradient in which the concentration of elements present in the shell decreases toward the center of the core.

In some embodiments, the quantum dot may have the above-described core/shell structure including a core containing nanocrystals and a shell around (e.g., surrounding) the core. The shell of the quantum dot may serve as a protection layer to prevent or reduce the chemical deformation of the core so as to maintain semiconductor properties, and/or as a charging layer to impart electrophoresis properties to the quantum dot. The shell may be a single layer or a multilayer. An example of the shell of the quantum dot may include a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound such as MgAl₂O₄, CoFe₂O₄, NiFe₂O₄, and/or CoMn₂O₄, but the embodiment of the present disclosure is not limited thereto.

In some embodiments, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AlSb, etc., but the embodiment of the present disclosure is not limited thereto.

The quantum dot may have a full width at half maximum (FWHM) of a light emission wavelength spectrum of about 45 nm or less, about 40 nm or less, or about 30 nm or less, and color purity or color reproducibility may be improved in the above ranges. In some embodiments, light emitted through such a quantum dot is emitted in all directions, and thus a wide viewing angle may be improved.

In some embodiments, although the form of a quantum dot is not particularly limited as long as it is a form commonly utilized in the art, for example, a quantum dot in the form of spherical, pyramidal, multi-arm, and/or cubic nanoparticles, nanotubes, nanowires, nanofibers, nanoplate particles, etc. may be utilized.

The quantum dot may control the color of emitted light according to the particle size thereof, and accordingly, the quantum dot may have one or more suitable emission colors such as blue, red, and/or green.

In each light emitting element ED of embodiments illustrated in FIGS. 3 to 6, the electron transport region ETR is provided on the emission layer EML. The electron transport region ETR may include at least one of the hole blocking layer HBL, the electron transport layer ETL, or the electron injection layer EIL, but the embodiment of the present disclosure is not limited thereto.

In the present disclosure, the electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in the respective stated order from the emission layer EML, but the embodiment of the present disclosure is not limited thereto. The electron transport region ETR may have a thickness, for example, from about 1,000 Å to about 1,500 Å.

In each light emitting element ED of embodiments illustrated in FIGS. 3 to 6, the electron transport region ETR is provided on the emission layer EML. The electron transport region ETR may include at least one of the hole blocking layer HBL, the electron transport layer ETL, or the electron injection layer EIL, but the embodiment of the present disclosure is not limited thereto.

The electron transport region ETR may be formed by utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-1:

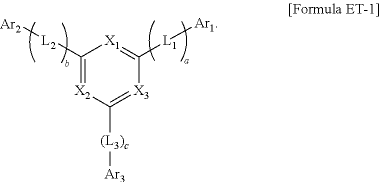

In Formula ET-1, at least one selected from among X₁ to X₃ may be N, and the remainder (e.g., the rest) may be CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ari to Ara may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer of 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c are each an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris(8-hydroxyquinolinato)aluminum (Alq3), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1-biphenyl-4-olato)aluminum (BAlq), berylliumbis(benzoquinolin-10-olate (Bebq₂), 9,10-di(naphthalene-2-yl)anthracene (ADN), 1,3-Bis[3,5-di(pyridin-3-yl)phenyl]benzene (BmPyPhB), or a mixture thereof.

The electron transport region ETR may include at least one selected from among Compound ET1 to Compound ET36:

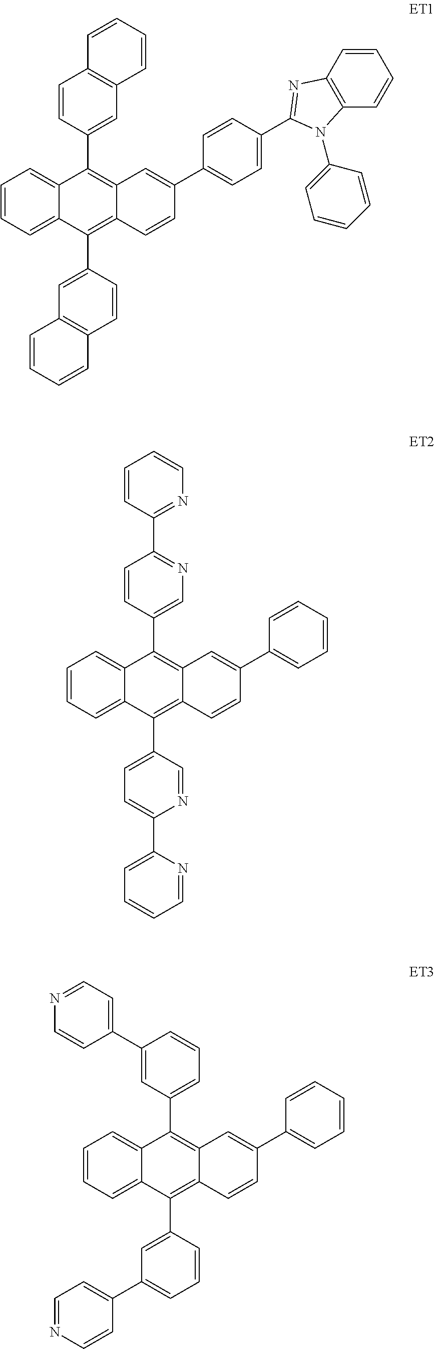 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

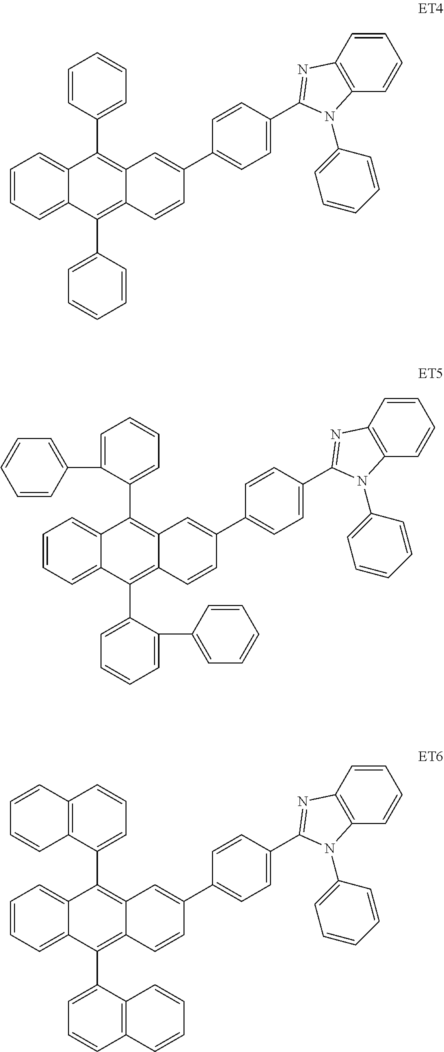 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

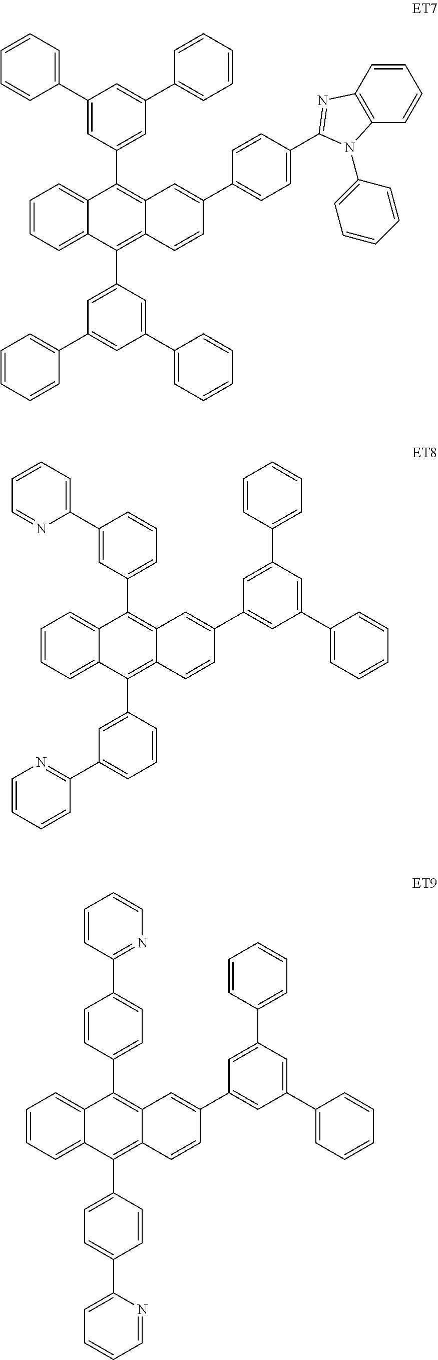 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

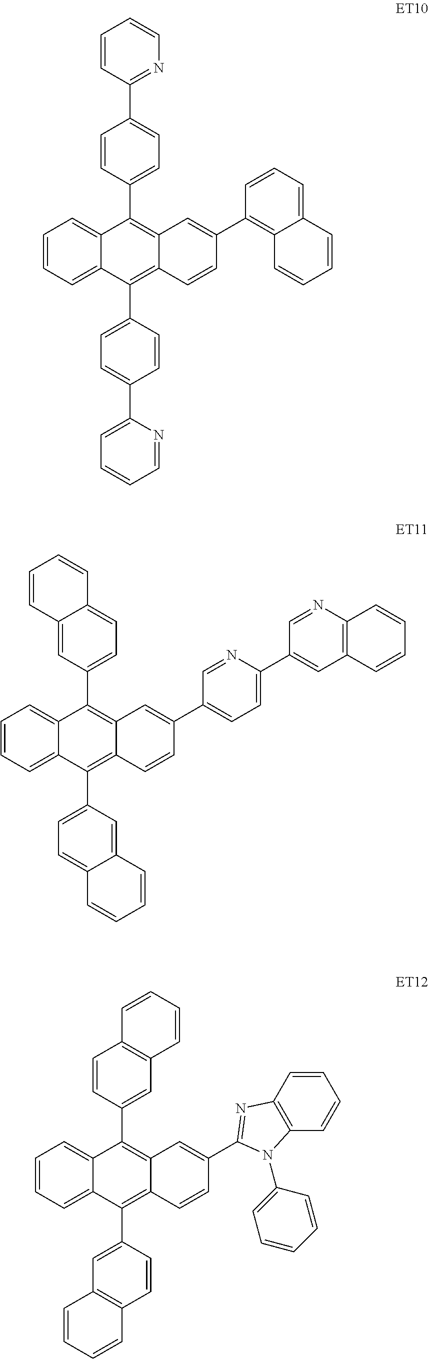 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

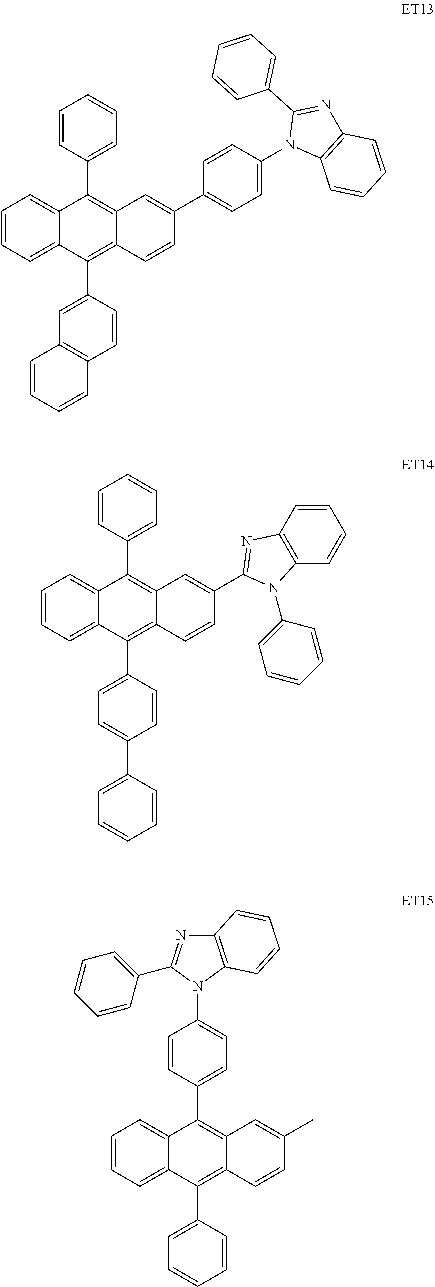 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

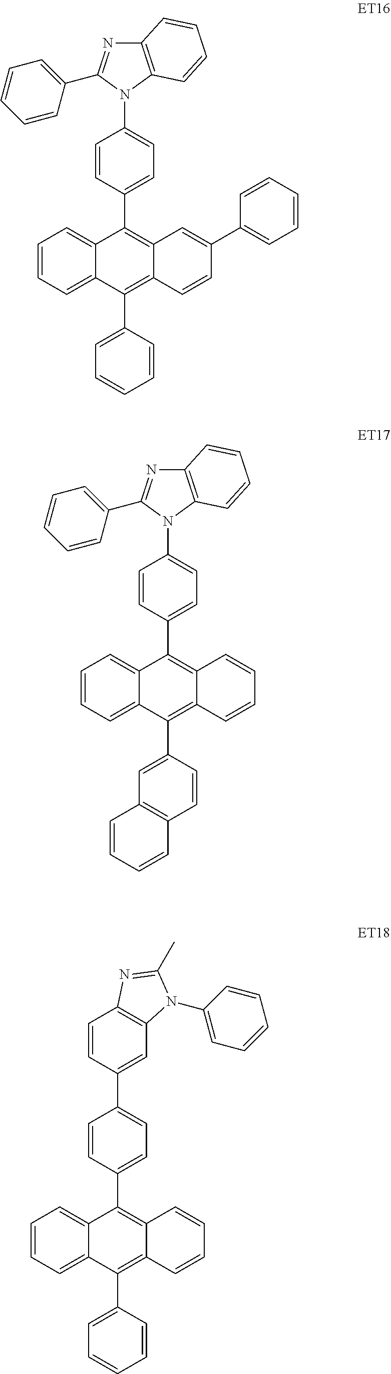 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

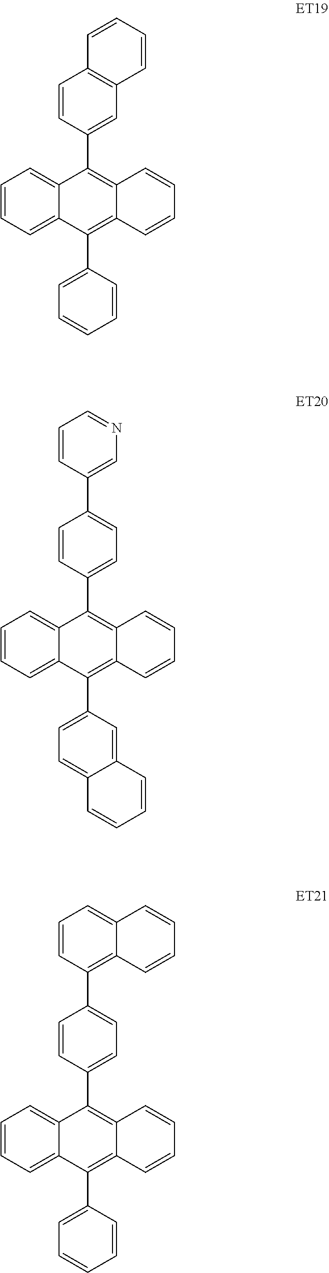

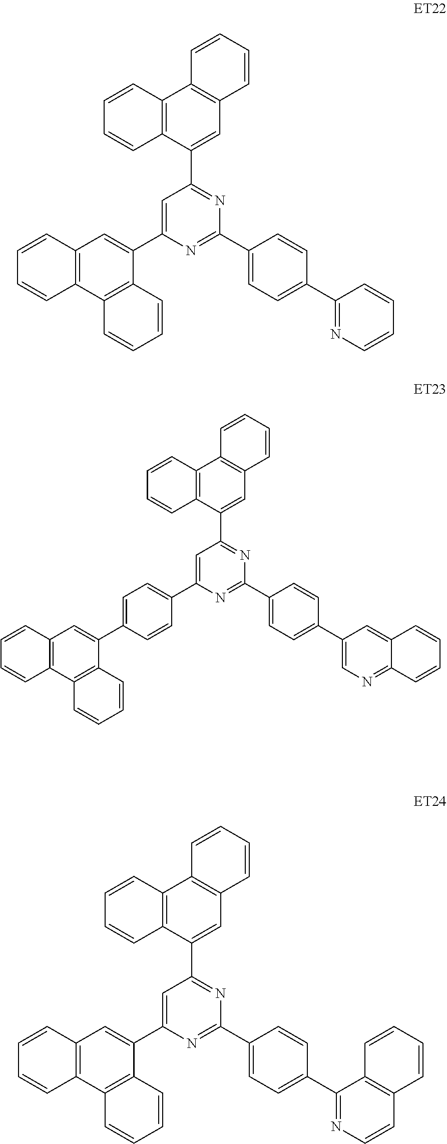 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

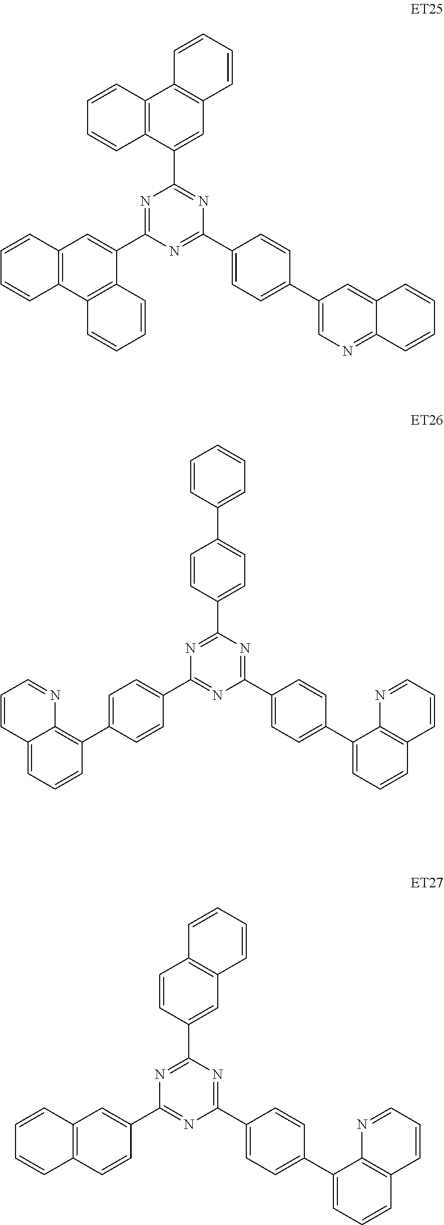 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

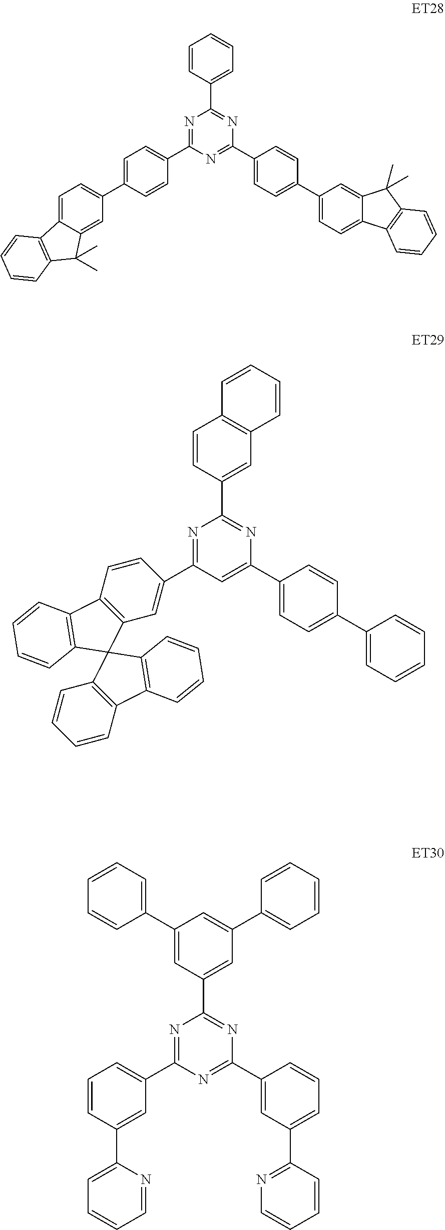 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

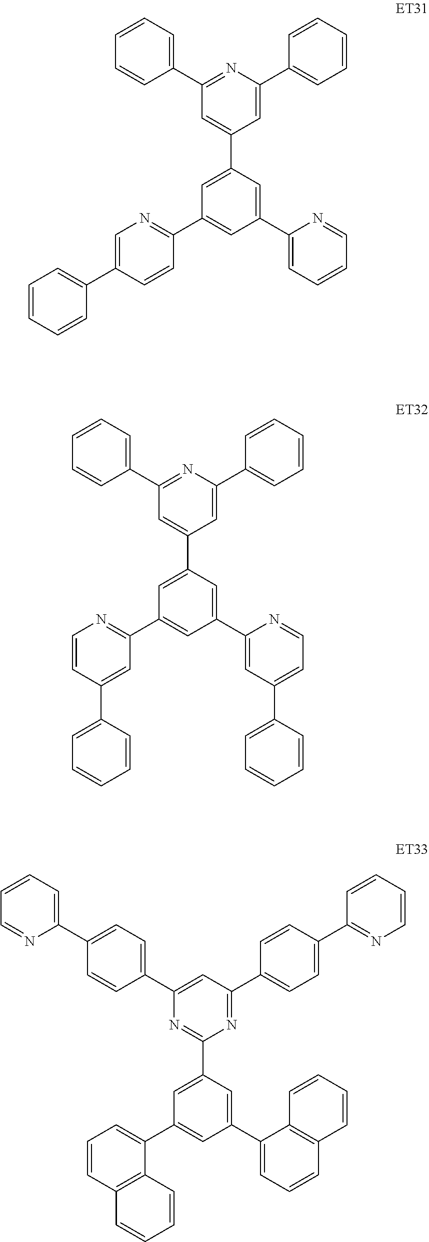 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

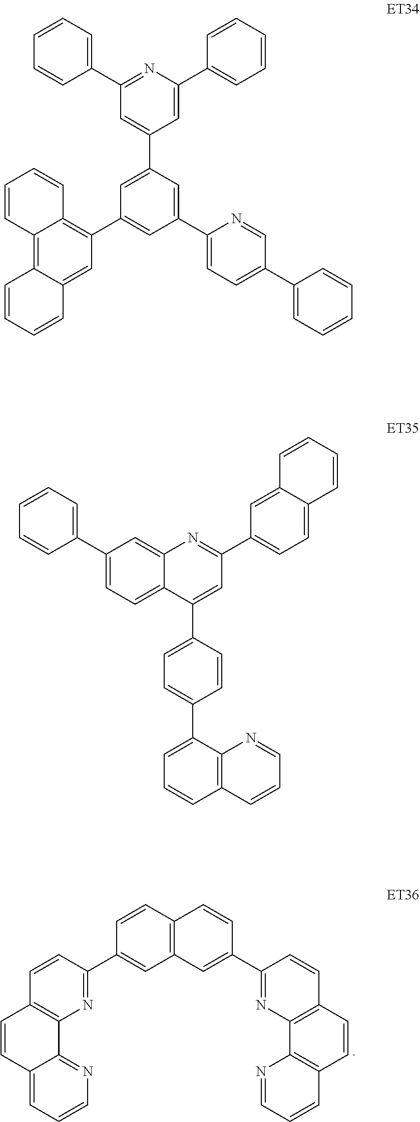 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In some embodiments, the electron transport regions ETR may include a metal halide such as LiF, NaCl, CsF, RbCI, RbI, Cul, and/or KI, a lanthanide metal such as Yb, and a co-deposited material of the metal halide and the lanthanide metal. For example, the electron transport region ETR may include KI:Yb, RbI:Yb, LiF:Yb, etc. as a co-deposited material. In some embodiments, the electron transport region ETR may be formed utilizing a metal oxide such as Li₂O and/or BaO, and/or 8-hydroxyl-lithium quinolate (Liq), etc., but the embodiment of the present disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, and/or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but the embodiment of the present disclosure is not limited thereto.

The electron transport region ETR may include the above-described compounds of the electron transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned ranges, satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the above-described ranges, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but the embodiment of the present disclosure is not limited thereto. For example, when the first electrode EU is an anode, the second electrode EL2 may be a cathode, and when the first electrode EL1 is a cathode, the second electrode EL2 may be an anode. The second electrode EL2 may include at least one selected from among Ag, Mg, Cu, Al, Pt, Pd, Au, Ni, Nd, Ir, Cr, Li, Ca, LiF, Mo, Ti, W, In, Sn, and Zn, at least one compound of two or more selected from among these, at least one mixture of two or more selected from among these, or at least one oxide thereof.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/AI, Mo, Ti, Yb, W, or a compound or mixture thereof (e.g., AgYb, and/or MgAg). In some embodiments, the second electrode EL2 may have a multilayer structure including a reflective film or a transflective film formed of the above-described materials, and a transparent conductive film formed of ITO, IZO, ZnO, ITZO, etc. For example, the second electrode EL2 may include one or more of the above-described metal materials, combinations of two or more metal materials of the above-described metal materials, oxides of the above-described metal materials, and/or the like.

In some embodiments, the second electrode EL2 may be connected with an auxiliary electrode. When the second electrode EL2 is connected with the auxiliary electrode, the resistance of the second electrode EL2 may be decreased.

In some embodiments, a capping layer CPL may further be disposed on the second electrode EL2 of the light emitting element ED of an embodiment. The capping layer CPL may include a multilayer or a single layer.

In an embodiment, the capping layer CPL may be an organic layer or an inorganic layer. For example, when the capping layer CPL contains an inorganic material, the inorganic material may include an alkali metal compound (for example, LiF), an alkaline earth metal compound (for example, MgF₂), SiON, SiNₓ, SiOy, etc.

For example, when the capping layer CPL contains an organic material, the organic material may include α-NPD, NPB, TPD, m-MTDATA, Alq3, CuPc,

N4,N4,N4′,N4′-tetra(biphenyl-4-yl)biphenyl-4,4′-diamine (TPD15), 4,4′,4″-tris(carbazol sol-9-yl)triphenylamine (TCTA), etc., or may include an epoxy resin, and/or an acrylate such as a methacrylate. However, the embodiment of the present disclosure is not limited thereto, and the capping layer CPL may include at least one selected from among Compounds P1 to P5:

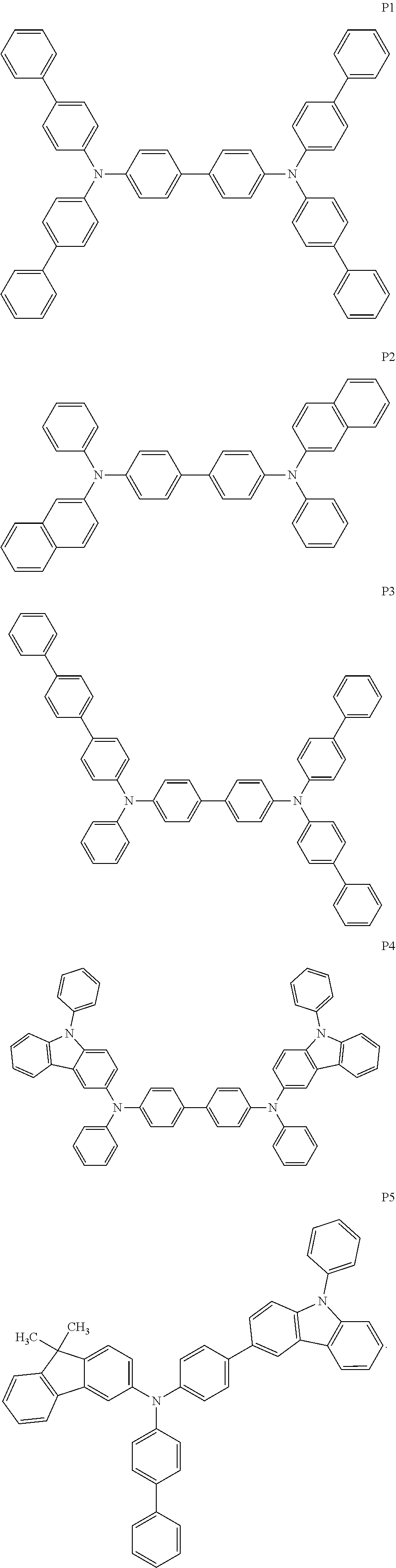 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL may be about 1.6 or more with respect to light in a wavelength range of about 550 nm to about 660 nm.

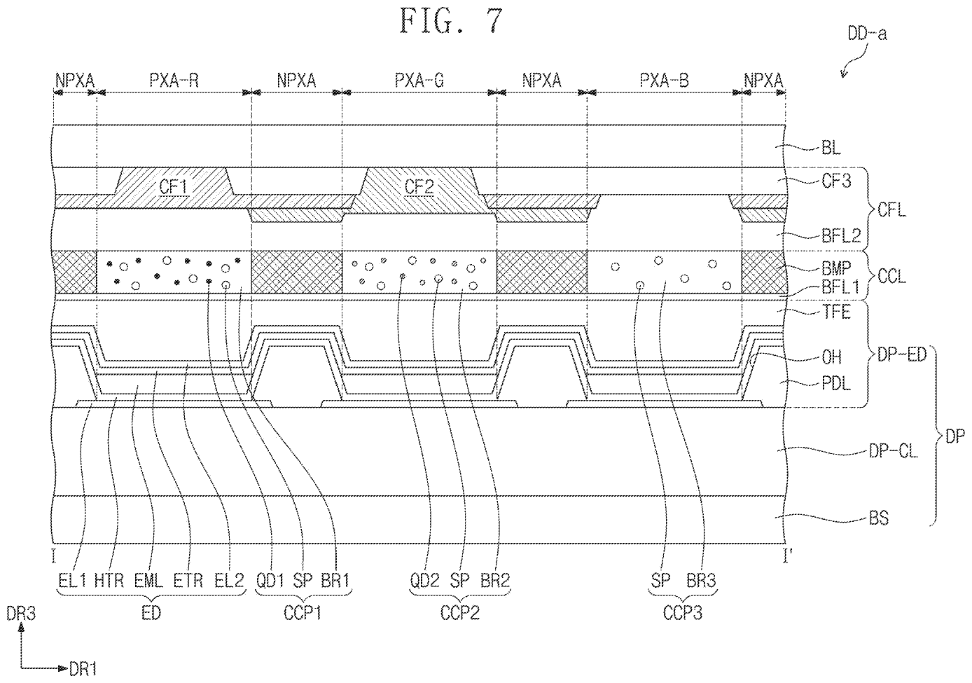

Each of FIGS. 7 to 10 is a cross-sectional view of a display device according to an embodiment of the present disclosure. Hereinafter, in describing the display devices of embodiments with reference to FIGS. 7 to 10, the duplicated features which have been described in FIGS. 1 to 6 are not described again, but their differences will be mainly described.

Referring to FIG. 7, the display device DD-a according to an embodiment may include a display panel DP including a display element layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In some embodiments, the same structures of the light emitting elements of FIGS. 3 to 6 as described above may be equally applied to the structure of the light emitting element ED illustrated in FIG. 7.

Referring to FIG. 7, the emission layer EML may be disposed in an opening OH defined in a pixel defining film PDL. For example, the emission layer EML which is divided by the pixel defining film PDL and provided corresponding to each light emitting regions PXA-R, PXA-G, and PXA-B may be to emit light in substantially the same wavelength range. In the display device DD of an embodiment, the emission layer EML may be to emit blue light. In some embodiments, unlike the configuration illustrated, the emission layer EML may be provided as a common layer in the entire light emitting regions PXA-R, PXA-G, and PXA-B.

The light control layer CCL may be disposed on the display panel DP. The light control layer CCL may include a light conversion body. The light conversion body may be a quantum dot, a phosphor, and/or the like. The light conversion body may be to emit provided light by converting the wavelength of the provided light and then emit a different color light. For example, the light control layer CCL may a layer containing the quantum dot or a layer containing the phosphor.

The light control layer CCL may include a plurality of light control parts CCP1, CCP2 and CCP3. The light control parts CCP1, CCP2, and CCP3 may be spaced apart from one another.

Referring to FIG. 7, divided patterns BMP may be disposed between the light control parts CCP1, CCP2 and CCP3 which are spaced apart from one another, but the embodiment of the present disclosure is not limited thereto. FIG. 7 illustrates that the divided patterns BMP do not overlap the light control parts CCP1, CCP2 and CCP3, but in some embodiments, at least a portion of the edges of the light control parts CCP1, CCP2 and CCP3 may overlap the divided patterns BMP.

The light control layer CCL may include a first light control part CCP1 containing a first quantum dot QD1 which converts a first color light provided from the light emitting element ED into a second color light, a second light control part CCP2 containing a second quantum dot QD2 which converts the first color light into a third color light, and a third light control part CCP3 which transmits the first color light.

In an embodiment, the first light control part CCP1 may provide red light, which is the second color light, and the second light control part CCP2 may provide green light, which is the third color light. The third light control part CCP3 may provide blue light by transmitting the blue light, which is the first color light provided from the light emitting element ED. For example, the first quantum dot QD1 may be a red quantum dot, and the second quantum dot QD2 may be a green quantum dot. The same as described above may be applied with respect to the quantum dots QD1 and

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dots but may include the scatterer SP.

The scatterer SP may be inorganic particles. For example, the scatterer SP may include at least one of TiO₂, ZnO, Al₂O₃, SiO₂, or hollow sphere silica. The scatterer SP may include any one selected from among TiO₂, ZnO, Al₂O₃, SiO₂, and hollow sphere silica, or may be a mixture of two or more materials selected from among TiO₂, ZnO, Al₂O₃, SiO₂, and hollow sphere silica.

The first light control part CCP1, the second light control part CCP2, and the third light control part CCP3 each may include a corresponding one of the base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in the first base resin BR1, the second light control part CCP2 may include the second quantum dot QD2 and the scatterer SP dispersed in the second base resin BR2, and the third light control part CCP3 may include the scatterer SP dispersed in the third base resin BR3. The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may be one or more acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from one another.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may be disposed on the light control parts CCP1, CCP2, and CCP3 to block or reduce the exposure of the light control parts CCP1, CCP2 and CCP3 to moisture/oxygen. In some embodiments, the barrier layer BFL1 may cover the light control parts CCP1, CCP2, and CCP3. In some embodiments, the barrier layer BFL2 may be provided between the light control parts CCP1, CCP2, and CCP3 and the color filter layer CFL (e.g., along the thickness direction).

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. In some embodiments, the barrier layers BFL1 and BFL2 may further include an organic film. The barrier layers BFL1 and BFL2 may be formed of a single layer or a plurality of layers.

In the display device DD of an embodiment, the color filter layer CFL may be disposed on the light control layer CCL. For example, the color filter layer CFL may be directly disposed on the light control layer CCL. In this case, the barrier layer BFL2 may not be provided.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment and/or dye. The first filter CF1 may include a red pigment and/or dye, the second filter CF2 may include a green pigment and/or dye, and the third filter CF3 may include a blue pigment and/or dye. The embodiment of the present disclosure is not limited thereto, and the third filter CF3 may not include (e.g., may exclude) any pigment or dye. The third filter CF3 may include a polymeric photosensitive resin and may not include (e.g., may exclude) any pigment or dye. The third filter CF3 may be transparent. The third filter CF3 may be formed of a transparent photosensitive resin.

Furthermore, in an embodiment, the first filter CF1 and the second filter CF2 may each be a yellow filter. The first filter CF1 and the second filter CF2 may not be separated but be provided as one filter. The first to third filters CF1, CF2, and CF3 may be disposed corresponding to the red light emitting region PXA-R, the green light emitting region PXA-G, and the blue light emitting region PXA-B, respectively.

In some embodiments, the color filter layer CFL may include a light shielding part. The color filter layer CFL may include a light shielding part disposed to overlap at the boundaries of neighboring filters CF1, CF2, and CF3. The light shielding part may be a black matrix. The light shielding part may include an organic light shielding material or an inorganic light shielding material containing a black pigment and/or dye. The light shielding part may separate boundaries between the adjacent filters CF1, CF2, and CF3. In some embodiments, the light shielding part may be formed of a blue filter.

A base substrate BL may be disposed on the color filter layer CFL. The base substrate BL may be a member which provides a base surface in which the color filter layer CFL, the light control layer CCL, and/or the like are disposed. The base substrate BL may be a glass substrate, a metal substrate, a plastic substrate, etc. However, an embodiment of the present disclosure is not limited thereto, and the base substrate BL may be an inorganic layer, an organic layer, or a composite material layer. In some embodiments, unlike the configuration illustrated, in an embodiment, the base substrate BL may not be provided.

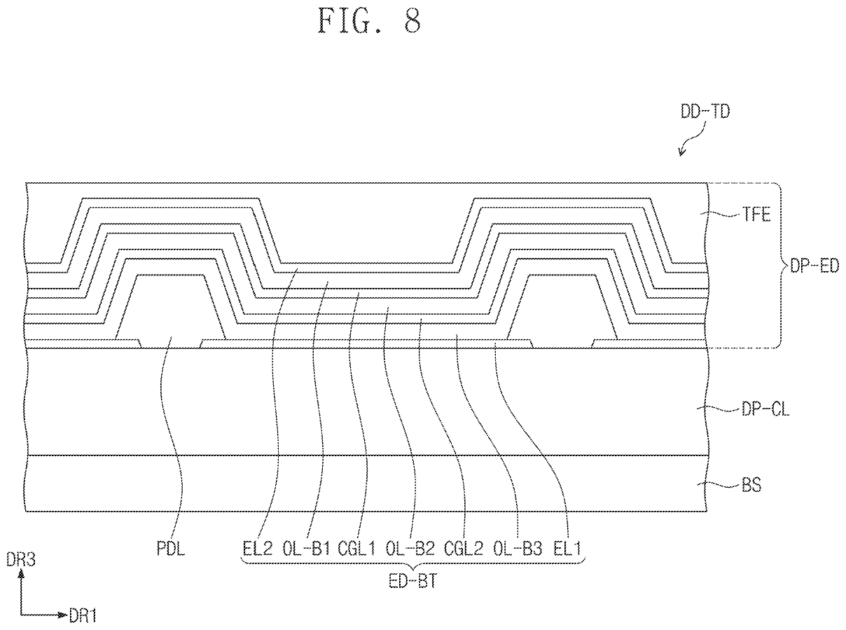

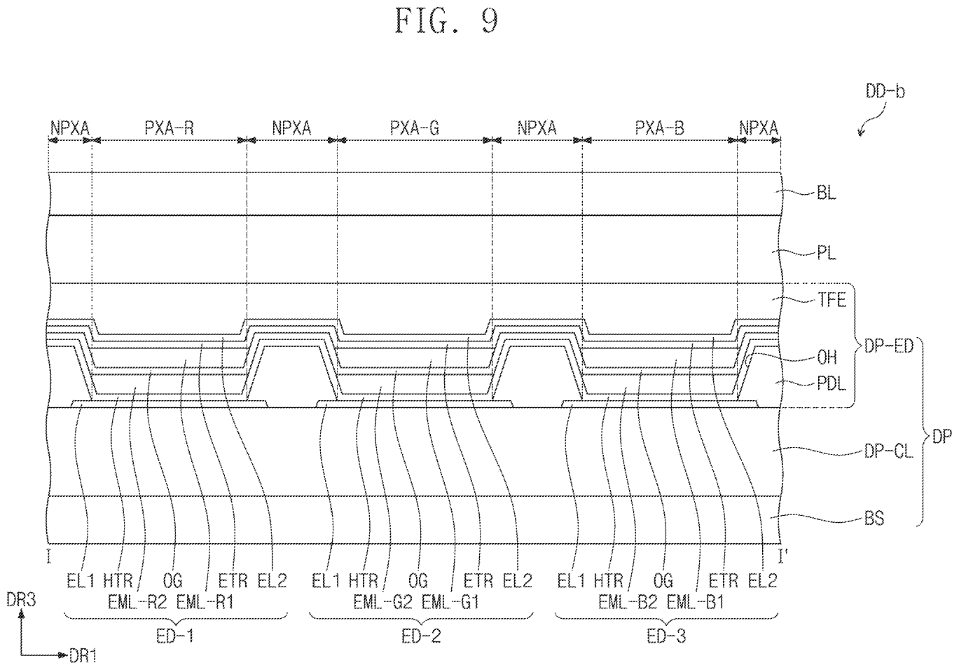

FIG. 8 is a cross-sectional view illustrating a portion of a display device according to an embodiment of the present disclosure. FIG. 8 illustrates a cross-sectional view of a part corresponding to the display panel DP of FIG. 7. In the display device DD-TD of an embodiment, the light emitting element ED-BT may include a plurality of light emitting structures OL-B1, OL-B2, and OL-B3. The light emitting element ED-BT may include a first electrode EL1 and a second electrode EL2 facing each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 7), and a hole transport region HTR and an electron transport region ETR disposed with the emission layer EML (FIG. 7) located therebetween.

For example, the light emitting element ED-BT included in the display device DD-TD of an embodiment may be a light emitting element having a tandem structure and including a plurality of emission layers.

In an embodiment illustrated in FIG. 8, light (e.g., light beams) respectively emitted from the light emitting structures OL-B1, OL-B2, and OL-B3 may all be blue light. However, the embodiment of the present disclosure is not limited thereto, and the light (e.g., light beams) respectively emitted from the light emitting structures OL-B1, OL-B2, and OL-B3 may have wavelength ranges different from one another. For example, the light emitting element ED-BT including the plurality of light emitting structures OL-B1, OL-B2, and OL-B3 which emit light (e.g., light beams) having wavelength ranges different from one another may be to emit white light.

Charge generation layers CGL1 and CGL2 may be respectively disposed between two of the neighboring light emitting structures OL-B1, OL-B2, and OL-B3. The charge generation layers CGL1 and CGL2 may include a p-type or kind charge generation layer and/or an n-type or kind charge generation layer.

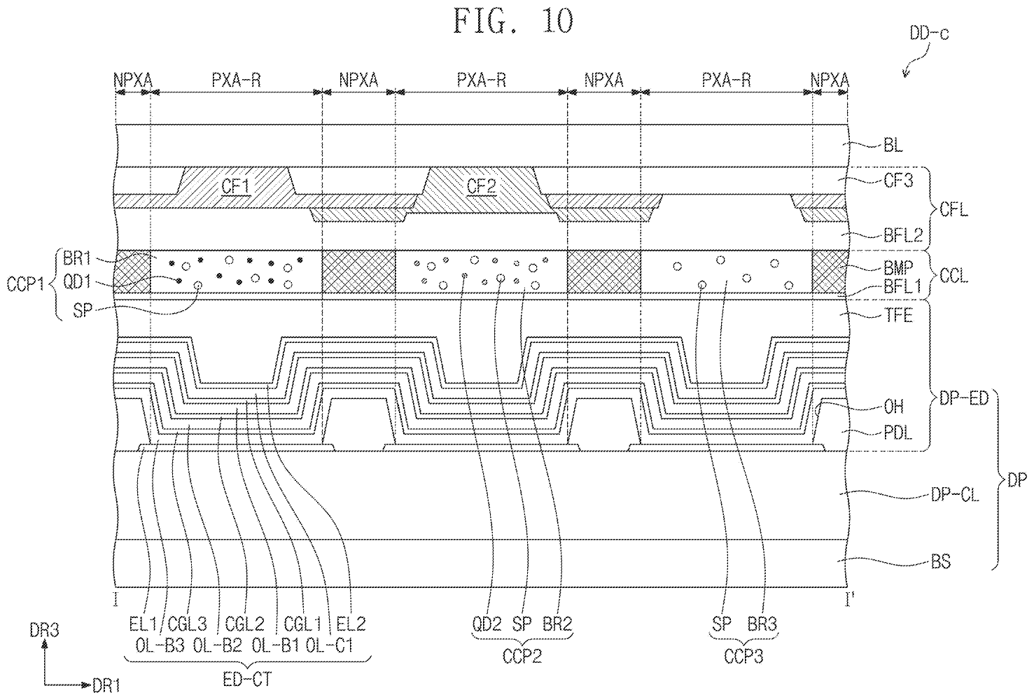

Referring to FIG. 9, the display device DD-b according to an embodiment may include light emitting elements ED-1, ED-2, and ED-3, in each of which two emission layers are stacked. Compared with the display device DD of an embodiment illustrated in FIG. 2, the embodiment illustrated in FIG. 9 is different in that the first to third light emitting elements ED-1, ED-2, and ED-3 each include two emission layers stacked in the thickness direction. In each of the first to third light emitting elements ED-1, ED-2, and ED-3, the two emission layers may be to emit light in substantially the same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. For example, the emission auxiliary part OG may include an electron transport region, a charge generation layer, and a hole transport region that are sequentially stacked in the stated order. The emission auxiliary part OG may be provided as a common layer in the whole (e.g., all) of the first to third light emitting elements ED-1, ED-2, and ED-3. However, the embodiment of the present disclosure is not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be disposed between the electron transport region ETR and the emission auxiliary part OG. The second red emission layer EML-R₂, the second green emission layer EML-G2, and the second blue emission layer EML-B2 may be disposed between the emission auxiliary part OG and the hole transport region HTR.

For example, the first light emitting element ED-1 may include the first electrode EL1, the hole transport region HTR, the second red emission layer EML-R₂, the emission auxiliary part OG, the first red emission layer EML-R₁, the electron transport region ETR, and the second electrode EL2 that are sequentially stacked in the stated order. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked in the stated order. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked in the stated order.

In some embodiments, an optical auxiliary layer PL may be disposed on the display element layer DP-ED. The optical auxiliary layer PL may include a polarizing layer. The optical auxiliary layer PL may be disposed on the display panel DP and control reflected light in the display panel DP due to external light. Unlike the configuration illustrated, the optical auxiliary layer PL in the display device according to an embodiment may not be provided.

Unlike FIGS. 8 and 9, FIG. 10 illustrates that a display device DD-c includes four light emitting structures OL-B1, OL-B2, OL-B3, and OL-C1. A light emitting element ED-CT may include a first electrode EL1 and a second electrode EL2 facing each other, and first to fourth light emitting structures OL-B1, OL-B2, OL-B3, and OL-C1 that are sequentially stacked in stated order in the thickness direction between the first electrode EL1 and the second electrode EL2. Charge generation layers CGL1, CGL2, and CGL3 may be respectively disposed between the first to fourth light emitting structures OL-B1, OL-B2, OL-B3, and OL-C1. Among the four light emitting structures, the first to third light emitting structures OL-B1, OL-B2, and OL-B3 may be to emit blue light, and the fourth light emitting structure OL-C1 may be to emit green light. However, the embodiment of the present disclosure is not limited thereto, and the first to fourth light emitting structures OL-B1, OL-B2, OL-B3, and OL-C1 may be to emit light (e.g., light beams) in different wavelength regions.

The charge generation layers CGL1, CGL2, and CGL3 disposed between adjacent light emitting structures OL-B1, OL-B2, OL-B3, and OL-C1 may each include a p-type or kind charge generation layer and/or an n-type or kind charge generation layer.

At least one selected from among the light emitting structures OL-B1, OL-B2, OL-B3, and OL-C1 included in the display device DD-c of an embodiment may include the above-described polycyclic compound of an embodiment.

The above-described polycyclic compound of an embodiment includes a structure in which a triphenylsilyl group is fused with a carbazole skeleton, and when the polycyclic compound is utilized as a host material of the light emitting element, an exciplex with a compound utilized as a dopant material is not generated, and thus the color purity may be improved, and a relatively high T1 level may be exhibited, thereby achieving high efficiency of the light emitting element. In some embodiments, the polycyclic compound of an embodiment may have an excellent or suitable electron transport ability, thereby providing an effect of reduced driving voltage.

Hereinafter, with reference to Examples and Comparative Examples, a polycyclic compound according to an embodiment of the present disclosure and a light emitting element of an embodiment of the present disclosure will be described in more detail. In addition, Examples described below are only illustrations to assist the understanding of the present disclosure, and the scope of the present disclosure is not limited thereto.

### EXAMPLES

### 1. Synthesis of Polycyclic Compound

A synthetic method of a polycyclic compound according to the current embodiment will be described in more detail by illustrating the synthetic method of Compounds 2, 3, 9, 22, 24, and 31. In the following descriptions, the synthetic methods of the polycyclic compounds are provided as examples, but the synthetic method according to an embodiment of the present disclosure is not limited to these Examples.

### (1) Synthesis of Compound 2

Polycyclic Compound 2 according to an example may be synthesized by, for example, the steps (acts) shown in Reaction Scheme 1:

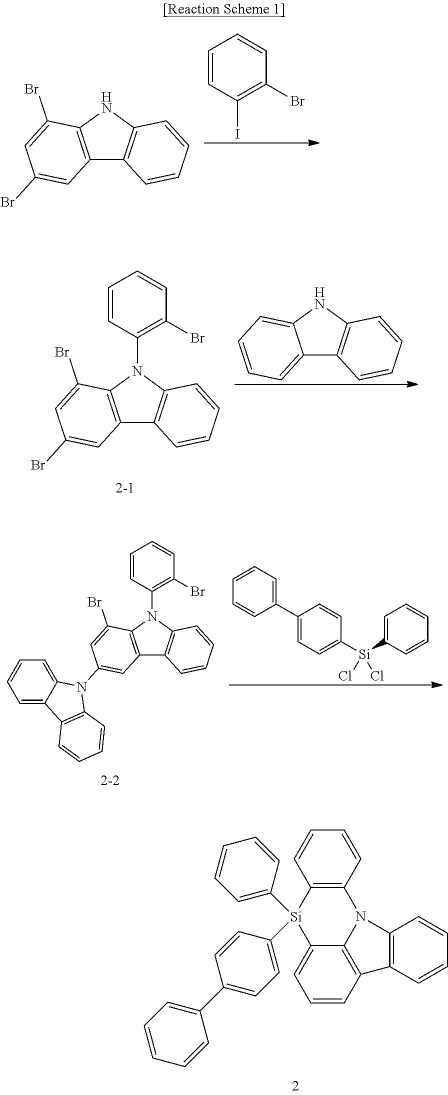

### 1) Synthesis of Intermediate 2-1

1,3-dibromo-9H-carbazole (1 eq) and 1-bromo-2-iodobenzene (1.5 eq) were reacted under the condition (e.g., in the presence) of Pd₂dba₃ (0.05 eq) to obtain Intermediate 2-1. Intermediate 2-1 was identified with LC/MS. C₁₈H₁₀Br₃N M+1: 477.90

### 2) Synthesis of Intermediate 2-2

Intermediate 2-1 (1 eq) and 9H-carbazole (0.8 eq) were reacted under the condition (e.g., in the presence) of Pd(pph₃)₄ (0.04 eq) to obtain Intermediate 2-2. Intermediate 2-2 was identified with LC/MS.

C₃₀H₁₈Br₂N₂ M+1: 565.12

### 3) Synthesis of Compound 2

Intermediate 2-2 (3.0 g) was dissolved in THF and stirred at about −78° C. for about 30 minutes. n-BuLi (4.26 mL, 2 eq) was slowly added dropwise thereto and stirred at about −78° C. for about 1 hour. [1,1′-biphenyl]-4-yldichloro(phenyl)silane (CAS:18557-48-7) (1.75 g, 1 eq) was quickly added dropwise thereto and stirred at room temperature for about 12 hours. After the reaction was completed, the reaction solution was extracted with ethyl acetate to collect an organic layer. The collected organic layer was dried over magnesium sulfate and the solvent was evaporated to obtain residuals. The obtained residuals were separated and purified by silica gel column chromatography to obtain Compound 2 (2.15 g, yield: 61%). Compound 2 was identified with LC-MS and ¹H-NMR, and the results thereof are listed in Table 1.

C₄₈H₃₂N₂Si M+1: 665.30

### (2) Synthesis of Compound 3

Polycyclic Compound 3 according to an example may be synthesized by, for example, the steps (acts) shown in Reaction Scheme 2:

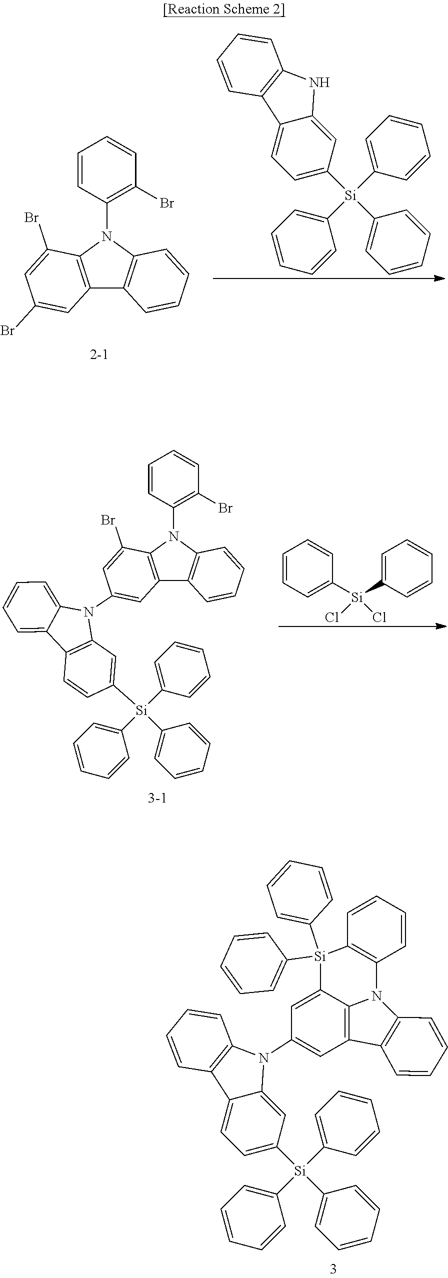

### 1) Synthesis of Intermediate 3-1

Intermediate 2-1 (1 eq) and 2-(triphenylsilyl)-9H-carbazole (0.8 eq) were reacted under the condition (e.g., in the presence) of Pd(pph₃)₄ (0.04 eq) to obtain Intermediate 3-1. Intermediate 3-1 was identified with LC/MS.

C₄₈H₃₂Br₂N₂Si M+1: 823.47

### 2) Synthesis of Compound 3

Intermediate 3-1 (3.92 g) was dissolved in THF and stirred at about −78° C. for about 30 minutes. n-BuLi (3.8 mL, 2 eq) was slowly added dropwise thereto and stirred at about −78° C. for about 1 hour. Dichlorodiphenylsilane (CAS: 80-10-4) (1.2 g, 1 eq) was quickly added dropwise thereto and stirred at room temperature for about 12 hours. After the reaction was completed, the reaction solution was extracted with ethyl acetate to collect an organic layer. The collected organic layer was dried over magnesium sulfate and the solvent was evaporated to obtain residuals. The obtained residuals were separated and purified by silica gel column chromatography to obtain Compound 3 (2.69 g, yield: 67%). Compound 3 was identified with LC-MS and ¹H-NMR, and the results thereof are listed in Table 1.

C₆₀H₄₂N₂Si₂ M+1: 847.33

### (3) Synthesis of Compound 9

Polycyclic Compound 9 according to an example may be synthesized by, for example, the steps (acts) shown in Reaction Scheme 3:

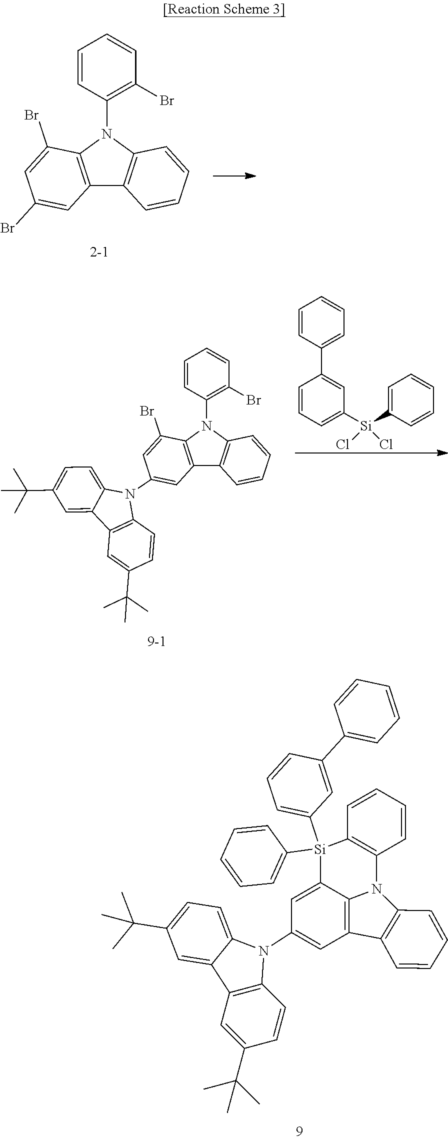

### 1) Synthesis of Intermediate 9-1

Intermediate 2-1 (1 eq) and 3,6-di-tert-butyl-9H-carbazole (0.8 eq) were reacted under the condition (e.g., in the presence) of Pd(pph₃)₄ (0.04 eq) to obtain Intermediate 9-1. Intermediate 9-1 was identified with LC/MS.

C₄₈H₃₂Br₂N₂Si M+1: 677.24

### 2) Synthesis of Compound 9

Intermediate 9-1 (3.51 g) was dissolved in THF and stirred at about −78° C. for about 30 minutes. n-BuLi (4.14 mL, 2 eq) was slowly added dropwise thereto and stirred at about −78° C. for about 1 hour. [1,1′-biphenyl]-3-yldichloro(phenyl)silane (1.7 g) was quickly added dropwise thereto and stirred at room temperature for about 12 hours. After the reaction was completed, the reaction solution was extracted with ethyl acetate to collect an organic layer. The collected organic layer was dried over magnesium sulfate and the solvent was evaporated to obtain residuals. The obtained residuals were separated and purified by silica gel column chromatography to obtain Compound 9 (2.61 g, yield: 65%). Compound 9 was identified with LC-MS and ¹H-NMR, and the results thereof are listed in Table 1.

C₅₆H₄₈N₂Si M+1: 778.26

### (4) Synthesis of Compound 22

Polycyclic Compound 22 according to an example may be synthesized by, for example, the steps (acts) shown in Reaction Scheme 4:

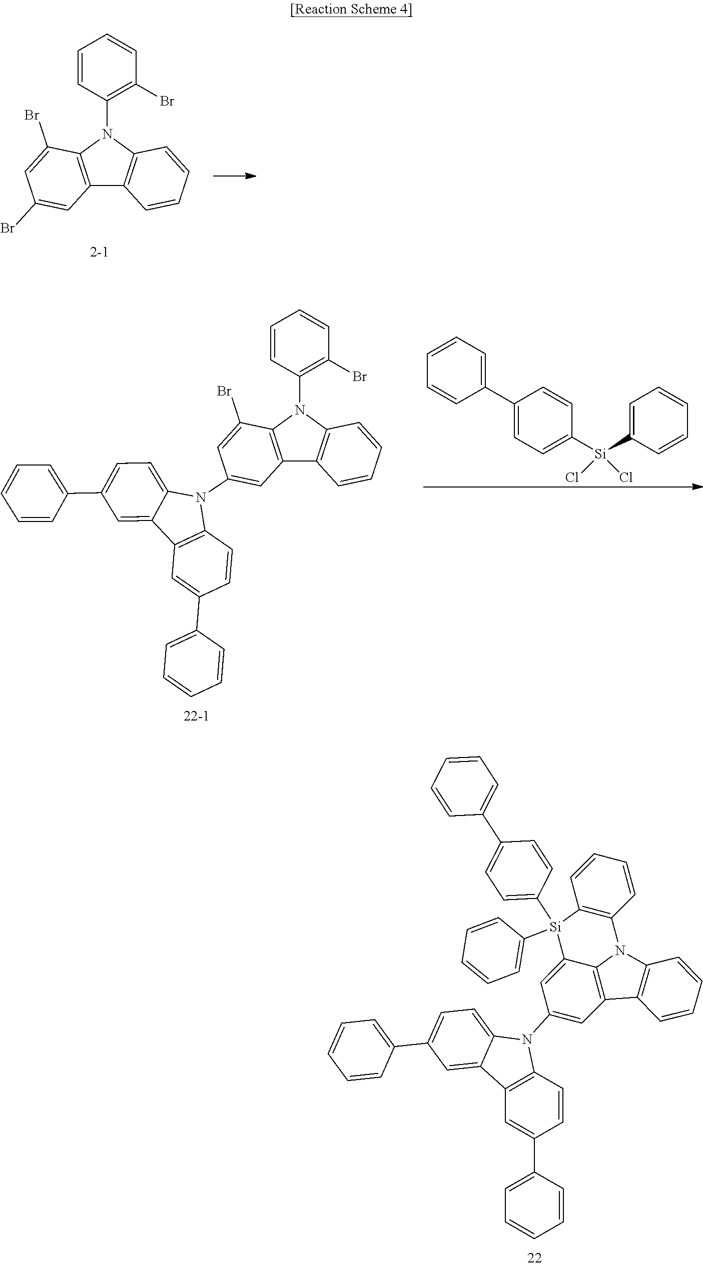

### 1) Synthesis of Intermediate 22-1

Intermediate 2-1 (1 eq) and 3,6-diphenyl-9H-carbazole (0.8 eq) were reacted under the condition (e.g., in the presence) of Pd(pph₃)₄ (0.04 eq) to obtain Intermediate 22-1. Intermediate 22-1 was identified with LC/MS.

C₄₂H₂₆Br₂N₂ M+1: 717.41

### 2) Synthesis of Compound 22

Intermediate 22-1 (2.87 g) was dissolved in THF and stirred at about −78° C. for about 30 minutes. n-BuLi (3.20 mL, 2 eq) was slowly added dropwise thereto and stirred at about −78° C. for about 1 hour. [1,1′-biphenyl]-4-yldichloro(phenyl)silane (1.32 g, 1 eq) was quickly added dropwise thereto and stirred at room temperature for about 12 hours. After the reaction was completed, the reaction solution was extracted with ethyl acetate to collect an organic layer. The collected organic layer was dried over magnesium sulfate and the solvent was evaporated to obtain residuals. The obtained residuals were separated and purified by silica gel column chromatography to obtain Compound 22 (1.69 g, yield: 52%). Compound 22 was identified with LC-MS and ¹H-NMR, and the results thereof are listed in Table 1.

C₆₀H₄₀N₂Si M+1: 817.38

### (5) Synthesis of Compound 24

Polycyclic Compound 24 according to an example may be synthesized by, for example, the steps (acts) shown in Reaction Scheme 5:

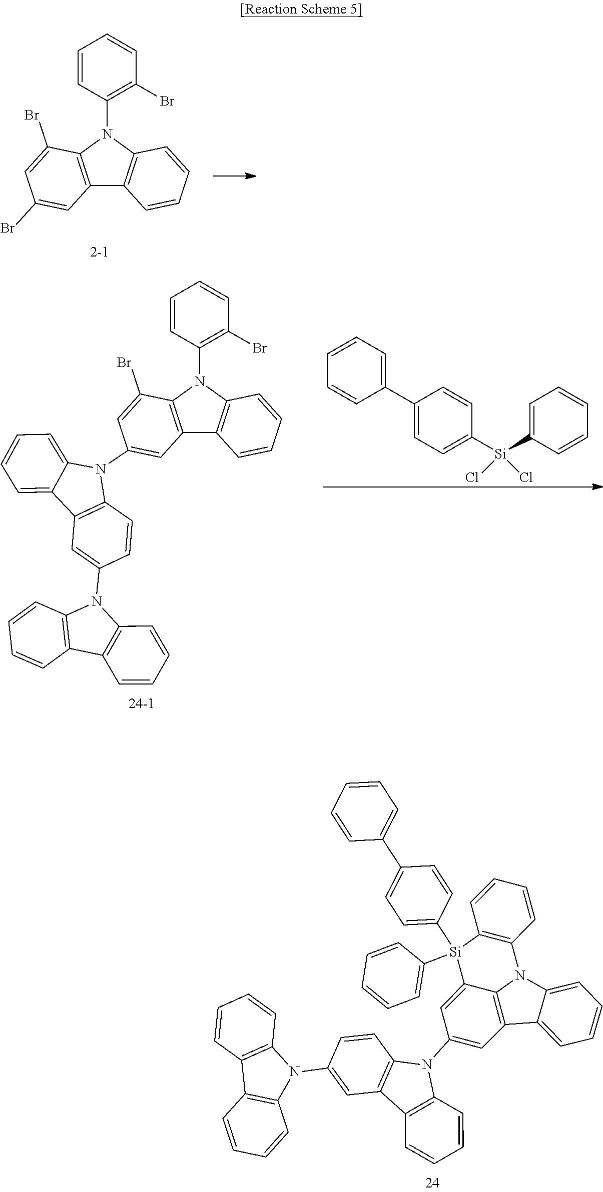

### 1) Synthesis of Intermediate 24-1

Intermediate 2-1 (1 eq) and 9H-3,9′-bicarbazole (0.8 eq) were reacted under the condition (e.g., in the presence) of Pd(pph₃)₄ (0.04 eq) to obtain Intermediate 24-1. Intermediate 24-1 was identified with LC/MS.

C₄₂H₂₅Br₂N₃ M+1: 730.25

### 2) Synthesis of Compound 24

Intermediate 24-1 (4.22 g) was dissolved in THF and stirred at about −78° C. for about 30 minutes. n-BuLi (4.61 mL, 2 eq) was slowly added dropwise thereto and stirred at about −78° C. for about 1 hour. [1,1′-biphenyl]-4-yldichloro(phenyl)silane (1.90 g) was quickly added dropwise thereto and stirred at room temperature for about 12 hours. After the reaction was completed, the reaction solution was extracted with ethyl acetate to collect an organic layer. The collected organic layer was dried over magnesium sulfate and the solvent was evaporated to obtain residuals. The obtained residuals were separated and purified by silica gel column chromatography to obtain Compound 24 (2.65 g, yield: 55%). Compound 24 was identified with LC-MS and ¹H-NMR, and the results thereof are listed in Table 1.

C₆₀H₃₉N₃Si M+1: 831.50

### (6) Synthesis of Compound 31

Polycyclic Compound 31 according to an example may be synthesized by, for example, the steps (acts) shown in Reaction Scheme 6:

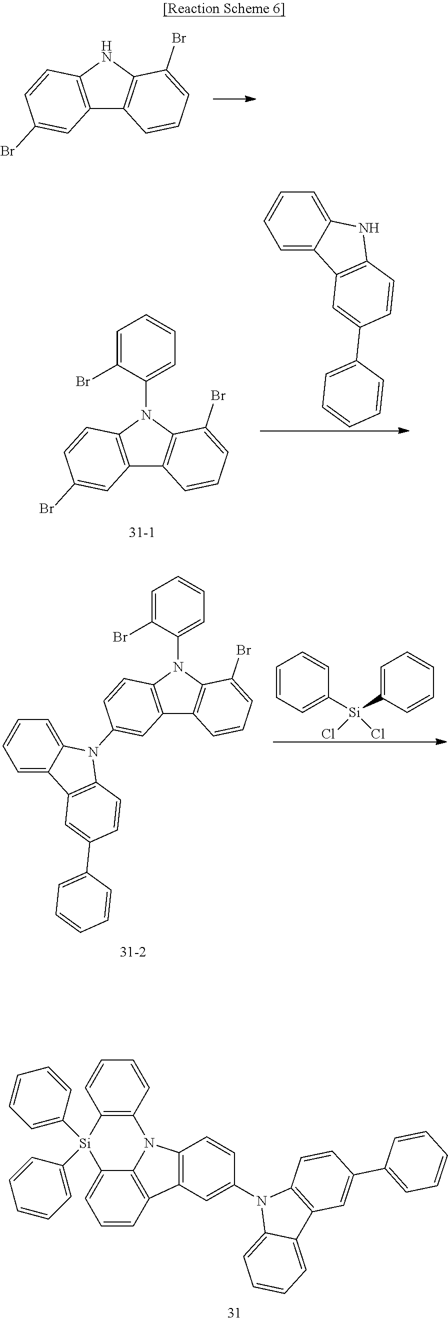

### 1) Synthesis of Intermediate 31-1

1,6-dibromo-9H-carbazole (1 eq) and 1-bromo-2-iodobenzene (1.5 eq) were reacted under the condition (e.g., in the presence) of Pd₂dba₃ (0.05 eq) to obtain Intermediate 31-1. Intermediate 31-1 was identified with LC/MS.

C₁₈H₁₀Br₃N M+1: 477.88

### 2) Synthesis of Intermediate 31-2

Intermediate 31-1 (1 eq) and 3-phenyl-9H-carbazole (0.8 eq) were reacted under the condition (e.g., in the presence) of Pd(pph₃)₄ (0.04 eq) to obtain Intermediate 31-2. Intermediate 31-2 was identified with LC/MS.

C₃₆H₂₂Br₂N₂ M+1: 641.12

### 3) Synthesis of Compound 31

Intermediate 31-2 (3.1 g) was dissolved in THF and stirred at about −78° C. for about 30 minutes. n-BuLi (3.86 mL, 2 eq) was slowly added dropwise thereto and stirred at about −78° C. for about 1 hour. Dichlorodiphenylsilane (CAS: 80-10-4) (1.22 g, 1 eq) was quickly added dropwise thereto and stirred at room temperature for about 12 hours. After the reaction was completed, the reaction solution was extracted with ethyl acetate to collect an organic layer. The collected organic layer was dried over magnesium sulfate and the solvent was evaporated to obtain residuals. The obtained residuals were separated and purified by silica gel column chromatography to obtain Compound 31 (2.18 g, yield: 68%). Compound 31 was identified with LC-MS and ¹H-NMR, and the results thereof are listed in Table 1.

C₄₈H₃₂N₂Si M+1: 665.39

TABLE 1

| | | MS/FAB | |
|---|---|---|---|
| Compound | ¹H NMR (CDCl₃, 400 MHz) | found | calc. |
| Compound 2 | 8.55(d, 2H), 8.19(d, 1H), | 665.30 | 664.23 |
| | 7.94-7.16(m, 29H) | | |
| Compound 3 | 8.53(d, 2H), 8.19(d, 1H), | 847.33 | 846.29 |
| | 7.83-7.80(m, 3H), | | |
| | 7.68(d, 1H), 7.58-7.16(m, 35H) | | |
| Compound 9 | 8.95(s, 1H), 8.55(d, 1H), | 778.26 | 777.10 |
| | 7.94-7.16(m, 28H)1.43(s, 18H) | | |
| Compound 22 | 8.55(d, 1H), 8.30(d, 1H), | 817.38 | 816.30 |
| | 8.13(d, 1H), 7.94-7.16(m, 37H) | | |
| Compound 24 | 8.55(d, 2H), 8.19(d, 1H), | 831.50 | 830.08 |
| | 7.94-7.16(m, 36H) | | |
| Compound 31 | 8.55(d, 1H), 8.29(d, 1H), | 665.39 | 664.88 |
| | 8.08(d, 1H), | | |
| | 7.99-7.33(m, 28H), 7.16(t, 1H) | | |

### 2. Manufacturing and Evaluation of Light Emitting Elements

Evaluation of the light emitting elements including compounds of Examples and Comparative Examples in a hole transport layer was performed as follows. The method for manufacturing the light emitting element for the evaluation of the element is described below.

### (1) Manufacturing of Light Emitting Elements

A 1,200 Å-thick ITO substrate was utilized as a first electrode. The ITO substrate was cleansed by ultrasonic waves utilizing isopropyl alcohol and pure water for about five minutes, respectively, and then was irradiated with ultraviolet rays for about 30 minutes and exposed to ozone and cleansed and prepared. The cleansed ITO substrate was installed on a vacuum deposition apparatus.

N,N′-di(1-naphthyl)-N,N′-diphenylbenzidine (NPB) was deposited in vacuum on the cleansed and prepared ITO substrate to form a hole injection layer. The hole injection layer was formed to have a thickness of about 300 Å. Next, mCP was deposited in vacuum on the hole injection layer to form a hole transport layer. The hole transport layer was formed to have a thickness of about 200 Å.

Next, an emission layer including a respective Example Compound or Comparative Example Compound was formed on the hole transport layer. For the emission layer, an Example Compound or Comparative Example Compound was co-deposited with Ir(pmp)₃ as a dopant material in a weight ratio of about 92:8 (Example Compound or Comparative Example Compound: dopant) to form a 250 Å-thick emission layer.

Then, on the upper portion of the emission layer, 3-(4-biphenylyl)-4-phenyl-5-tert-butylphenyl-1,2,4-triazole (TAZ) was deposited to form a 200 Å-thick electron transport layer, on the upper portion of the electron transport layer, LiF, which is an alkali metal halide, was then deposited to form 10 Å-thick electron injection layer, and Al was deposited on the electron injection layer in vacuum to form a 100 Å-thick second electrode. An LiF/Al electrode was formed on the second electrode, thereby manufacturing a light emitting element.

Example Compounds and Comparative Example Compounds utilized to manufacture the light emitting elements are as follows:

### Example Compounds

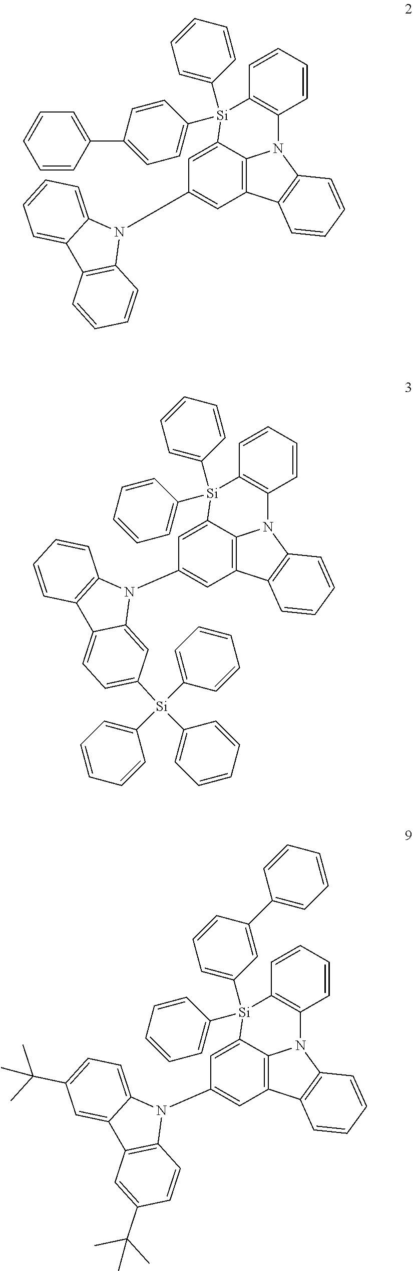 [SMILES: c1ccc(-c2ccc([Si]3(c4ccccc4)c4ccccc4-n4c5ccccc5c5cc(-n6c7ccccc7c7ccccc76)cc3c54)cc2)cc1 ; c1ccc([Si](c2ccccc2)(c2ccccc2)c2ccc3c4ccccc4n(-c4cc5c6c(c4)c4ccccc4n6-c4ccccc4[Si]5(c4ccccc4)c4ccccc4)c3c2)cc1 ; CC(C)(C)c1ccc2c(c1)c1cc(C(C)(C)C)ccc1n2-c1cc2c3c(c1)c1ccccc1n3-c1ccccc1[Si]2(c1ccccc1)c1cccc(-c2ccccc2)c1]

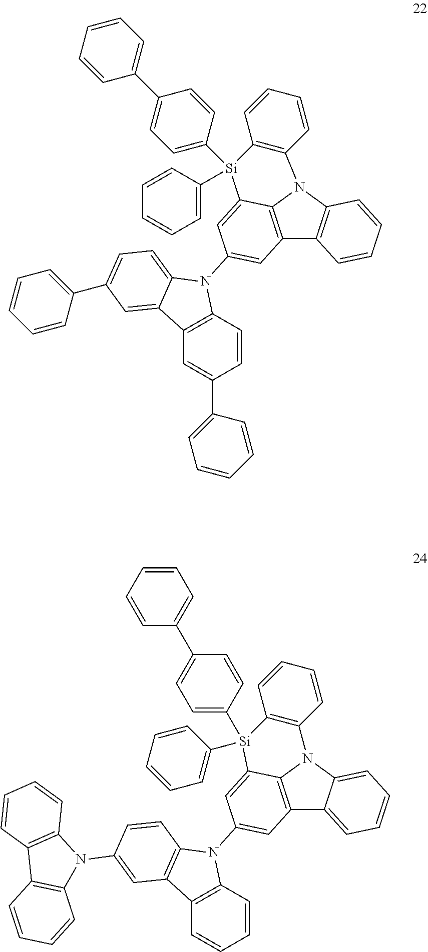 [SMILES: c1ccc(-c2ccc([Si]3(c4ccccc4)c4ccccc4-n4c5ccccc5c5cc(-n6c7ccc(-c8ccccc8)cc7c7cc(-c8ccccc8)ccc76)cc3c54)cc2)cc1 ; c1ccc(-c2ccc([Si]3(c4ccccc4)c4ccccc4-n4c5ccccc5c5cc(-n6c7ccccc7c7cc(-n8c9ccccc9c9ccccc98)ccc76)cc3c54)cc2)cc1]

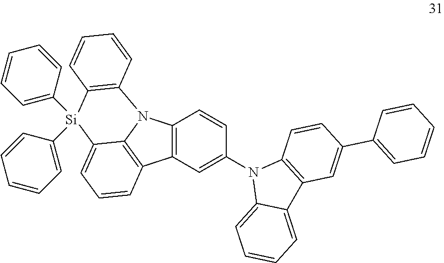 [SMILES: c1ccc(-c2ccc3c(c2)c2ccccc2n3-c2ccc3c(c2)c2cccc4c2n3-c2ccccc2[Si]4(c2ccccc2)c2ccccc2)cc1]

### Comparative Example Compounds

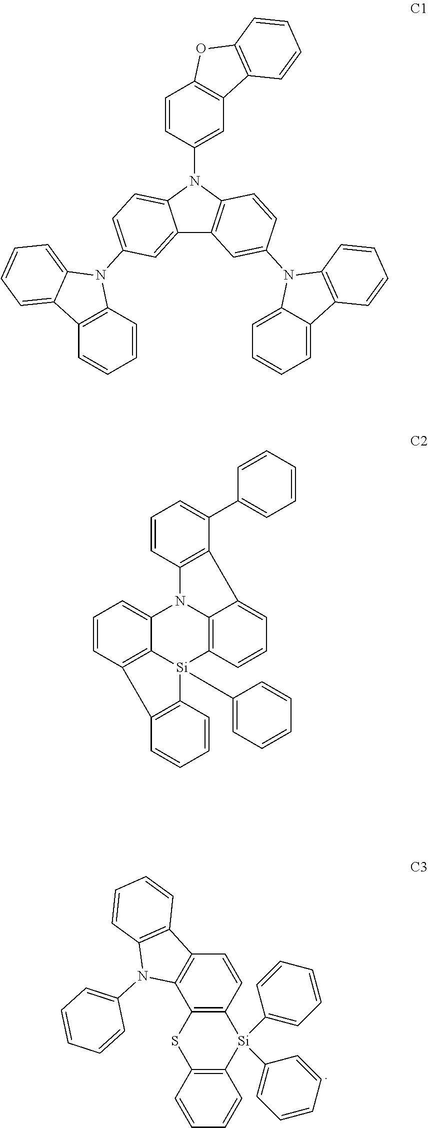 [SMILES: c1ccc2c(c1)oc1ccc(-n3c4ccc(-n5c6ccccc6c6ccccc65)cc4c4cc(-n5c6ccccc6c6ccccc65)ccc43)cc12 ; c1ccc(-c2cccc3c2c2cccc4c2n3-c2cccc3c2[Si]4(c2ccccc2)c2ccccc2-3)cc1 ; c1ccc(-n2c3ccccc3c3ccc4c(c32)Sc2ccccc2[Si]4(c2ccccc2)c2ccccc2)cc1]

In addition, compounds of each functional layer utilized to manufacture light emitting elements are as follows:

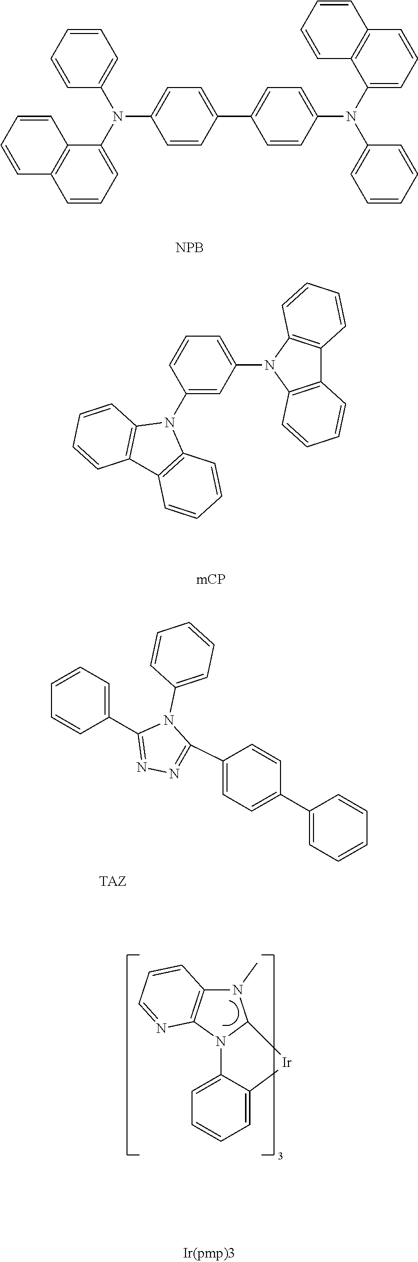

### (2) Evaluation of Light Emitting Element Properties

To evaluate properties of the light emitting elements according to Examples and Comparative Examples, driving voltages, current densities, and maximum quantum efficiencies at a current density of 10 mA/cm² were measured. The driving voltage and current density of the light emitting element were measured by utilizing Source Meter (manufactured by Keithley Instruments, Inc., 2400 Series). The maximum quantum efficiency was measured by utilizing an external quantum efficiency measurement apparatus, C9920-2-12 manufactured by Hamamatsu Photonics, Co., Japan. With respect to the evaluation of maximum quantum efficiency, brightness/current density was measured by utilizing brightness photometer in which wavelength sensitivity is calibrated, and the maximum quantum efficiency is converted assuming angular brightness distribution (Lambertian distribution) in which ideal diffuse reflecting surface is contemplated. The results of the evaluation of properties of the light emitting elements are listed in Table 2.

TABLE 2

| Examples | | | | Maximum | | |
|---|---|---|---|---|---|---|
| of manu- | | Driving | Effi- | quantum | | Lumi- |
| factured | Emission | voltage | ciency | efficiency | T1 | nous |
| elements | layer | (V) | (Cd/A) | (%) | (eV) | color |
| Example 1 | Example | 4.1 | 18.9 | 29.3 | 3.03 | Blue |
| | Compound | | | | | |
| | 2 | | | | | |
| Example 2 | Example | 4.6 | 17.5 | 28.7 | 3.04 | Blue |
| | Compound | | | | | |
| | 3 | | | | | |
| Example 3 | Example | 4.3 | 18.8 | 29.1 | 3.03 | Blue |
| | Compound | | | | | |
| | 9 | | | | | |
| Example 4 | Example | 4.5 | 18.7 | 28.6 | 3.01 | Blue |
| | Compound | | | | | |
| | 22 | | | | | |
| Example 5 | Example | 4.1 | 18.5 | 28.2 | 3.04 | Blue |
| | Compound | | | | | |
| | 24 | | | | | |
| Example 6 | Example | 4.4 | 18.0 | 28.0 | 3.02 | Blue |
| | Compound | | | | | |
| | 31 | | | | | |
| Comparative | Comparative | 5.7 | 12.8 | 22.4 | 2.99 | Blue |
| Example 1 | Example | | | | | |
| | Compound | | | | | |
| | C1 | | | | | |
| Comparative | Comparative | 5.5 | 10.8 | 20.2 | 2.73 | Blue |
| Example 2 | Example | | | | | |
| | Compound | | | | | |
| | C2 | | | | | |
| Comparative | Comparative | 5.2 | 14.2 | 24.5 | 2.89 | Blue |
| Example 3 | Example | | | | | |
| | Compound | | | | | |
| | C3 | | | | | |

Referring to the results shown in Table 2, it may be seen that Examples of the light emitting elements utilizing the polycyclic compounds according to the present disclosure as host materials of the emission layers exhibit excellent or suitable luminous efficiency and low driving voltage characteristics compared with Comparative Examples.

Meanwhile, it may be seen that Comparative Example Compounds have a decrease in both (e.g., simultaneously) luminous efficiency and driving voltage characteristics compared with Example Compounds. In particular, Comparative Example Compound C2 utilized in Comparative Example 2 is a structure in which a silyl group is fused with a carbazole skeleton. However, it may be seen that unlike the polycyclic compound of an embodiment, the phenyl group bonded to Si is fused with the benzene ring linked to the nitrogen atom of the carbazole skeleton to include a part in which the conjugation is expanded, and thus a relatively low T1 level is exhibited, the luminous efficiency is not only significantly reduced, but also the driving voltage characteristic is reduced compared with Examples.

The light emitting element of an embodiment may include the polycyclic compound of an embodiment, thereby exhibiting a low driving voltage characteristic and providing an effect of improving luminous efficiency.

The polycyclic compound of an embodiment may be utilized as a luminescent material capable of improving a driving voltage characteristic and luminous efficiency of the light emitting element.

The use of “may” when describing embodiments of the present disclosure refers to “one or more embodiments of the present disclosure”.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to a preferred embodiment of the present disclosure, it will be understood that the present disclosure should not be limited to these preferred embodiments but one or more suitable changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims, and equivalents thereof.

What is claimed is:

1. A light emitting element comprising:
a first electrode;
a second electrode on the first electrode; and
at least one functional layer between the first electrode and the second electrode,
wherein the at least one functional layer comprises a polycyclic compound represented by Formula 1: 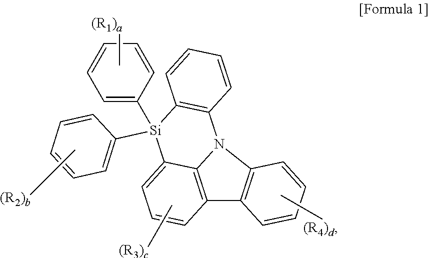
wherein, in Formula 1,
R₁ and R₂ are each independently a hydrogen atom, a deuterium atom, a cyano group, a substituted or unsubstituted silyl group, a substituted or unsubstituted alkyl group having 1 to 20 carbon atoms, a substituted or unsubstituted cycloalkyl group having 3 to 20 ring-forming carbon atoms, a substituted or unsubstituted heterocycloalkyl group having 3 to 20 ring-forming carbon atoms, a substituted or unsubstituted cycloalkenyl group having 3 to 20 ring-forming carbon atoms, a substituted or unsubstituted heterocycloalkenyl group having 3 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms,
R₃ and R₄ are each independently a hydrogen atom, a deuterium atom, or a group represented by Formula 2 or Formula 3,
a and b are each independently an integer of 0 to 5, c is an integer of 0 to 3, and d is an integer of 0 to 4: 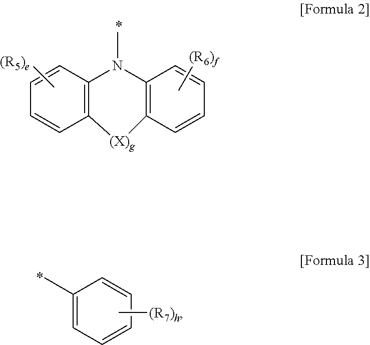
wherein, in Formula 2, g is 0 or 1, and when g is 1, X is a direct linkage,
in Formula 2 and Formula 3,
R₅ to R₇ are each independently a hydrogen atom, a deuterium atom, a cyano group, a substituted or unsubstituted silyl group, a substituted or unsubstituted alkyl group having 1 to 20 carbon atoms, a substituted or unsubstituted cycloalkyl group having 3 to 20 ring-forming carbon atoms, a substituted or unsubstituted heterocycloalkyl group having 3 to 20 ring-forming carbon atoms, a substituted or unsubstituted cycloalkenyl group having 3 to 20 ring-forming carbon atoms, a substituted or unsubstituted heterocycloalkenyl group having 3 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring,
e and f are each independently an integer of 0 to 4, h is an integer of 0 to 5, and [symbol] represents a linking position.

2. The light emitting element of claim 1, wherein
the at least one functional layer comprises an emission layer, a hole transport region between the first electrode and the emission layer, and an electron transport region between the emission layer and the second electrode, and
the emission layer comprises the polycyclic compound.

3. The light emitting element of claim 2, wherein the emission layer is to emit delayed fluorescence or phosphorescence.

4. The light emitting element of claim 2, wherein
the emission layer comprises a host and a dopant, and
the host comprises the polycyclic compound.

5. The light emitting element of claim 2, wherein the emission layer is to emit light having a center wavelength of about 430 nm to about 480 nm.

6. The light emitting element of claim 1, wherein R₁ and R₂ are each independently a hydrogen atom, a deuterium atom, or a substituted or unsubstituted phenyl group.

7. The light emitting element of claim 1, wherein R₃ and/or R₄ is represented by Formula 2 or Formula 3.

8. The light emitting element of claim 1, wherein Formula 2 is represented by Formula 2-1 or Formula 2-2: 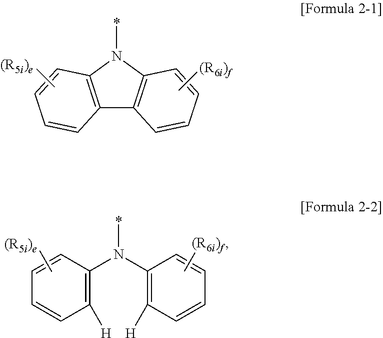
wherein, in Formula 2-1 and Formula 2-2,
R₅ᵢ and R₆ᵢ are each independently a hydrogen atom, a deuterium atom, a substituted or unsubstituted silyl group, a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms, and
e and f are each independently an integer of 0 to 4.

9. The light emitting element of claim 1, wherein the polycyclic compound represented by Formula 1 is represented by Formula 1-1 or Formula 1-2: 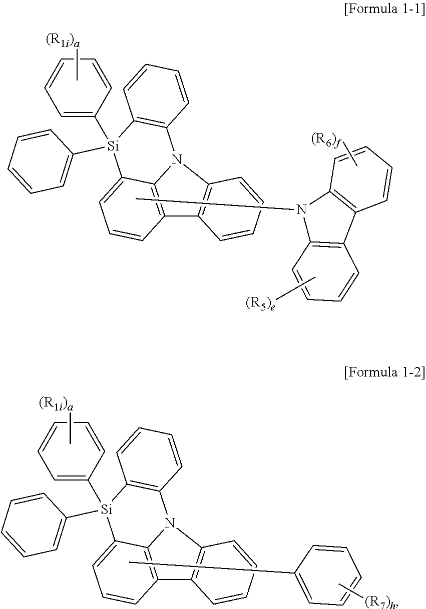
wherein, in Formula 1-1 and Formula 1-2,
R₁ᵢ is a hydrogen atom, a deuterium atom, a substituted or unsubstituted alkyl group having 1 to 10 carbon atoms, or a substituted or unsubstituted aryl group having 6 to 20 ring-forming carbon atoms, and
R₅ to R₇, a, e, f, and h are the same as respectively defined in Formula 1 to Formula 3.

10. The light emitting element of claim 9, wherein the polycyclic compound represented by Formula 1-1 is represented by Formula 1-1-1 or Formula 1-1-2: 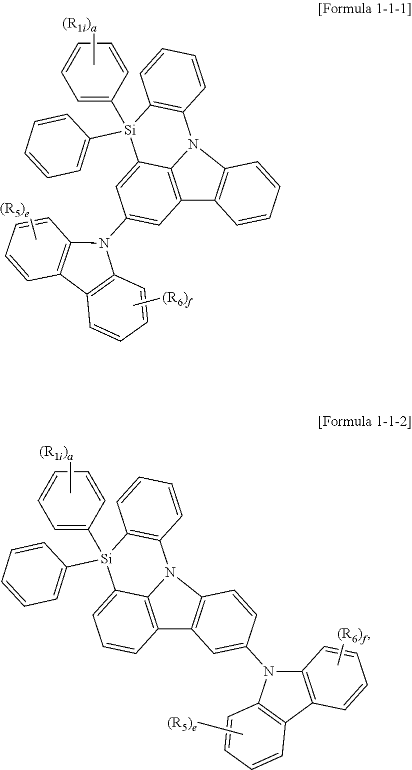
wherein, in Formula 1-1-1 and Formula 1-1-2, R₁ᵢ, R₅, R₆, a, e, f, and h are the same as respectively defined in Formula 1-1 and Formula 2.

11. The light emitting element of claim 9, wherein the polycyclic compound represented by Formula 1-2 is represented by Formula 1-2-1 or Formula 1-2-2: 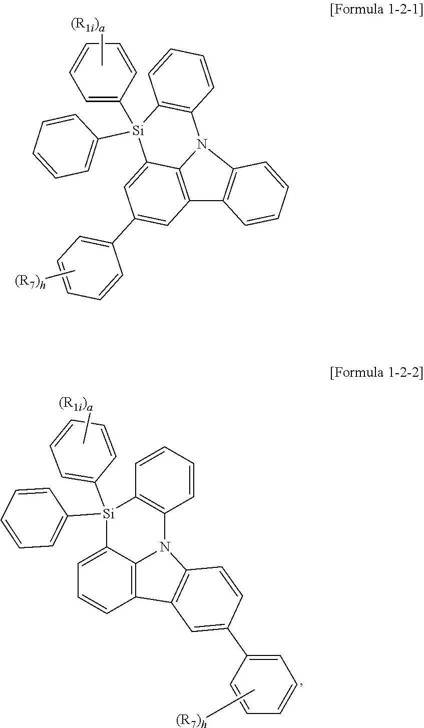
wherein, in Formula 1-2-1 and Formula 1-2-2, R₁ᵢ, R₇, a, and h are the same as respectively defined in Formula 1-2 and Formula 3.

12. The light emitting element of claim 1, wherein R₅ to R₇ are each independently a hydrogen atom, a deuterium atom, or a group represented by any one selected from among R-1 to R-5:

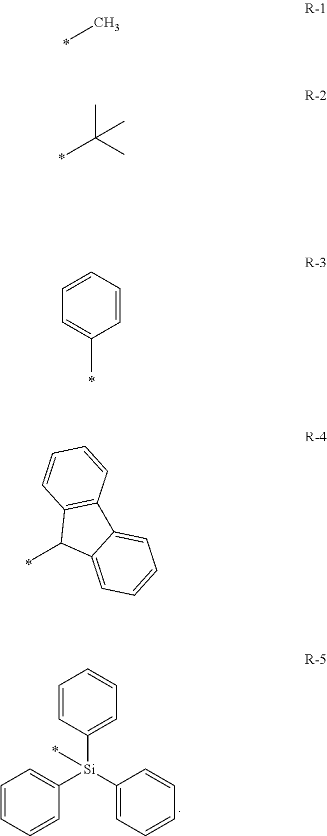

13. The light emitting element of claim 1, wherein the polycyclic compound is represented by any one selected from among polycyclic compounds of Compound Group 1:

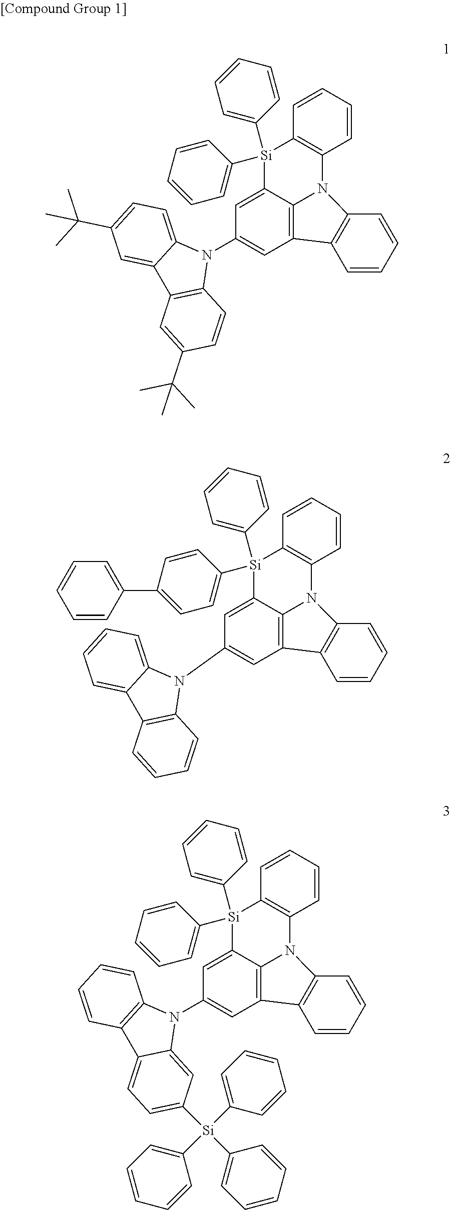 [SMILES: CC(C)(C)c1ccc2c(c1)c1cc(C(C)(C)C)ccc1n2-c1cc2c3c(c1)c1ccccc1n3-c1ccccc1[Si]2(c1ccccc1)c1ccccc1 ; c1ccc(-c2ccc([Si]3(c4ccccc4)c4ccccc4-n4c5ccccc5c5cc(-n6c7ccccc7c7ccccc76)cc3c54)cc2)cc1 ; c1ccc([Si](c2ccccc2)(c2ccccc2)c2ccc3c4ccccc4n(-c4cc5c6c(c4)c4ccccc4n6-c4ccccc4[Si]5(c4ccccc4)c4ccccc4)c3c2)cc1]

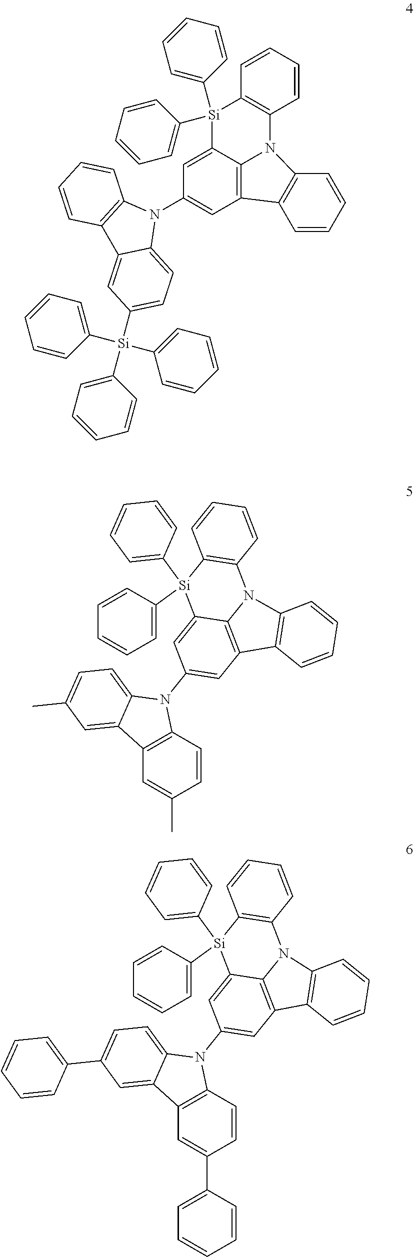

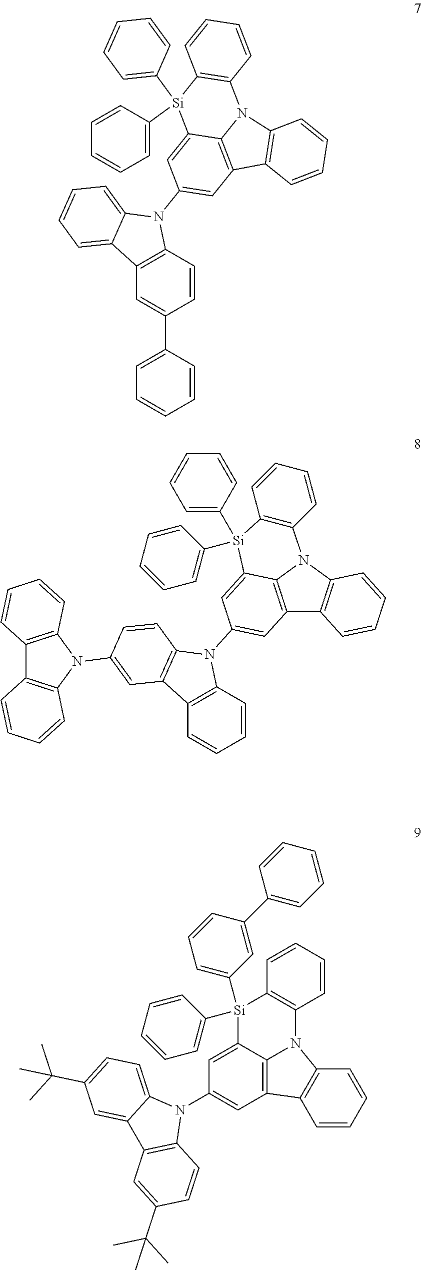

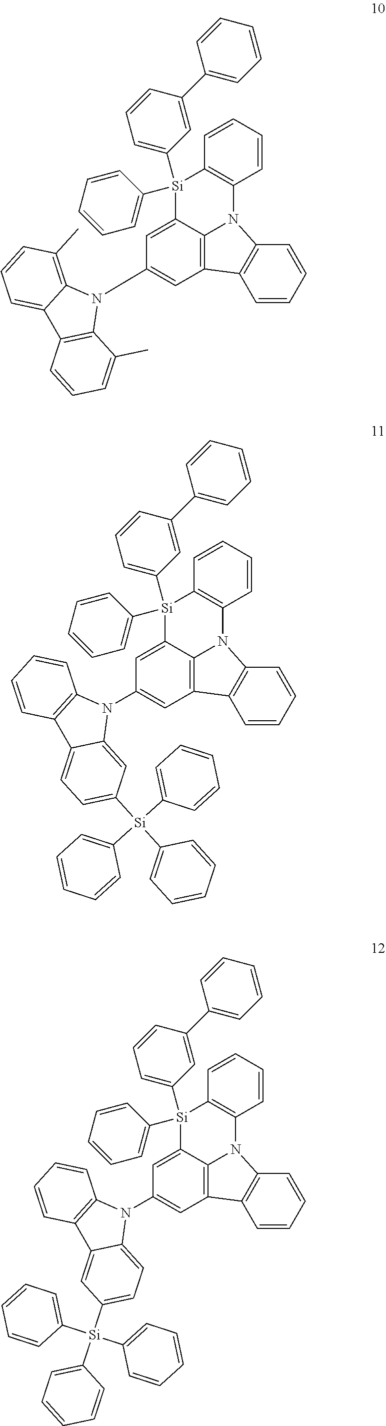 [SMILES: Cc1cccc2c3cccc(C)c3n(-c3cc4c5c(c3)c3ccccc3n5-c3ccccc3[Si]4(c3ccccc3)c3cccc(-c4ccccc4)c3)c12 ; c1ccc(-c2cccc([Si]3(c4ccccc4)c4ccccc4-n4c5ccccc5c5cc(-n6c7ccccc7c7ccc([Si](c8ccccc8)(c8ccccc8)c8ccccc8)cc76)cc3c54)c2)cc1 ; c1ccc(-c2cccc([Si]3(c4ccccc4)c4ccccc4-n4c5ccccc5c5cc(-n6c7ccccc7c7cc([Si](c8ccccc8)(c8ccccc8)c8ccccc8)ccc76)cc3c54)c2)cc1]

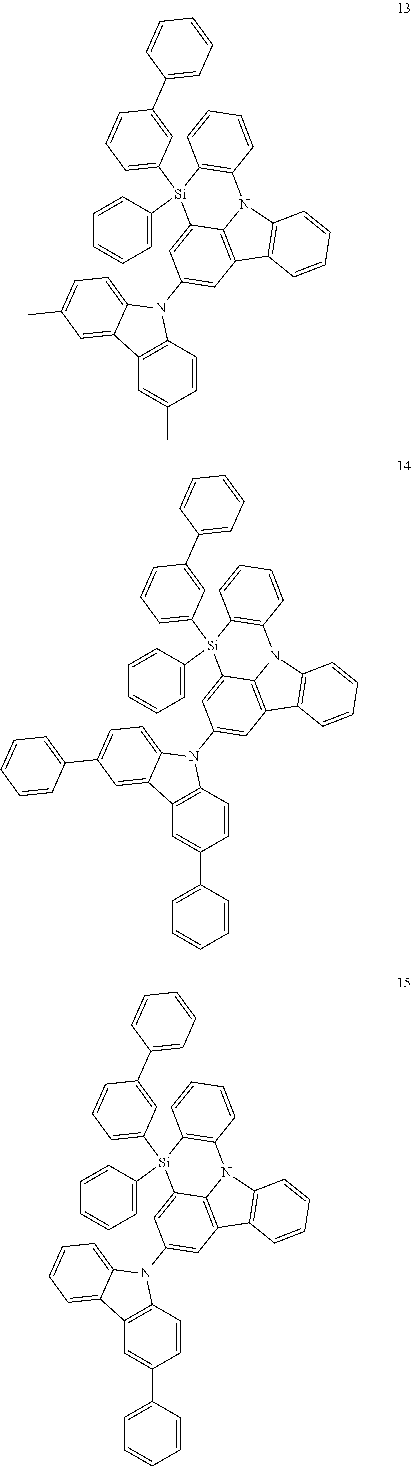 [SMILES: Cc1ccc2c(c1)c1cc(C)ccc1n2-c1cc2c3c(c1)c1ccccc1n3-c1ccccc1[Si]2(c1ccccc1)c1cccc(-c2ccccc2)c1 ; c1ccc(-c2cccc([Si]3(c4ccccc4)c4ccccc4-n4c5ccccc5c5cc(-n6c7ccc(-c8ccccc8)cc7c7cc(-c8ccccc8)ccc76)cc3c54)c2)cc1 ; c1ccc(-c2cccc([Si]3(c4ccccc4)c4ccccc4-n4c5ccccc5c5cc(-n6c7ccccc7c7cc(-c8ccccc8)ccc76)cc3c54)c2)cc1]

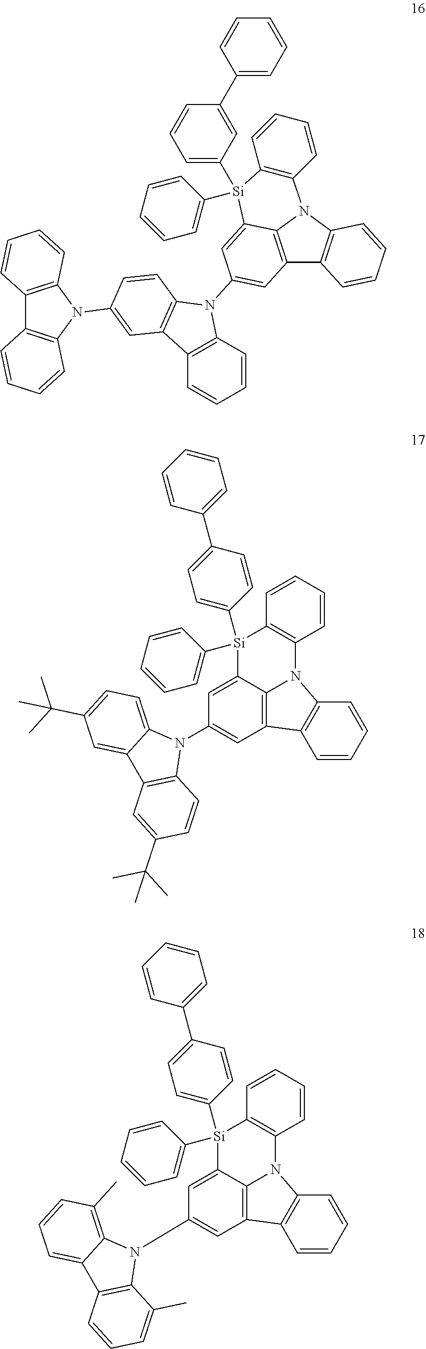 [SMILES: c1ccc(-c2cccc([Si]3(c4ccccc4)c4ccccc4-n4c5ccccc5c5cc(-n6c7ccccc7c7cc(-n8c9ccccc9c9ccccc98)ccc76)cc3c54)c2)cc1 ; CC(C)(C)c1ccc2c(c1)c1cc(C(C)(C)C)ccc1n2-c1cc2c3c(c1)c1ccccc1n3-c1ccccc1[Si]2(c1ccccc1)c1ccc(-c2ccccc2)cc1 ; Cc1cccc2c3cccc(C)c3n(-c3cc4c5c(c3)c3ccccc3n5-c3ccccc3[Si]4(c3ccccc3)c3ccc(-c4ccccc4)cc3)c12]

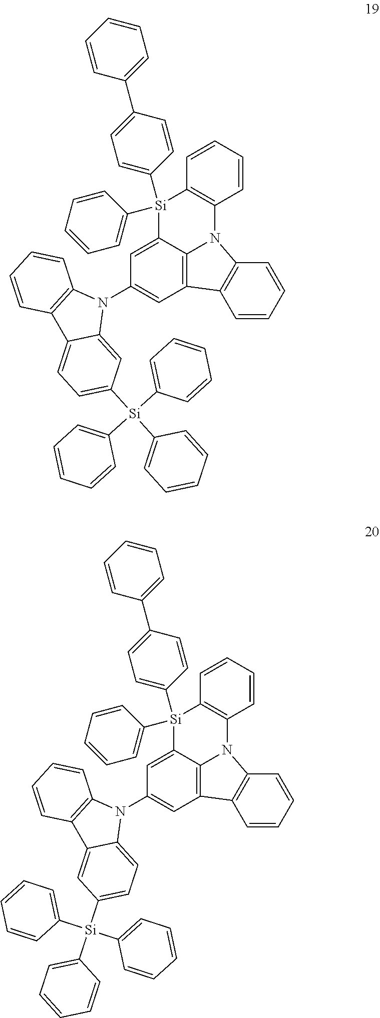 [SMILES: c1ccc(-c2ccc([Si]3(c4ccccc4)c4ccccc4-n4c5ccccc5c5cc(-n6c7ccccc7c7ccc([Si](c8ccccc8)(c8ccccc8)c8ccccc8)cc76)cc3c54)cc2)cc1 ; c1ccc(-c2ccc([Si]3(c4ccccc4)c4ccccc4-n4c5ccccc5c5cc(-n6c7ccccc7c7cc([Si](c8ccccc8)(c8ccccc8)c8ccccc8)ccc76)cc3c54)cc2)cc1]

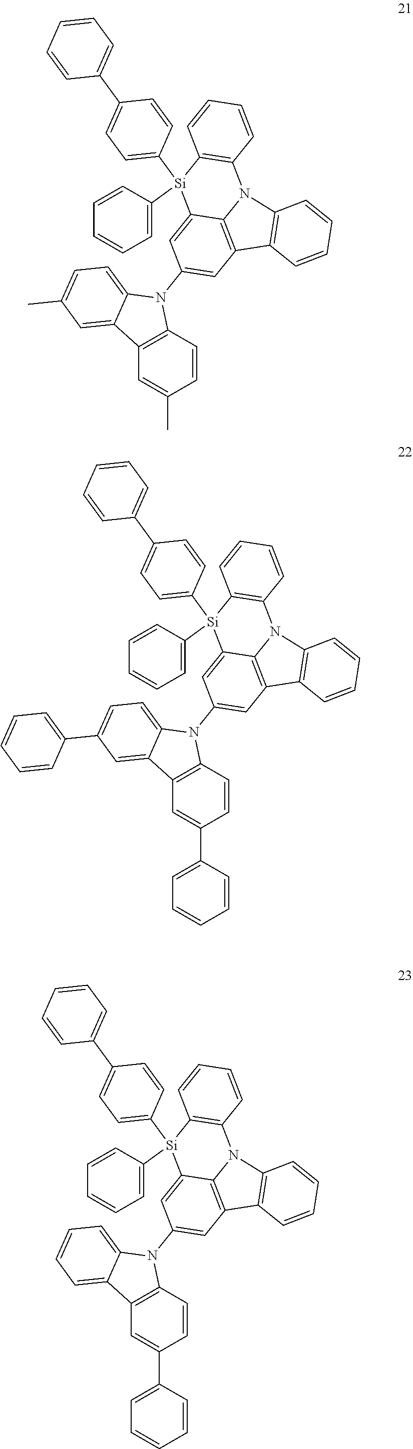 [SMILES: Cc1ccc2c(c1)c1cc(C)ccc1n2-c1cc2c3c(c1)c1ccccc1n3-c1ccccc1[Si]2(c1ccccc1)c1ccc(-c2ccccc2)cc1 ; c1ccc(-c2ccc([Si]3(c4ccccc4)c4ccccc4-n4c5ccccc5c5cc(-n6c7ccc(-c8ccccc8)cc7c7cc(-c8ccccc8)ccc76)cc3c54)cc2)cc1 ; c1ccc(-c2ccc([Si]3(c4ccccc4)c4ccccc4-n4c5ccccc5c5cc(-n6c7ccccc7c7cc(-c8ccccc8)ccc76)cc3c54)cc2)cc1]

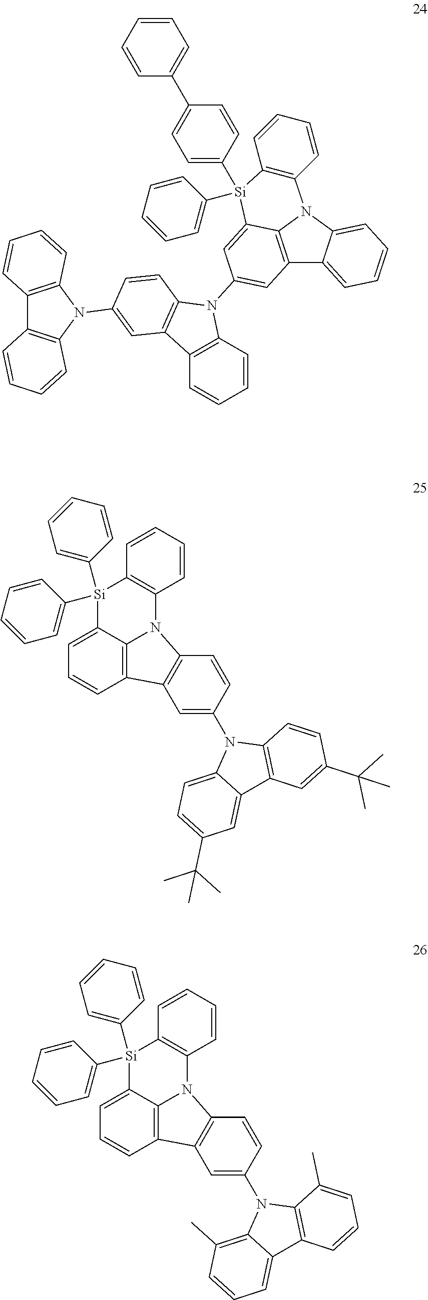 [SMILES: c1ccc(-c2ccc([Si]3(c4ccccc4)c4ccccc4-n4c5ccccc5c5cc(-n6c7ccccc7c7cc(-n8c9ccccc9c9ccccc98)ccc76)cc3c54)cc2)cc1 ; CC(C)(C)c1ccc2c(c1)c1cc(C(C)(C)C)ccc1n2-c1ccc2c(c1)c1cccc3c1n2-c1ccccc1[Si]3(c1ccccc1)c1ccccc1 ; Cc1cccc2c3cccc(C)c3n(-c3ccc4c(c3)c3cccc5c3n4-c3ccccc3[Si]5(c3ccccc3)c3ccccc3)c12]

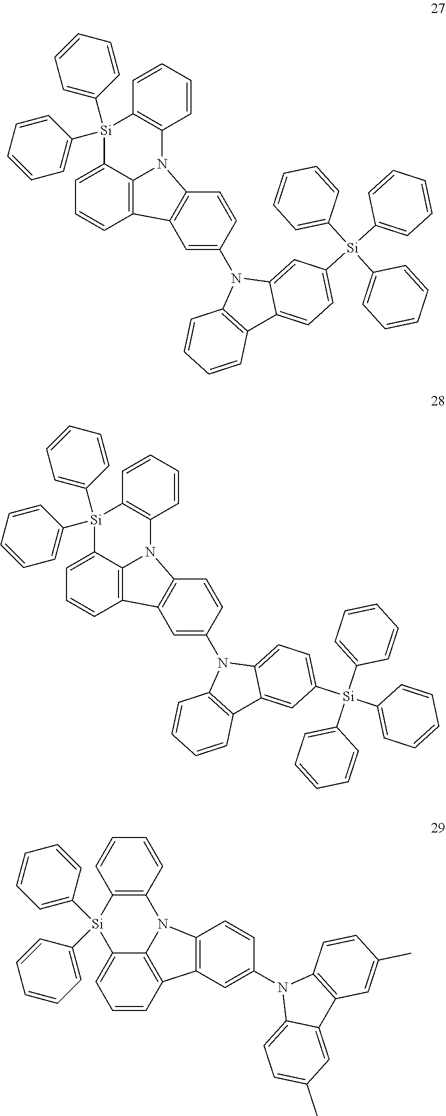 [SMILES: c1ccc([Si](c2ccccc2)(c2ccccc2)c2ccc3c4ccccc4n(-c4ccc5c(c4)c4cccc6c4n5-c4ccccc4[Si]6(c4ccccc4)c4ccccc4)c3c2)cc1 ; c1ccc([Si](c2ccccc2)(c2ccccc2)c2ccc3c(c2)c2ccccc2n3-c2ccc3c(c2)c2cccc4c2n3-c2ccccc2[Si]4(c2ccccc2)c2ccccc2)cc1 ; Cc1ccc2c(c1)c1cc(C)ccc1n2-c1ccc2c(c1)c1cccc3c1n2-c1ccccc1[Si]3(c1ccccc1)c1ccccc1]

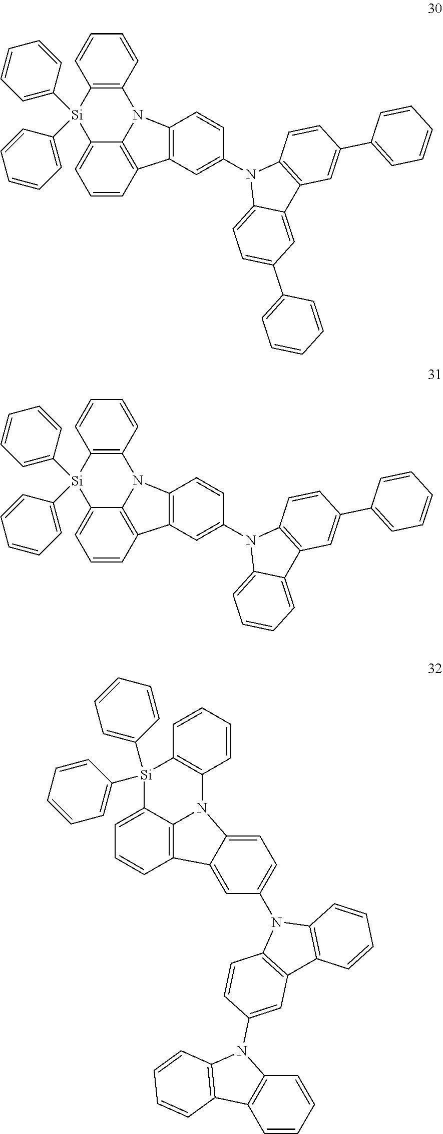 [SMILES: c1ccc(-c2ccc3c(c2)c2cc(-c4ccccc4)ccc2n3-c2ccc3c(c2)c2cccc4c2n3-c2ccccc2[Si]4(c2ccccc2)c2ccccc2)cc1 ; c1ccc(-c2ccc3c(c2)c2ccccc2n3-c2ccc3c(c2)c2cccc4c2n3-c2ccccc2[Si]4(c2ccccc2)c2ccccc2)cc1 ; c1ccc([Si]2(c3ccccc3)c3ccccc3-n3c4ccc(-n5c6ccccc6c6cc(-n7c8ccccc8c8ccccc87)ccc65)cc4c4cccc2c43)cc1]

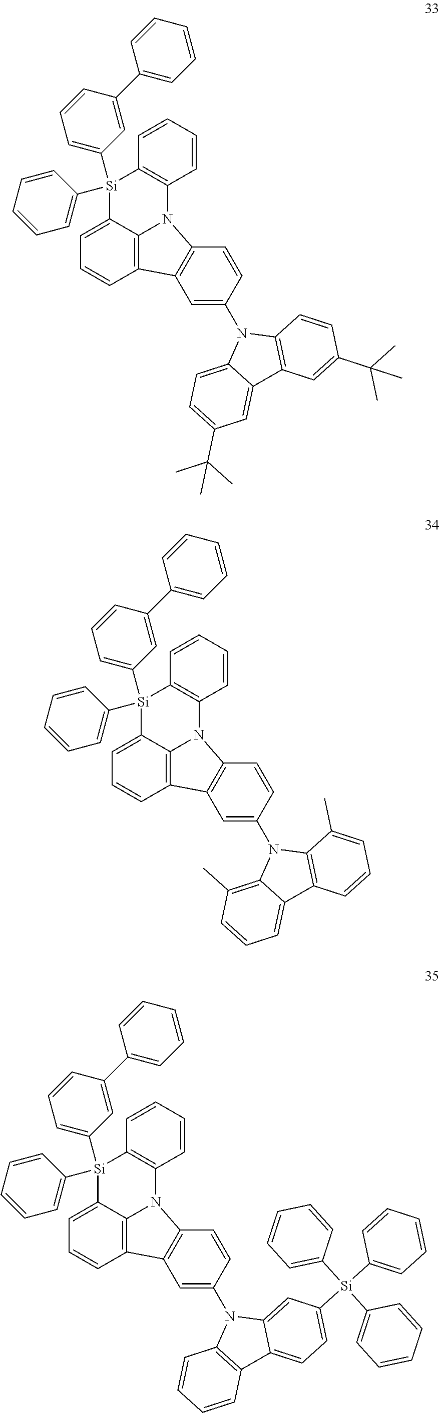

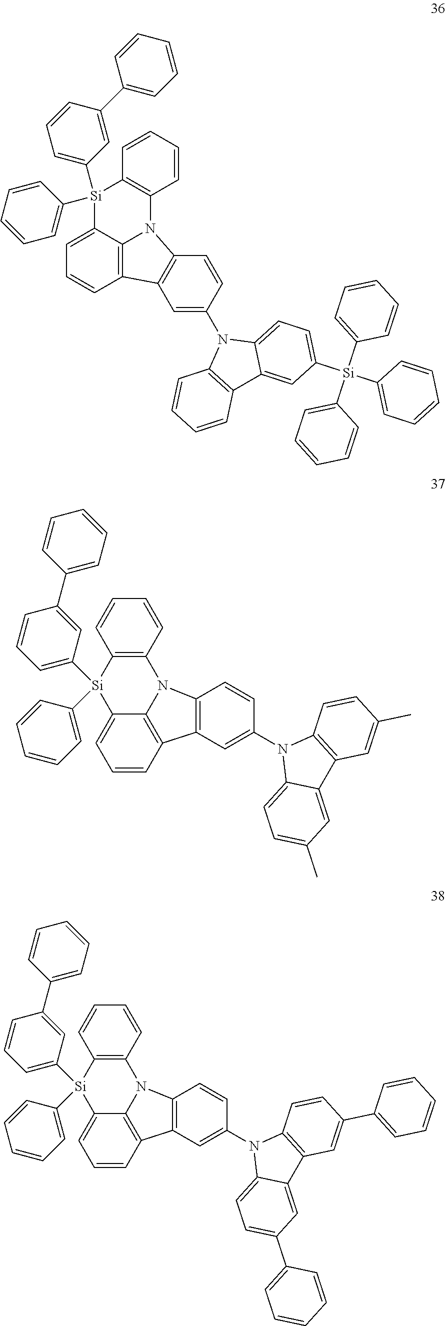 [SMILES: c1ccc(-c2cccc([Si]3(c4ccccc4)c4ccccc4-n4c5ccc(-n6c7ccccc7c7cc([Si](c8ccccc8)(c8ccccc8)c8ccccc8)ccc76)cc5c5cccc3c54)c2)cc1 ; Cc1ccc2c(c1)c1cc(C)ccc1n2-c1ccc2c(c1)c1cccc3c1n2-c1ccccc1[Si]3(c1ccccc1)c1cccc(-c2ccccc2)c1 ; c1ccc(-c2cccc([Si]3(c4ccccc4)c4ccccc4-n4c5ccc(-n6c7ccc(-c8ccccc8)cc7c7cc(-c8ccccc8)ccc76)cc5c5cccc3c54)c2)cc1]

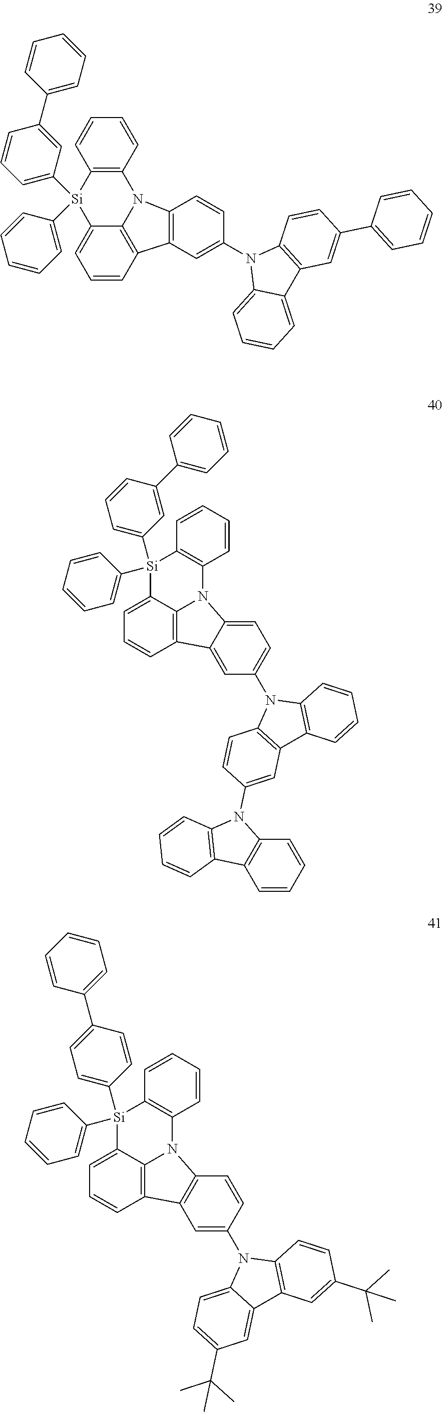 [SMILES: c1ccc(-c2cccc([Si]3(c4ccccc4)c4ccccc4-n4c5ccc(-n6c7ccccc7c7cc(-c8ccccc8)ccc76)cc5c5cccc3c54)c2)cc1 ; c1ccc(-c2cccc([Si]3(c4ccccc4)c4ccccc4-n4c5ccc(-n6c7ccccc7c7cc(-n8c9ccccc9c9ccccc98)ccc76)cc5c5cccc3c54)c2)cc1 ; CC(C)(C)c1ccc2c(c1)c1cc(C(C)(C)C)ccc1n2-c1ccc2c(c1)c1cccc3c1n2-c1ccccc1[Si]3(c1ccccc1)c1ccc(-c2ccccc2)cc1]

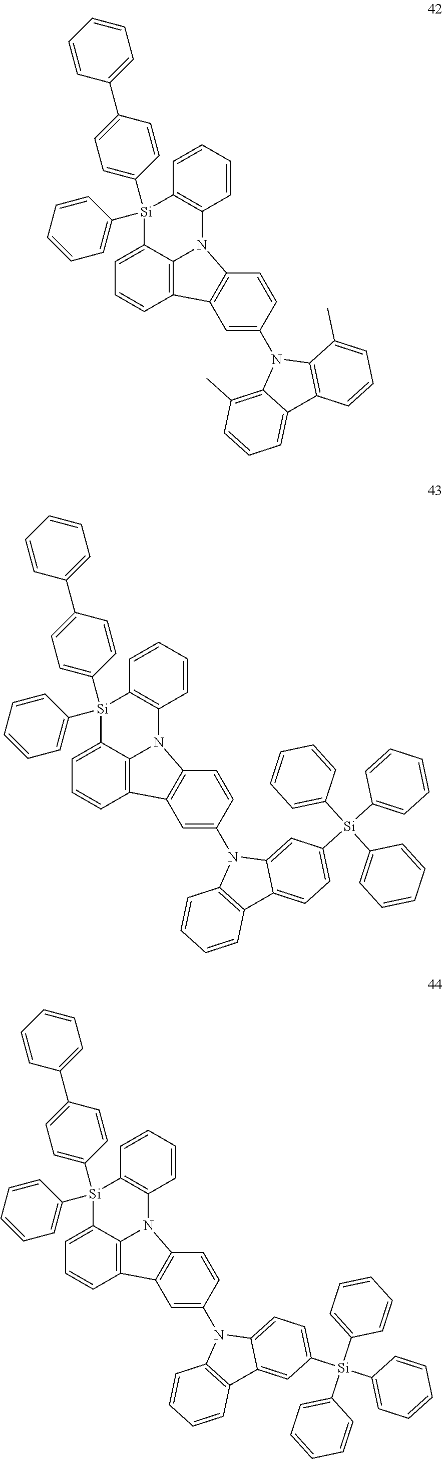 [SMILES: Cc1cccc2c3cccc(C)c3n(-c3ccc4c(c3)c3cccc5c3n4-c3ccccc3[Si]5(c3ccccc3)c3ccc(-c4ccccc4)cc3)c12 ; c1ccc(-c2ccc([Si]3(c4ccccc4)c4ccccc4-n4c5ccc(-n6c7ccccc7c7ccc([Si](c8ccccc8)(c8ccccc8)c8ccccc8)cc76)cc5c5cccc3c54)cc2)cc1 ; c1ccc(-c2ccc([Si]3(c4ccccc4)c4ccccc4-n4c5ccc(-n6c7ccccc7c7cc([Si](c8ccccc8)(c8ccccc8)c8ccccc8)ccc76)cc5c5cccc3c54)cc2)cc1]

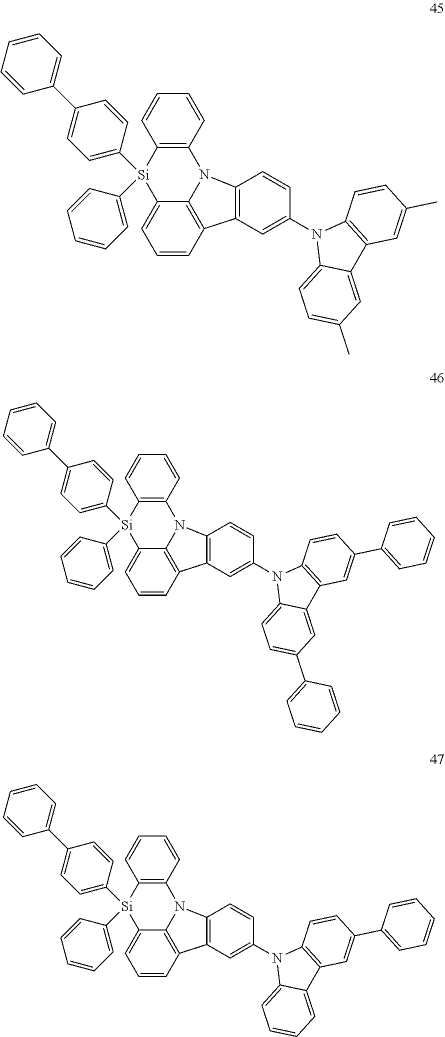 [SMILES: Cc1ccc2c(c1)c1cc(C)ccc1n2-c1ccc2c(c1)c1cccc3c1n2-c1ccccc1[Si]3(c1ccccc1)c1ccc(-c2ccccc2)cc1 ; c1ccc(-c2ccc([Si]3(c4ccccc4)c4ccccc4-n4c5ccc(-n6c7ccc(-c8ccccc8)cc7c7cc(-c8ccccc8)ccc76)cc5c5cccc3c54)cc2)cc1 ; c1ccc(-c2ccc([Si]3(c4ccccc4)c4ccccc4-n4c5ccc(-n6c7ccccc7c7cc(-c8ccccc8)ccc76)cc5c5cccc3c54)cc2)cc1]

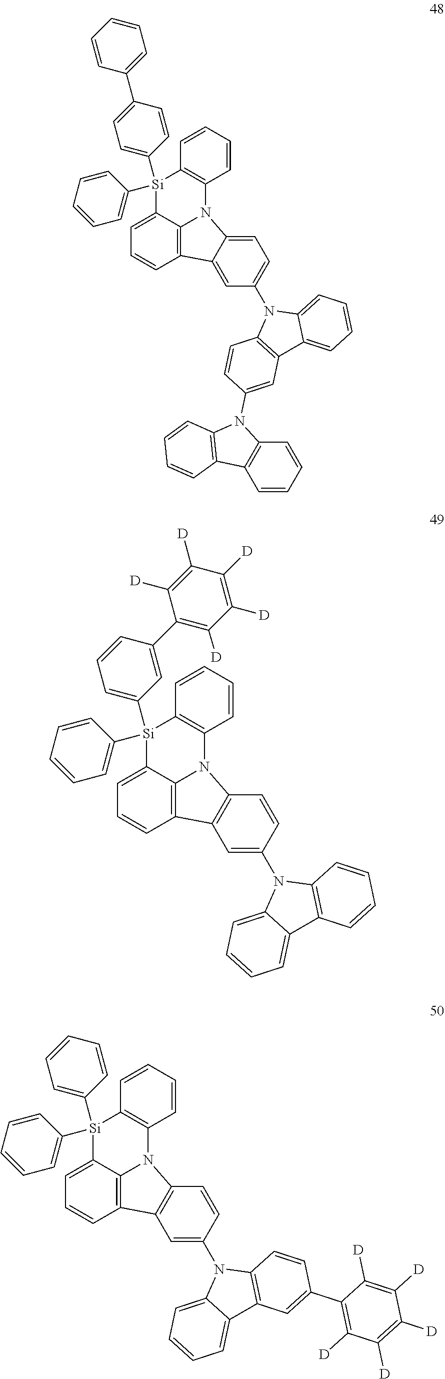 [SMILES: c1ccc(-c2ccc([Si]3(c4ccccc4)c4ccccc4-n4c5ccc(-n6c7ccccc7c7cc(-n8c9ccccc9c9ccccc98)ccc76)cc5c5cccc3c54)cc2)cc1 ; [2H]c1c([2H])c([2H])c(-c2cccc([Si]3(c4ccccc4)c4ccccc4-n4c5ccc(-n6c7ccccc7c7ccccc76)cc5c5cccc3c54)c2)c([2H])c1[2H] ; [2H]c1c([2H])c([2H])c(-c2ccc3c(c2)c2ccccc2n3-c2ccc3c(c2)c2cccc4c2n3-c2ccccc2[Si]4(c2ccccc2)c2ccccc2)c([2H])c1[2H]]

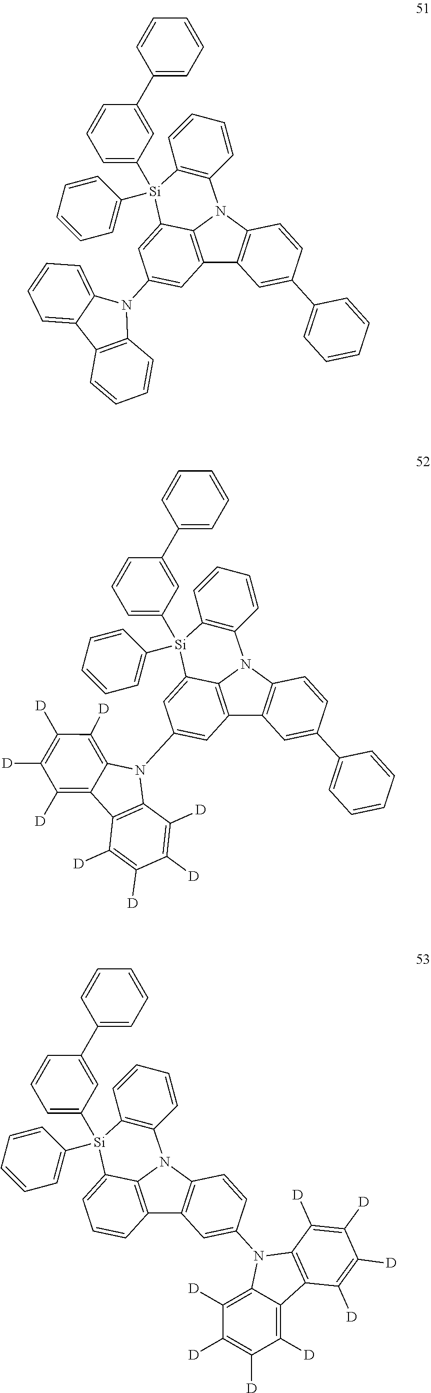 [SMILES: c1ccc(-c2cccc([Si]3(c4ccccc4)c4ccccc4-n4c5ccc(-c6ccccc6)cc5c5cc(-n6c7ccccc7c7ccccc76)cc3c54)c2)cc1 ; [2H]c1c([2H])c([2H])c2c(c1[2H])c1c([2H])c([2H])c([2H])c([2H])c1n2-c1cc2c3c(c1)c1cc(-c4ccccc4)ccc1n3-c1ccccc1[Si]2(c1ccccc1)c1cccc(-c2ccccc2)c1 ; [2H]c1c([2H])c([2H])c2c(c1[2H])c1c([2H])c([2H])c([2H])c([2H])c1n2-c1ccc2c(c1)c1cccc3c1n2-c1ccccc1[Si]3(c1ccccc1)c1cccc(-c2ccccc2)c1]

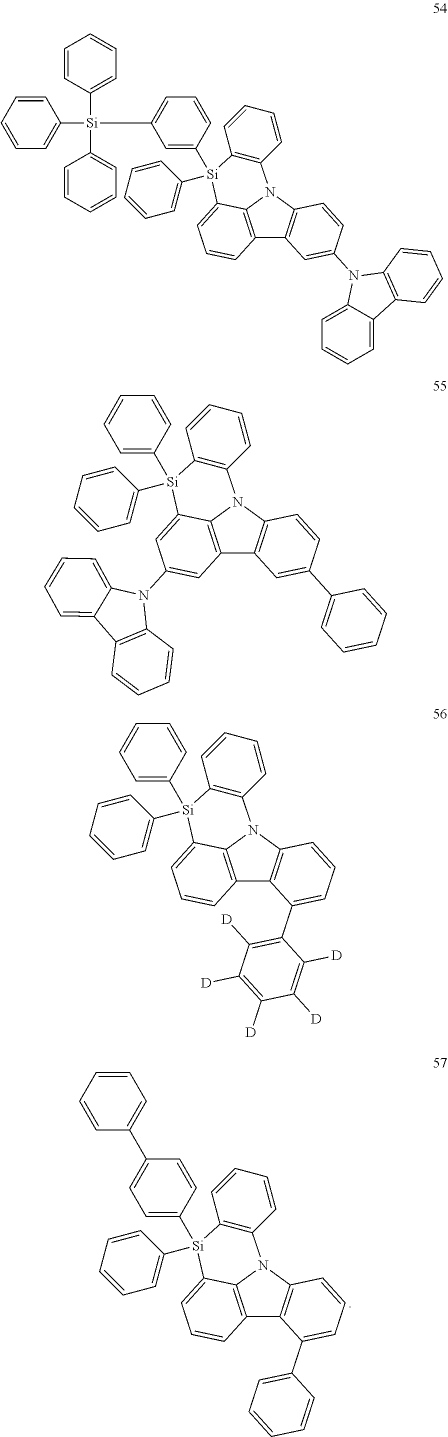

14. A polycyclic compound represented by Formula 1: 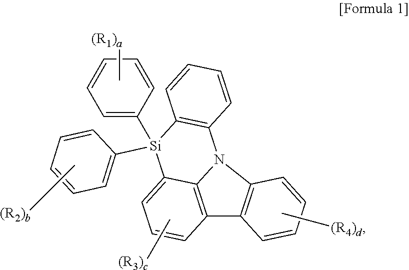
wherein, in Formula 1,
R₁ and R₂ are each independently a hydrogen atom, a deuterium atom, a cyano group, a substituted or unsubstituted silyl group, a substituted or unsubstituted alkyl group having 1 to 20 carbon atoms, a substituted or unsubstituted cycloalkyl group having 3 to 20 ring-forming carbon atoms, a substituted or unsubstituted heterocycloalkyl group having 3 to 20 ring-forming carbon atoms, a substituted or unsubstituted cycloalkenyl group having 3 to 20 ring-forming carbon atoms, a substituted or unsubstituted heterocycloalkenyl group having 3 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms,
R₃ and R₄ are each independently a hydrogen atom, a deuterium atom, or a group represented by Formula 2 or Formula 3,
a and b are each independently an integer of 0 to 5, c is an integer of 0 to 3, and d is an integer of 0 to 4: 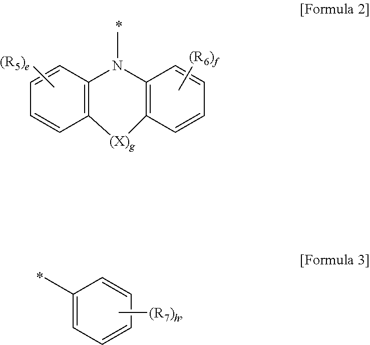
wherein, in Formula 2, g is 0 or 1, and when g is 1, X is a direct linkage,
in Formula 2 and Formula 3,
R₅ to R₇ are each independently a hydrogen atom, a deuterium atom, a cyano group, a substituted or unsubstituted silyl group, a substituted or unsubstituted alkyl group having 1 to 20 carbon atoms, a substituted or unsubstituted cycloalkyl group having 3 to 20 ring-forming carbon atoms, a substituted or unsubstituted heterocycloalkyl group having 3 to 20 ring-forming carbon atoms, a substituted or unsubstituted cycloalkenyl group having 3 to 20 ring-forming carbon atoms, a substituted or unsubstituted heterocycloalkenyl group having 3 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring,
e and f are each independently an integer of 0 to 4, h is an integer of 0 to 5, and [symbol] represents a linking position.

15. The polycyclic compound of claim 14, wherein one selected from among R₃ and R₄ is represented by Formula 2 or Formula 3, and the other is a hydrogen atom or a deuterium atom.

16. The polycyclic compound of claim 14, wherein Formula 2 is represented by Formula 2-1 or Formula 2-2: 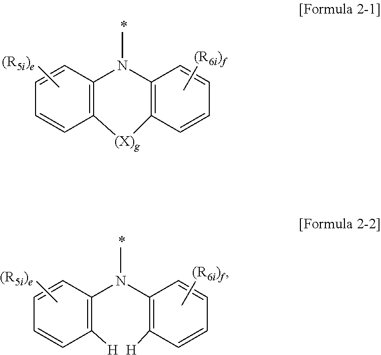
wherein, in Formula 2-1 and Formula 2-2,
R₅ᵢ and R₆ᵢ are each independently a hydrogen atom, a deuterium atom, a substituted or unsubstituted silyl group, a substituted or unsubstituted alkyl group having 1 to 10 carbon atoms, a substituted or unsubstituted aryl group having 6 to 20 ring-forming carbon atoms, or a substituted or unsubstituted heteroaryl group having 2 to 20 ring-forming carbon atoms, and
e and f are each independently an integer of 0 to 4.

17. The polycyclic compound of claim 14, wherein the polycyclic compound represented by Formula 1 is represented by Formula 1-1 or Formula 1-2: 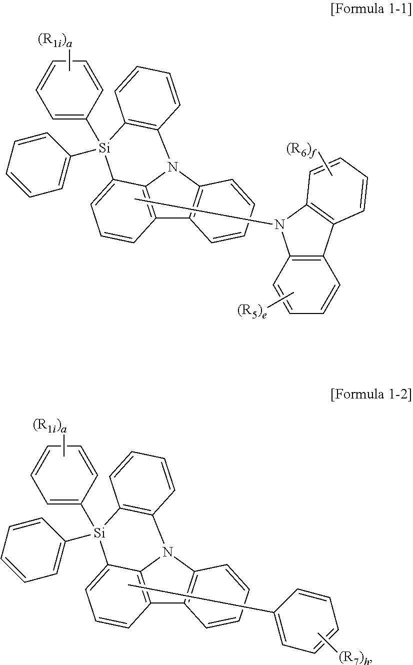
wherein, in Formula 1-1 and Formula 1-2, R₁ᵢ is a hydrogen atom, a deuterium atom, a substituted or unsubstituted alkyl group having 1 to 10 carbon atoms, or a substituted or unsubstituted aryl group having 6 to 20 ring-forming carbon atoms, and
R₅ to R₇, a, e, f, and h are the same as respectively defined in Formula 1 to Formula 3.

18. The polycyclic compound of claim 17, wherein the polycyclic compound represented by Formula 1-1 is represented by Formula 1-1-1 or Formula 1-1-2: 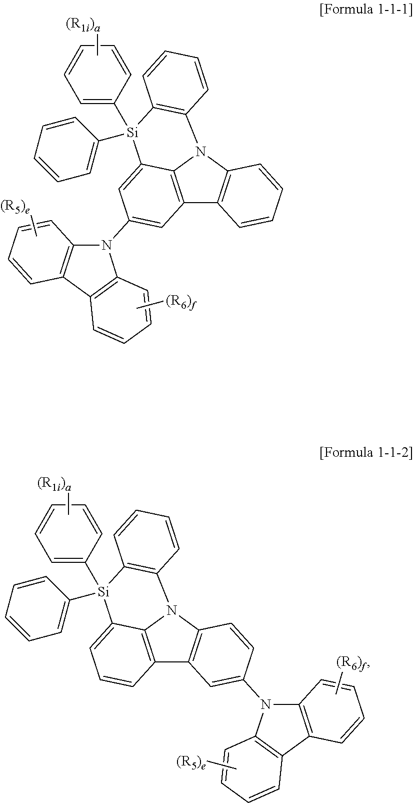
wherein, in Formula 1-1-1 and Formula 1-1-2, R₁ᵢ, R₅, R₆, a, e, and f are the same as respectively defined in Formula 1-1 and Formula 2.

19. The polycyclic compound of claim 17, wherein the polycyclic compound represented by Formula 1-2 is represented by Formula 1-2-1 or Formula 1-2-2: 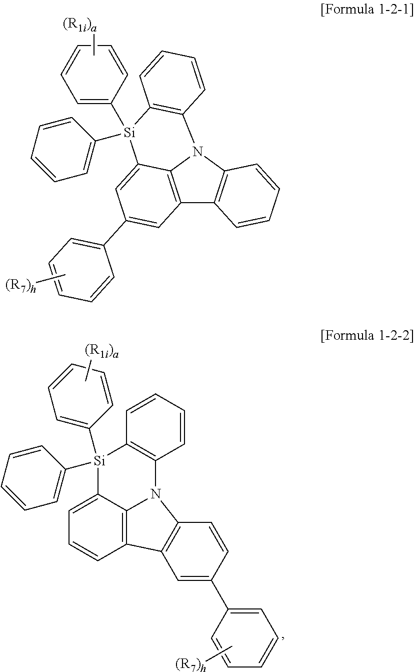
wherein, in Formula 1-2-1 and Formula 1-2-2, R₁ᵢ, R₇, a, and h are the same as respectively defined in Formula 1-2 and Formula 3.

20. The polycyclic compound of claim 14, wherein the polycyclic compound represented by Formula 1 is represented by any one selected from among compounds of Compound Group 1: 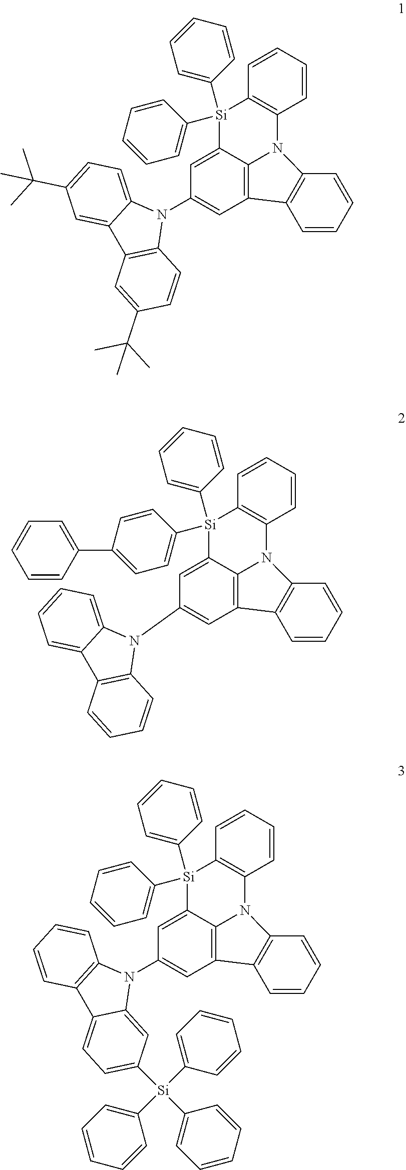 [SMILES: CC(C)(C)c1ccc2c(c1)c1cc(C(C)(C)C)ccc1n2-c1cc2c3c(c1)c1ccccc1n3-c1ccccc1[Si]2(c1ccccc1)c1ccccc1 ; c1ccc(-c2ccc([Si]3(c4ccccc4)c4ccccc4-n4c5ccccc5c5cc(-n6c7ccccc7c7ccccc76)cc3c54)cc2)cc1 ; c1ccc([Si](c2ccccc2)(c2ccccc2)c2ccc3c4ccccc4n(-c4cc5c6c(c4)c4ccccc4n6-c4ccccc4[Si]5(c4ccccc4)c4ccccc4)c3c2)cc1] 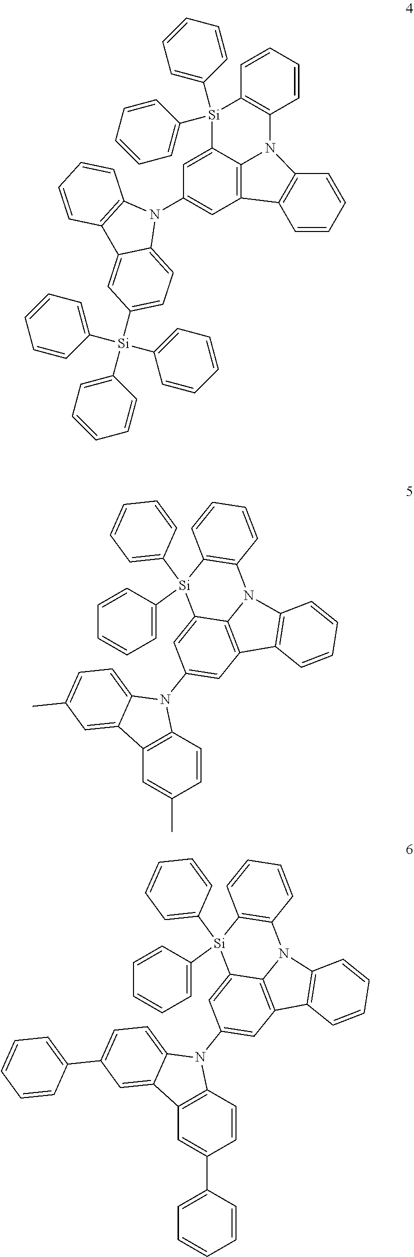 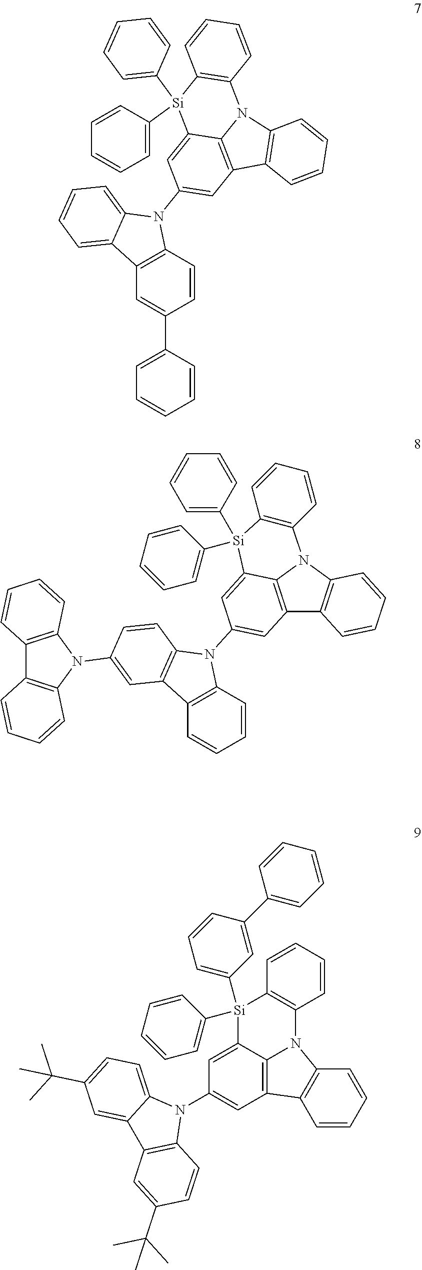 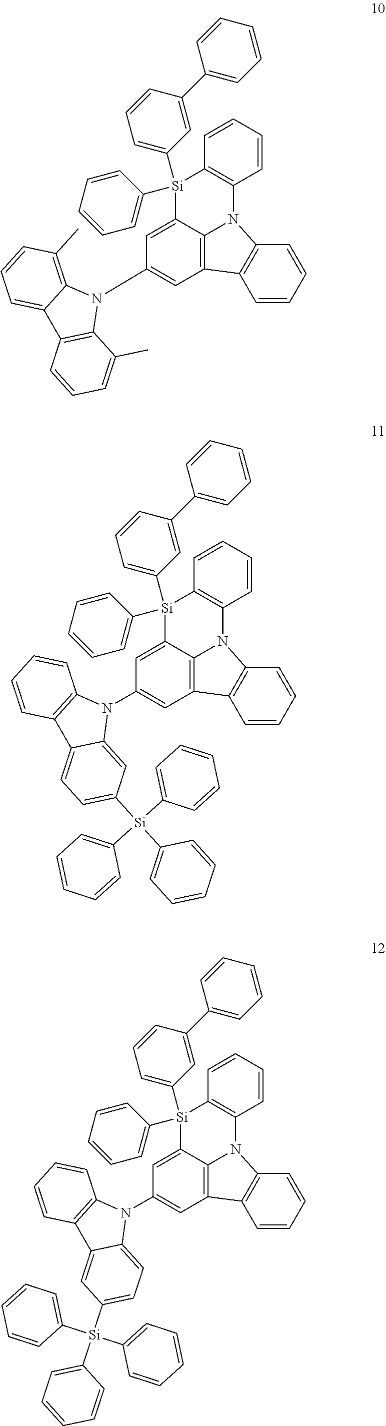 [SMILES: Cc1cccc2c3cccc(C)c3n(-c3cc4c5c(c3)c3ccccc3n5-c3ccccc3[Si]4(c3ccccc3)c3cccc(-c4ccccc4)c3)c12 ; c1ccc(-c2cccc([Si]3(c4ccccc4)c4ccccc4-n4c5ccccc5c5cc(-n6c7ccccc7c7ccc([Si](c8ccccc8)(c8ccccc8)c8ccccc8)cc76)cc3c54)c2)cc1 ; c1ccc(-c2cccc([Si]3(c4ccccc4)c4ccccc4-n4c5ccccc5c5cc(-n6c7ccccc7c7cc([Si](c8ccccc8)(c8ccccc8)c8ccccc8)ccc76)cc3c54)c2)cc1] 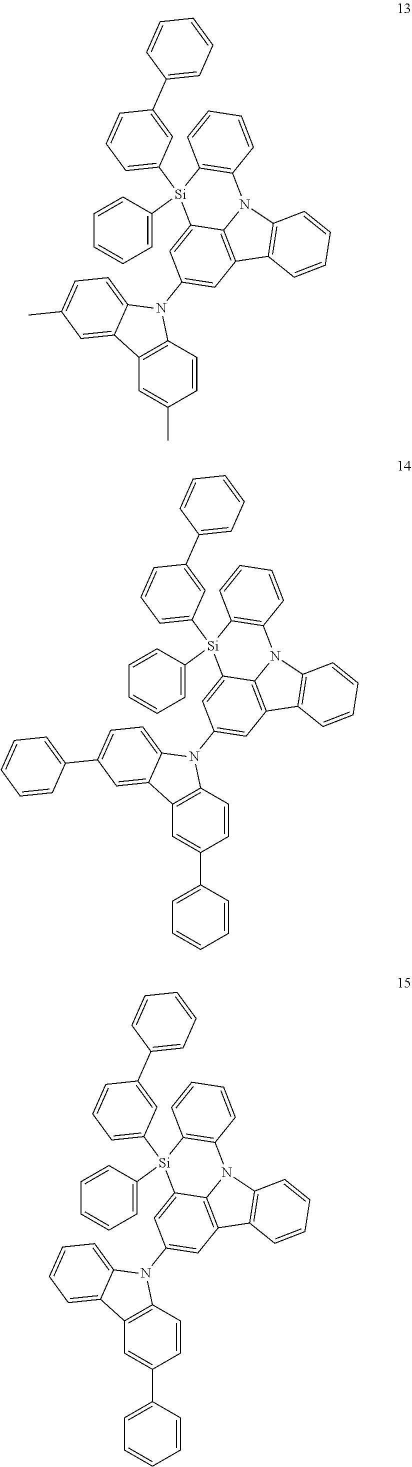 [SMILES: Cc1ccc2c(c1)c1cc(C)ccc1n2-c1cc2c3c(c1)c1ccccc1n3-c1ccccc1[Si]2(c1ccccc1)c1cccc(-c2ccccc2)c1 ; c1ccc(-c2cccc([Si]3(c4ccccc4)c4ccccc4-n4c5ccccc5c5cc(-n6c7ccc(-c8ccccc8)cc7c7cc(-c8ccccc8)ccc76)cc3c54)c2)cc1 ; c1ccc(-c2cccc([Si]3(c4ccccc4)c4ccccc4-n4c5ccccc5c5cc(-n6c7ccccc7c7cc(-c8ccccc8)ccc76)cc3c54)c2)cc1] 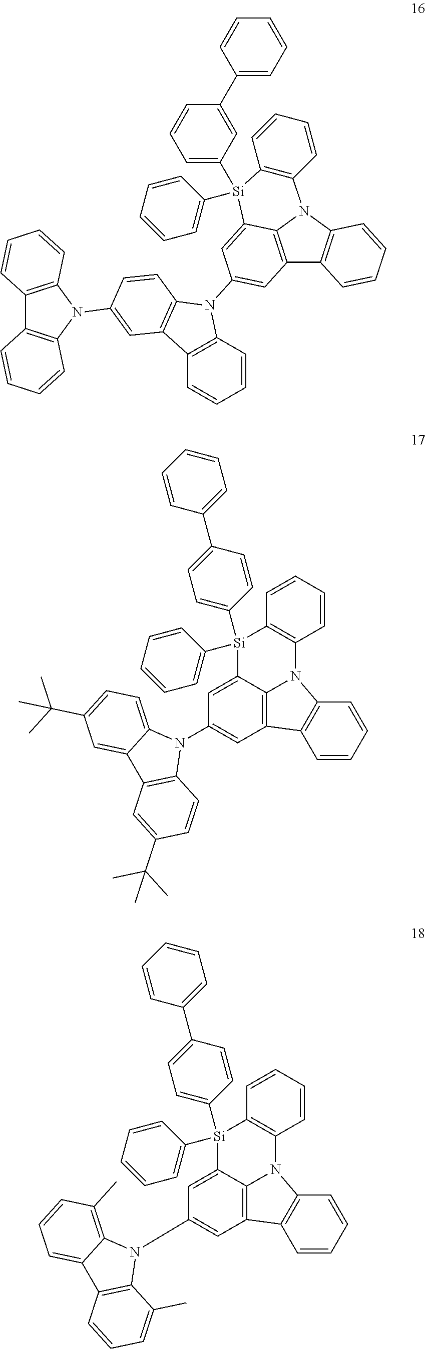 [SMILES: c1ccc(-c2cccc([Si]3(c4ccccc4)c4ccccc4-n4c5ccccc5c5cc(-n6c7ccccc7c7cc(-n8c9ccccc9c9ccccc98)ccc76)cc3c54)c2)cc1 ; CC(C)(C)c1ccc2c(c1)c1cc(C(C)(C)C)ccc1n2-c1cc2c3c(c1)c1ccccc1n3-c1ccccc1[Si]2(c1ccccc1)c1ccc(-c2ccccc2)cc1 ; Cc1cccc2c3cccc(C)c3n(-c3cc4c5c(c3)c3ccccc3n5-c3ccccc3[Si]4(c3ccccc3)c3ccc(-c4ccccc4)cc3)c12] 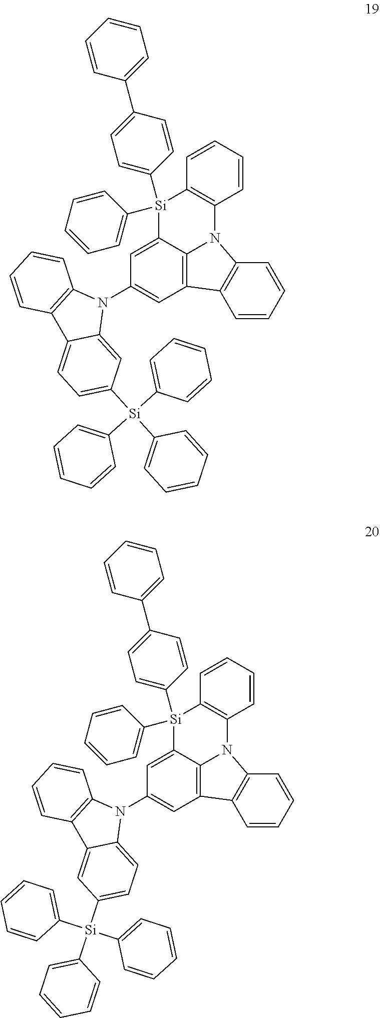 [SMILES: c1ccc(-c2ccc([Si]3(c4ccccc4)c4ccccc4-n4c5ccccc5c5cc(-n6c7ccccc7c7ccc([Si](c8ccccc8)(c8ccccc8)c8ccccc8)cc76)cc3c54)cc2)cc1 ; c1ccc(-c2ccc([Si]3(c4ccccc4)c4ccccc4-n4c5ccccc5c5cc(-n6c7ccccc7c7cc([Si](c8ccccc8)(c8ccccc8)c8ccccc8)ccc76)cc3c54)cc2)cc1] 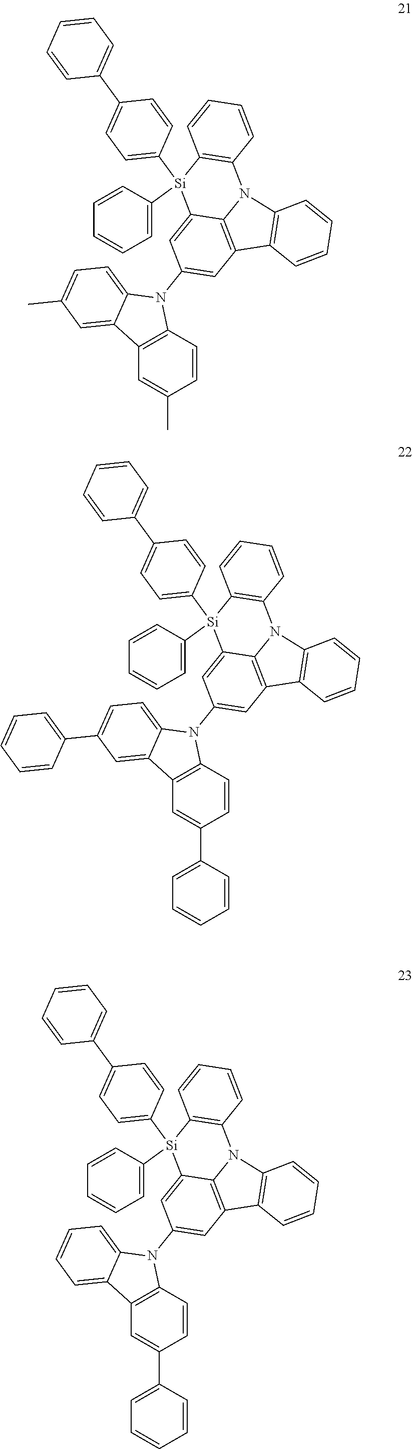 [SMILES: Cc1ccc2c(c1)c1cc(C)ccc1n2-c1cc2c3c(c1)c1ccccc1n3-c1ccccc1[Si]2(c1ccccc1)c1ccc(-c2ccccc2)cc1 ; c1ccc(-c2ccc([Si]3(c4ccccc4)c4ccccc4-n4c5ccccc5c5cc(-n6c7ccc(-c8ccccc8)cc7c7cc(-c8ccccc8)ccc76)cc3c54)cc2)cc1 ; c1ccc(-c2ccc([Si]3(c4ccccc4)c4ccccc4-n4c5ccccc5c5cc(-n6c7ccccc7c7cc(-c8ccccc8)ccc76)cc3c54)cc2)cc1] 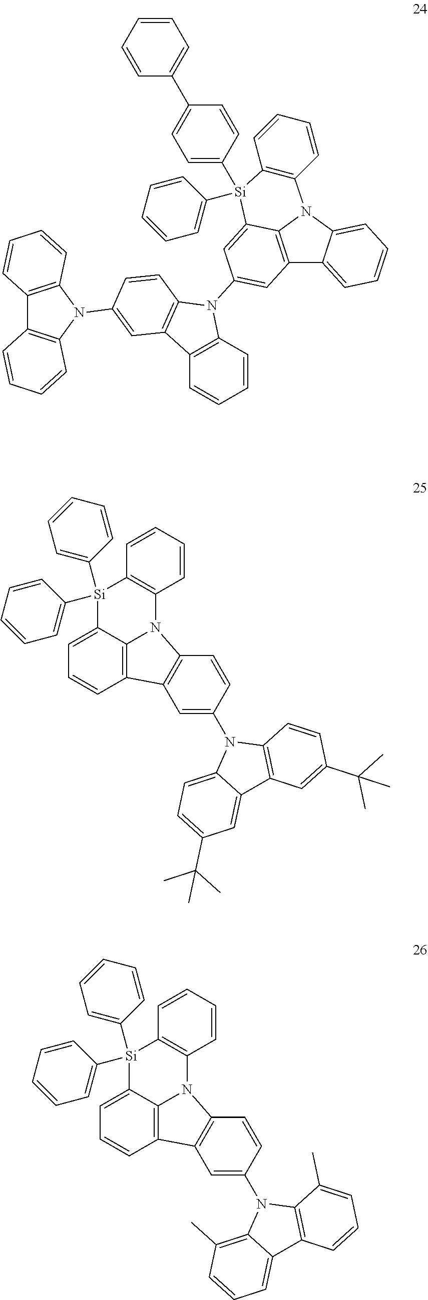 [SMILES: c1ccc(-c2ccc([Si]3(c4ccccc4)c4ccccc4-n4c5ccccc5c5cc(-n6c7ccccc7c7cc(-n8c9ccccc9c9ccccc98)ccc76)cc3c54)cc2)cc1 ; CC(C)(C)c1ccc2c(c1)c1cc(C(C)(C)C)ccc1n2-c1ccc2c(c1)c1cccc3c1n2-c1ccccc1[Si]3(c1ccccc1)c1ccccc1 ; Cc1cccc2c3cccc(C)c3n(-c3ccc4c(c3)c3cccc5c3n4-c3ccccc3[Si]5(c3ccccc3)c3ccccc3)c12] 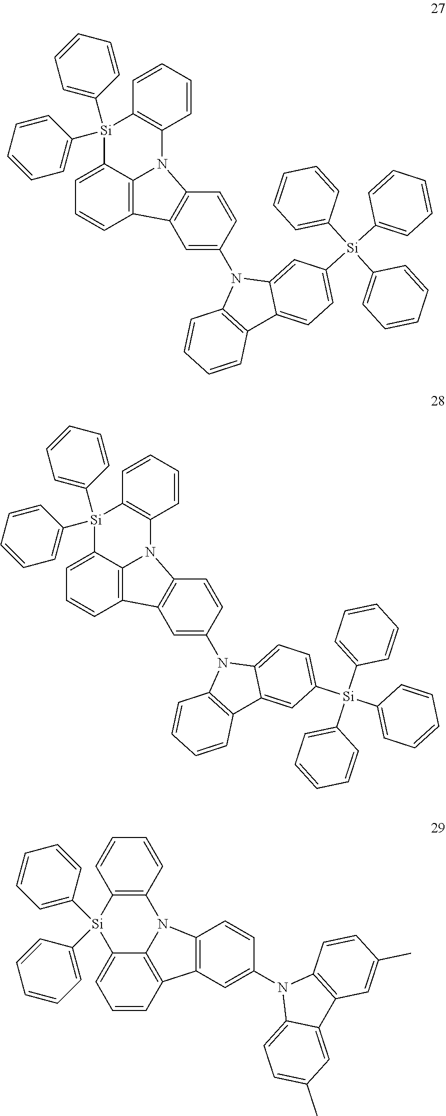 [SMILES: c1ccc([Si](c2ccccc2)(c2ccccc2)c2ccc3c4ccccc4n(-c4ccc5c(c4)c4cccc6c4n5-c4ccccc4[Si]6(c4ccccc4)c4ccccc4)c3c2)cc1 ; c1ccc([Si](c2ccccc2)(c2ccccc2)c2ccc3c(c2)c2ccccc2n3-c2ccc3c(c2)c2cccc4c2n3-c2ccccc2[Si]4(c2ccccc2)c2ccccc2)cc1 ; Cc1ccc2c(c1)c1cc(C)ccc1n2-c1ccc2c(c1)c1cccc3c1n2-c1ccccc1[Si]3(c1ccccc1)c1ccccc1] 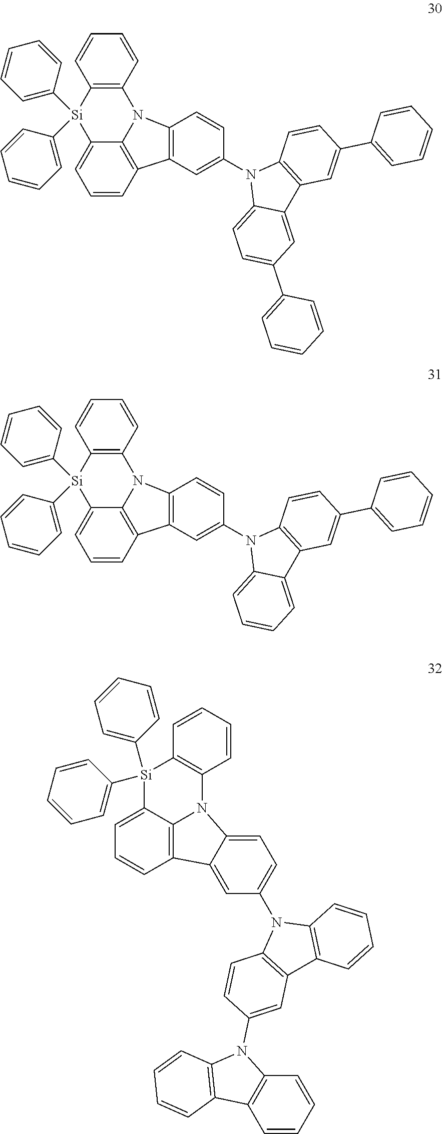 [SMILES: c1ccc(-c2ccc3c(c2)c2cc(-c4ccccc4)ccc2n3-c2ccc3c(c2)c2cccc4c2n3-c2ccccc2[Si]4(c2ccccc2)c2ccccc2)cc1 ; c1ccc(-c2ccc3c(c2)c2ccccc2n3-c2ccc3c(c2)c2cccc4c2n3-c2ccccc2[Si]4(c2ccccc2)c2ccccc2)cc1 ; c1ccc([Si]2(c3ccccc3)c3ccccc3-n3c4ccc(-n5c6ccccc6c6cc(-n7c8ccccc8c8ccccc87)ccc65)cc4c4cccc2c43)cc1] 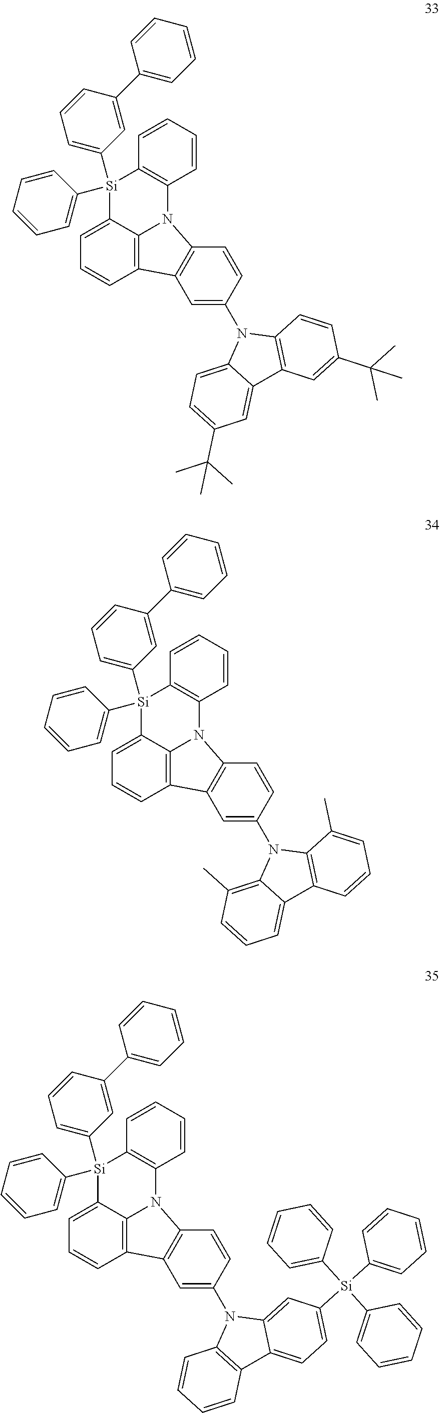 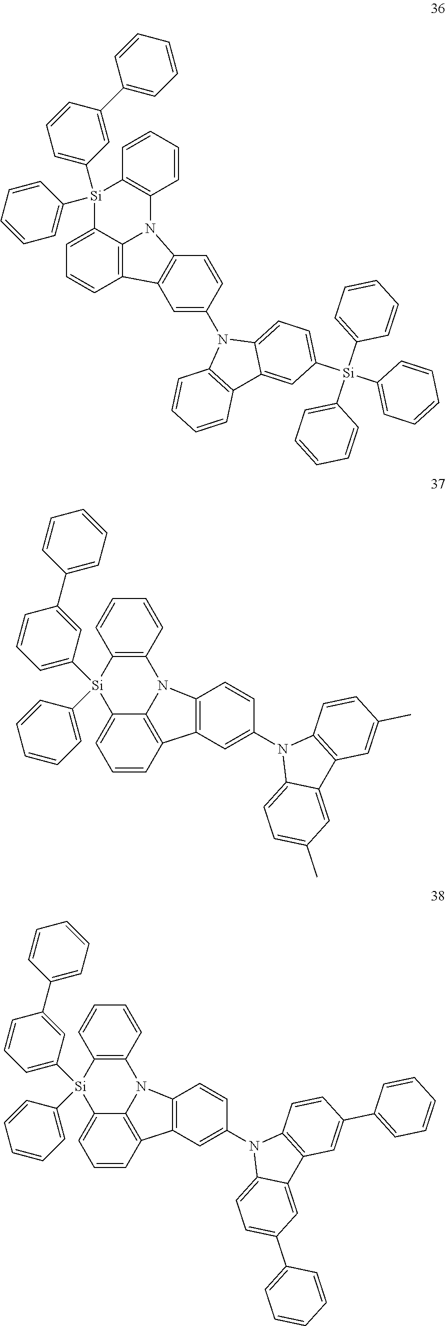 [SMILES: c1ccc(-c2cccc([Si]3(c4ccccc4)c4ccccc4-n4c5ccc(-n6c7ccccc7c7cc([Si](c8ccccc8)(c8ccccc8)c8ccccc8)ccc76)cc5c5cccc3c54)c2)cc1 ; Cc1ccc2c(c1)c1cc(C)ccc1n2-c1ccc2c(c1)c1cccc3c1n2-c1ccccc1[Si]3(c1ccccc1)c1cccc(-c2ccccc2)c1 ; c1ccc(-c2cccc([Si]3(c4ccccc4)c4ccccc4-n4c5ccc(-n6c7ccc(-c8ccccc8)cc7c7cc(-c8ccccc8)ccc76)cc5c5cccc3c54)c2)cc1] 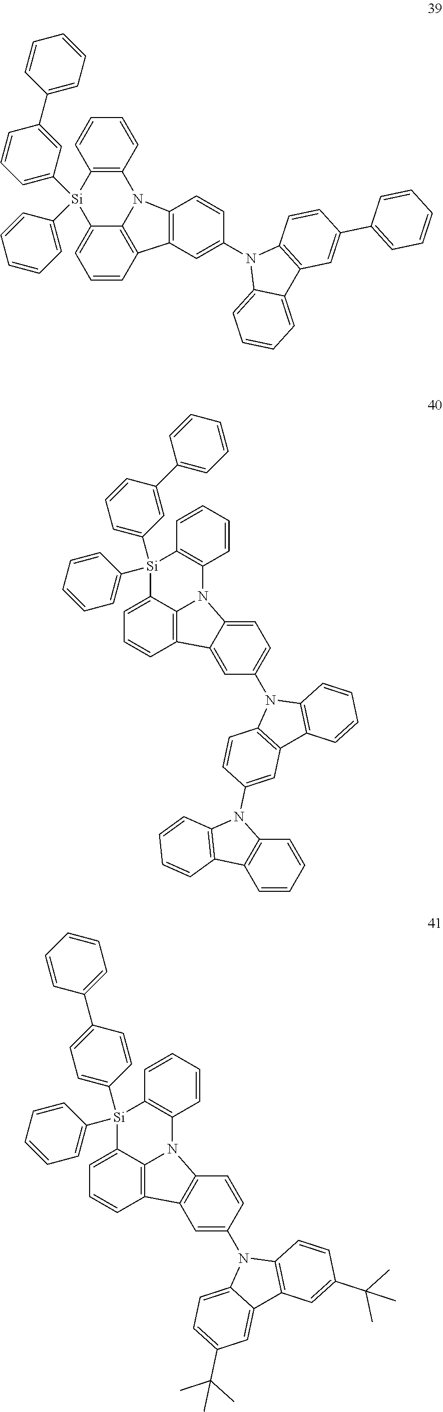 [SMILES: c1ccc(-c2cccc([Si]3(c4ccccc4)c4ccccc4-n4c5ccc(-n6c7ccccc7c7cc(-c8ccccc8)ccc76)cc5c5cccc3c54)c2)cc1 ; c1ccc(-c2cccc([Si]3(c4ccccc4)c4ccccc4-n4c5ccc(-n6c7ccccc7c7cc(-n8c9ccccc9c9ccccc98)ccc76)cc5c5cccc3c54)c2)cc1 ; CC(C)(C)c1ccc2c(c1)c1cc(C(C)(C)C)ccc1n2-c1ccc2c(c1)c1cccc3c1n2-c1ccccc1[Si]3(c1ccccc1)c1ccc(-c2ccccc2)cc1] 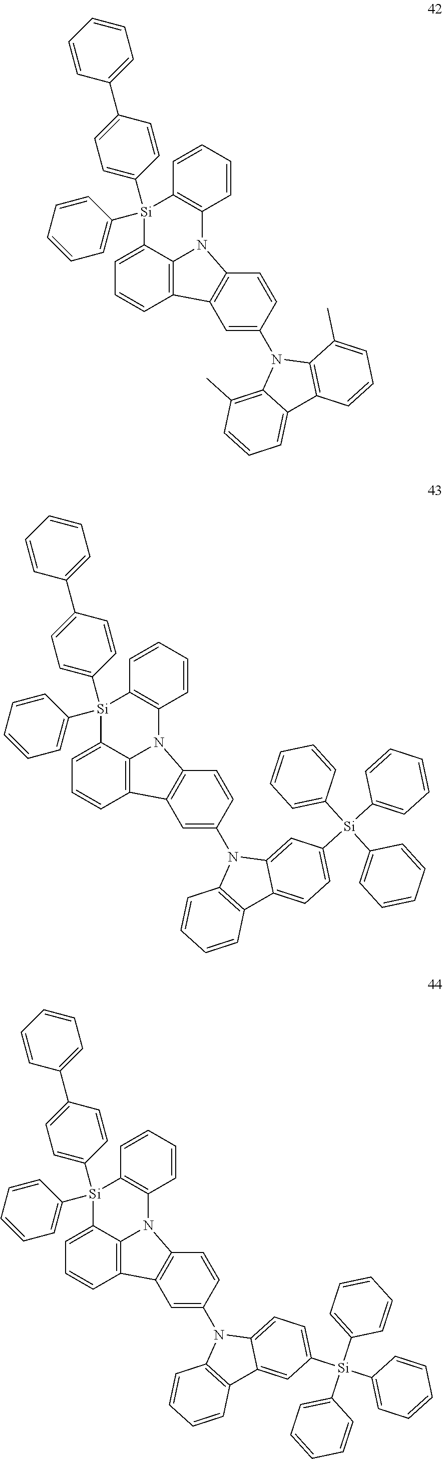 [SMILES: Cc1cccc2c3cccc(C)c3n(-c3ccc4c(c3)c3cccc5c3n4-c3ccccc3[Si]5(c3ccccc3)c3ccc(-c4ccccc4)cc3)c12 ; c1ccc(-c2ccc([Si]3(c4ccccc4)c4ccccc4-n4c5ccc(-n6c7ccccc7c7ccc([Si](c8ccccc8)(c8ccccc8)c8ccccc8)cc76)cc5c5cccc3c54)cc2)cc1 ; c1ccc(-c2ccc([Si]3(c4ccccc4)c4ccccc4-n4c5ccc(-n6c7ccccc7c7cc([Si](c8ccccc8)(c8ccccc8)c8ccccc8)ccc76)cc5c5cccc3c54)cc2)cc1] 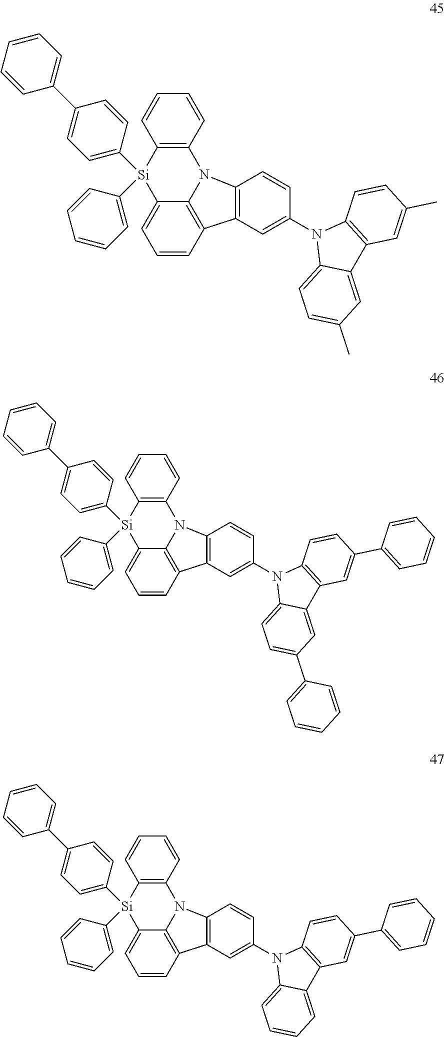 [SMILES: Cc1ccc2c(c1)c1cc(C)ccc1n2-c1ccc2c(c1)c1cccc3c1n2-c1ccccc1[Si]3(c1ccccc1)c1ccc(-c2ccccc2)cc1 ; c1ccc(-c2ccc([Si]3(c4ccccc4)c4ccccc4-n4c5ccc(-n6c7ccc(-c8ccccc8)cc7c7cc(-c8ccccc8)ccc76)cc5c5cccc3c54)cc2)cc1 ; c1ccc(-c2ccc([Si]3(c4ccccc4)c4ccccc4-n4c5ccc(-n6c7ccccc7c7cc(-c8ccccc8)ccc76)cc5c5cccc3c54)cc2)cc1] 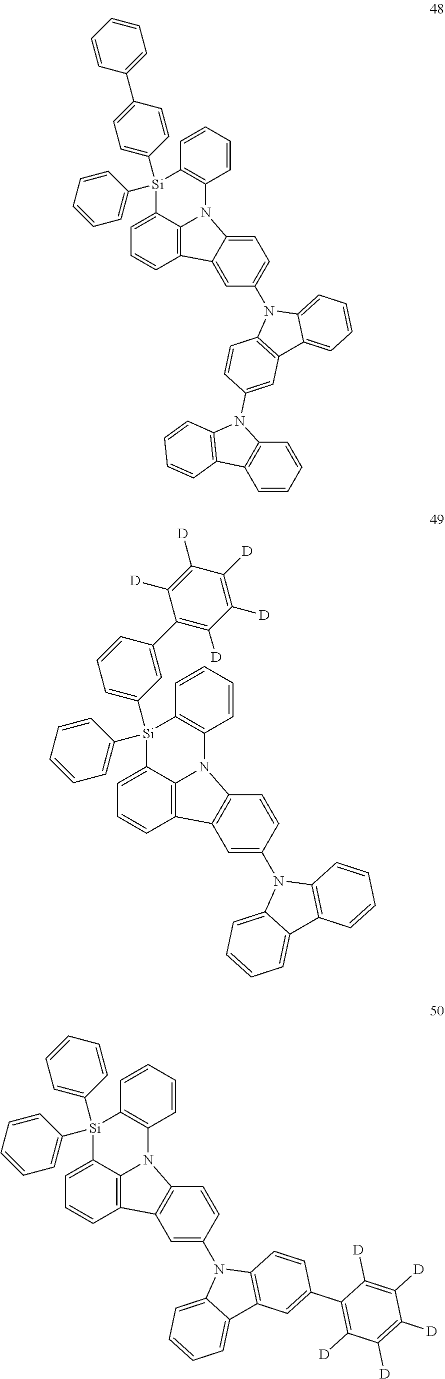 [SMILES: c1ccc(-c2ccc([Si]3(c4ccccc4)c4ccccc4-n4c5ccc(-n6c7ccccc7c7cc(-n8c9ccccc9c9ccccc98)ccc76)cc5c5cccc3c54)cc2)cc1 ; [2H]c1c([2H])c([2H])c(-c2cccc([Si]3(c4ccccc4)c4ccccc4-n4c5ccc(-n6c7ccccc7c7ccccc76)cc5c5cccc3c54)c2)c([2H])c1[2H] ; [2H]c1c([2H])c([2H])c(-c2ccc3c(c2)c2ccccc2n3-c2ccc3c(c2)c2cccc4c2n3-c2ccccc2[Si]4(c2ccccc2)c2ccccc2)c([2H])c1[2H]] 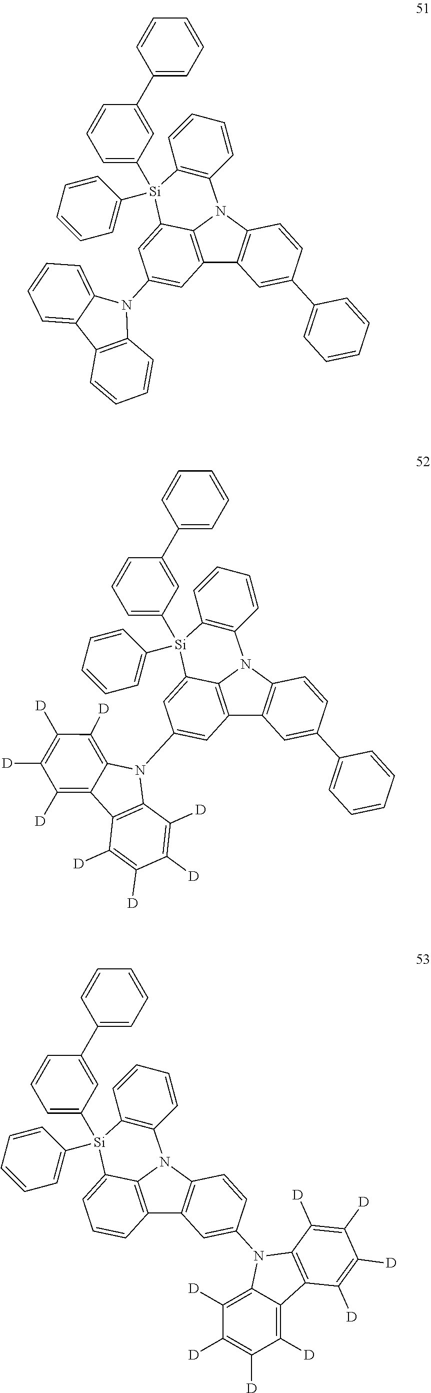 [SMILES: c1ccc(-c2cccc([Si]3(c4ccccc4)c4ccccc4-n4c5ccc(-c6ccccc6)cc5c5cc(-n6c7ccccc7c7ccccc76)cc3c54)c2)cc1 ; [2H]c1c([2H])c([2H])c2c(c1[2H])c1c([2H])c([2H])c([2H])c([2H])c1n2-c1cc2c3c(c1)c1cc(-c4ccccc4)ccc1n3-c1ccccc1[Si]2(c1ccccc1)c1cccc(-c2ccccc2)c1 ; [2H]c1c([2H])c([2H])c2c(c1[2H])c1c([2H])c([2H])c([2H])c([2H])c1n2-c1ccc2c(c1)c1cccc3c1n2-c1ccccc1[Si]3(c1ccccc1)c1cccc(-c2ccccc2)c1] [chemical structure]
